(19) United States
(12) Patent Application Publication
(10) Pub. No.: US 2016/0212836 A1
(43) Pub. Date: Jul. 21, 2016

(54) Surface-Treated Metal Material, Metal Foil With Carrier, Connector, Terminal, Laminate, Shielding Tape, Shielding Material, Printed Wiring Board, Processed Metal Member, Electronic Device, And Method For Manufacturing Printed Wiring Board

(71) Applicant: JX NIPPON MINING & METALS CORPORATION, Tokyo (JP)

(72) Inventors: Hideta Arai, Ibaraki (JP); Ryo Fukuchi, Ibaraki (JP); Satoru Morioka, Tokyo (JP); Naohiko Era, Tokyo (JP)

(21) Appl. No.: 14/915,293

(22) PCT Filed: Aug. 29, 2014
(86) PCT No.: PCT/JP2014/072829

§ 371 Date: Feb. 29, 2016

(30) Foreign Application Priority Data
Aug. 29, 2013 (JP) 2013-191092

(51) Int. Cl. H05K 1/02; C22C 9/04; H05K 3/02; C22C 9/01; H05K 7/20; C22C 9/06; C22C 9/02

(52) U.S. Cl. CPC H05K 1/0207; C22C 9/06; C22C 9/04; C22C 9/02; C22C 9/01; H05K 7/20436; H05K 3/025; H05K 2201/0382; H05K 2201/0355; H05K 2203/06

(57) ABSTRACT

A surface-treated metal material good in heat absorbency and heat releasability is provided. The surface-treated metal material has a heat conductivity of 32 W/(m·K) or higher; and a color difference ΔL based on JIS Z8730 of the surface thereof satisfying ΔL≦−40.

### TECHNICAL FIELD

The present invention relates to a surface-treated metal material, a metal foil with a carrier, a connector, a terminal, a laminate, a shielding tape, a shielding material, a printed wiring board, a processed metal member, an electronic device, and a method for manufacturing a printed wiring board.

### BACKGROUND ART

In recent years, along with the size reduction and fineness enhancement of electronic devices, there has arisen a problem of failures and the like due to heat generation of electronic components to be used. Electronic components used in remarkably growing electric automobiles and hybrid electric automobiles particularly include components through which a remarkably high current flows, such as connectors of battery sections, posing a problem of heat generation of electronic components during energization. Heat releasing plates called liquid crystal frames are used for liquid crystals of smartphone tablets and tablet PCs. These heat releasing plates release heat from liquid crystal components, IC chips and the like arranged in their circumference to the outside to thereby suppress failures and the like of electronic components.

### CITATION LIST

### Patent Literature

### [Patent Literature 1]

Japanese Patent Laid-Open No. 07-094644

### [Patent Literature 2]

Japanese Patent Laid-Open No. 08-078461

### SUMMARY OF INVENTION

### Technical Problem

Due to recent variations of electronic devices as described above, however, conventional liquid crystal frames come not to be able to meet such a function of well absorbing conductive heat, radiant heat, convective heat and the like from liquid crystal components, IC chips and the like, and well releasing the absorbed heat to the outside so as not to stay inside.

Then, the present invention has an object to provide a surface-treated metal material having good heat absorbency and heat releasability.

### Solution to Problem

As a result of exhaustive studies, the present inventor has found that by carrying out a surface treatment on a metal material having a predetermined heat conductivity to thereby control the color difference of the surface of the metal material, a surface-treated metal material having good heat absorbency and heat releasability can be provided.

One aspect of the present invention completed based on the above finding is a surface-treated metal material having: a heat conductivity of 32 W/(m·K) or higher; and

a color difference ΔL based on JIS Z8730 of the surface thereof satisfying ΔL≦−40.

In one embodiment of the surface-treated metal material according to the present invention, with respect to the color differences ΔL, Δa based on JIS Z8730 of the surface thereof,

when Δa≦0.23, ΔL satisfies ΔL≦−40;

when 0.23<Δa≦2.8, ΔL satisfies ΔL≦−8.5603×Δa−38.0311; and

when 2.8<Δa, ΔL satisfies ΔL≦−62.

In another embodiment of the surface-treated metal material according to the present invention, with respect to the color differences ΔL, Δb based on JIS Z8730 of the surface thereof,

when Δb≦−0.68, ΔL satisfies ΔL≦−40;

when −0.68<Δb≦0.83, ΔL satisfies ΔL≦−2.6490×Δb−41.8013;

when 0.83<Δb≦1.2, ΔL satisfies ΔL≦−48.6486×Δb−3.6216; and

when 1.2<Δb, ΔL satisfies ΔL≦−62.

In further another embodiment of the surface-treated metal material according to the present invention, with respect to the color differences ΔL, Δa based on JIS Z8730 of the surface thereof,

when Δa≦0.23, ΔL satisfies ΔL≦−40;

when 0.23<Δa≦2.8, ΔL satisfies ΔL≦−8.5603×Δa−38.0311; and

when 2.8<Δa, ΔL satisfies ΔL≦−62, and

with respect to the color differences ΔL, Δb based on JIS Z8730 of the surface thereof,

when Δb≦−0.68, ΔL satisfies ΔL≦−40;

when −0.68<Δb≦0.83, ΔL satisfies ΔL≦−2.6490×Δb−41.8013;

when 0.83<Δb≦1.2, ΔL satisfies ΔL≦−48.6486×Δb−3.6216; and

when 1.2<Δb, ΔL satisfies ΔL≦−62.

In further another embodiment of the surface-treated metal material according to the present invention, the color difference ΔL satisfies ΔL≦−45.

In further another embodiment of the surface-treated metal material according to the present invention, the color difference ΔL satisfies ΔL≦−55.

In further another embodiment of the surface-treated metal material according to the present invention, the color difference ΔL satisfies ΔL≦−60.

In further another embodiment of the surface-treated metal material according to the present invention, the color difference ΔL satisfies ΔL≦−65.

In further another embodiment of the surface-treated metal material according to the present invention, the color difference ΔL satisfies ΔL≦−68.

In further another embodiment of the surface-treated metal material according to the present invention, the color difference ΔL satisfies ΔL≦−70.

In further another embodiment of the surface-treated metal material according to the present invention, the metal material is a metal material for heat release.

In further another embodiment of the surface-treated metal material according to the present invention, the surface-treated metal material has a treated surface layer containing a metal.

In further another embodiment of the surface-treated metal material according to the present invention, the surface-treated metal material has a treated surface layer containing a roughening-treated layer.

In further another embodiment of the surface-treated metal material according to the present invention, the surface-treated metal material has a 60° glossiness of 10 to 80%.

In further another embodiment of the surface-treated metal material according to the present invention, the surface-treated metal material has the 60° glossiness of lower than 10%.

In further another embodiment of the surface-treated metal material according to the present invention, the surface-treated metal material has a treated surface layer containing a chromium layer or a chromate layer and/or a silane-treated layer.

In further another embodiment of the surface-treated metal material according to the present invention, the metal material is formed of copper, a copper alloy, aluminum, an aluminum alloy, iron, an iron alloy, nickel, a nickel alloy, gold, a gold alloy, silver, a silver alloy, a platinum-group metal, a platinum-group metal alloy, chromium, a chromium alloy, magnesium, a magnesium alloy, tungsten, a tungsten alloy, molybdenum, a molybdenum alloy, lead, a lead alloy, tantalum, a tantalum alloy, tin, a tin alloy, indium, an indium alloy, zinc, or a zinc alloy.

In further another embodiment of the surface-treated metal material according to the present invention, the metal material is formed of copper, a copper alloy, aluminum, an aluminum alloy, iron, an iron alloy, nickel, a nickel alloy, zinc, or a zinc alloy.

In further another embodiment of the surface-treated metal material according to the present invention, the metal material is formed of a phosphor bronze, a Corson alloy, a red brass, a brass, a German silver, or another copper alloy.

In further another embodiment of the surface-treated metal material according to the present invention, the metal material is a metal strip, a metal plate or a metal foil.

In further another embodiment of the surface-treated metal material according to the present invention, the surface of the treated surface layer has a resin layer.

In further another embodiment of the surface-treated metal material according to the present invention, the resin layer contains a dielectric.

Another aspect of the present invention is a metal foil with a carrier having a middle layer and an ultrathin metal layer in this order on one surface or both surfaces of the carrier, in which the ultrathin metal layer is the surface-treated metal material according to the present invention.

In one embodiment of the metal foil with a carrier according to the present invention, the metal foil with a carrier has the middle layer and the ultrathin metal layer in this order on one surface of the carrier and has a roughening-treated layer on the other surface of the carrier.

In another embodiment of the metal foil with a carrier according to the present invention, the ultrathin metal layer is an ultrathin copper layer.

Further another aspect of the present invention is a connector comprising the surface-treated metal material according to the present invention.

Further another aspect of the present invention is a terminal comprising the surface-treated metal material according to the present invention.

Further another aspect of the present invention is a laminate manufactured by laminating the surface-treated metal material according to the present invention or the metal foil with a carrier according to the present invention with a resin substrate.

Further another aspect of the present invention is a shielding tape or a shielding material having the laminate according to the present invention.

Further another aspect of the present invention is a printed wiring board having the laminate according to the present invention.

Further another aspect of the present invention is a processed metal member comprising the surface-treated metal material according to the present invention or the metal foil with a carrier according to the present invention.

Further another aspect of the present invention is an electronic device comprising the surface-treated metal material according to the present invention or the metal foil with a carrier according to the present invention.

Further another aspect of the present invention is a method for manufacturing a printed wiring board, comprising the steps of:

providing the metal foil with a carrier according to the present invention and an insulating substrate;

laminating the metal foil with a carrier and the insulating substrate;

after the metal foil with a carrier and the insulating substrate are laminated, peeling off the carrier of the metal foil with a carrier to thereby form a metal clad laminated plate; and

thereafter forming a circuit by any one method of a semi-additive method, a subtractive method, a partly additive method and a modified semi-additive method.

Further another aspect of the present invention is a method for manufacturing a printed wiring board, comprising the steps of:

forming a circuit on the surface of the ultrathin metal layer side of the metal foil with a carrier according to the present invention or the surface of the carrier side thereof;

forming a resin layer on the surface of the ultrathin metal layer side of the metal foil with a carrier or the surface of the carrier side thereof so as to embed the circuit;

forming a circuit on the resin layer;

after the circuit is formed on the resin layer, peeling off the carrier or the ultrathin metal layer; and

after the carrier or the ultrathin metal layer is peeled off, removing the ultrathin metal layer or the carrier to thereby expose the circuit formed on the surface of the ultrathin metal layer side or the surface of the carrier side and embedded in the resin layer.

### Advantageous Effects of Invention

The present invention can provide the surface-treated metal material having good heat absorbency and heat releasability.

### BRIEF DESCRIPTION OF DRAWINGS

FIG. 1(A) is a schematic view of the upper surface of a shielding box fabricated in Example. FIG. 1(B) is a cross-sectional schematic view of the shielding box fabricated in Example.

FIG. 2 is a Δa-ΔL graph relevant to Examples and Comparative Examples.

FIG. 3 is a Δb-ΔL graph relevant to the Examples and the Comparative Examples.

### DESCRIPTION OF EMBODIMENTS

[A Form and a Manufacturing Method of a Surface-Treated Metal Material]

A metal material to be used in the present invention includes metal materials, such as copper, a copper alloy, aluminum, an aluminum alloy, iron, an iron alloy, nickel, a nickel alloy, gold, a gold alloy, silver, a silver alloy, a platinum-group metal, a platinum-group metal alloy, chromium, a chromium alloy, magnesium, a magnesium alloy, tungsten, a tungsten alloy, molybdenum, a molybdenum alloy, lead, a lead alloy, a tantalum, a tantalum alloy, tin, a tin alloy, indium, an indium alloy, zinc and a zinc alloy, having a heat conductivity of 32 W/(m·K) or higher; and further a well-known metal material having a heat conductivity of 32 W/(m·K) or higher can also be used. Further a metal material can also be used which is a metal material standardized in JIS, CDA and the like and having a heat conductivity of 32 W/(m·K) or higher.

The copper typically includes copper of 95% by mass or higher, preferably 99.90% by mass or higher in purity such as phosphorus deoxidized copper standardized in JIS H0500 and JIS H3100 (JIS H3100, alloy numbers: C1201, C1220, C1221), oxygen free copper (JIS H3100, alloy number: C1020), tough pitch copper (JIS H3100, alloy number: C1100) and electrodeposited copper foil. The copper may be a copper or a copper alloy containing 0.001 to 4.0% by mass in total of one or more of Sn, Ag, Au, Co, Cr, Fe, In, Ni, P, Si, Te, Ti, Zn, B, Mn and Zr.

The copper alloy further includes phosphor bronze, Corson alloys, red brass, brass, German silver and other copper alloys. The copper and copper alloys usable in the present invention also include copper and copper alloys standardized in JIS H3100 to JIS H3510, JIS H5120, JIS H5121, JIS C2520 to JIS C2801, and JIS E2101 to JIS E2102. Here, in the present description, JIS Standards cited in order to indicate standards of metals refer to JIS Standards: 2001 unless otherwise specified.

The phosphor bronze typically refers to a copper alloy containing copper as a main component and containing Sn and a smaller mass than the Sn of P. A phosphor bronze as an example has a composition containing 3.5 to 11% by mass of Sn and 0.03 to 0.35% by mass of P, and being composed of copper and inevitable impurities as remainders. A phosphor bronze may contain 1.0% by mass or less in total of elements such as Ni and Zn.

The Corson alloy typically refers to a copper alloy in which elements (for example, one or more of Ni, Co and Cr) to form compounds with Si are added and the compounds are deposited as second-phase particles in a parent phase. A Corson alloy as an example has a composition containing 0.5 to 4.0% by mass of Ni and 0.1 to 1.3% by mass of Si and being constituted of copper and inevitable impurities as remainders. A Corson alloy as another example has a composition containing 0.5 to 4.0% by mass of Ni, 0.1 to 1.3% by mass of Si and 0.03 to 0.5% by mass of Cr and being constituted of copper and inevitable impurities as remainders. A Corson alloy as further another example has a composition containing 0.5 to 4.0% by mass of Ni, 0.1 to 1.3% by mass of Si and 0.5 to 2.5% by mass of Co and being constituted of copper and inevitable impurities as remainders. A Corson alloy as further another example has a composition containing 0.5 to 4.0% by mass of Ni, 0.1 to 1.3% by mass of Si, 0.5 to 2.5% by mass of Co and 0.03 to 0.5% by mass of Cr and being constituted of copper and inevitable impurities as remainders. A Corson alloy as further another example has a composition containing 0.2 to 1.3% by mass of Si and 0.5 to 2.5% by mass of Co and being constituted of copper and inevitable impurities as remainders. Other elements (for example, Mg, Sn, B, Ti, Mn, Ag, P, Zn, As, Sb, Be, Zr, Al and Fe) may optionally be added to a Corson alloy. It is usual that these other elements are added in about 5.0% by mass in total. A Corson alloy as still further another example has a composition containing 0.5 to 4.0% by mass of Ni, 0.1 to 1.3% by mass of Si, 0.01 to 2.0% by mass of Sn and 0.01 to 2.0% by mass of Zn and being constituted of copper and inevitable impurities as remainders.

In the present invention, the red brass is an alloy of copper and zinc, and refers to a copper alloy containing 1 to 20% by mass of Zn, more preferably 1 to 10% by mass of Zn. A red brass may contain 0.1 to 1.0% by mass of tin.

In the present invention, the brass is an alloy of copper and zinc, and refers particularly to a copper alloy containing 20% by mass or more of zinc. The upper limit of zinc is not especially limited, but is 60% by mass or less, and preferably 45% by mass or less, or 40% by mass or less.

In the present invention, the German silver refers to a copper alloy containing 60% by mass to 75% by mass of copper, 8.5% by mass to 19.5% by mass of nickel and 10% by mass to 30% by mass of zinc.

In the present invention, the other copper alloys refer to copper alloys containing 8.0% or less in total of one or two or more of Zn, Sn, Ni, Mg, Fe, Si, P, Co, Mn, Zr, Ag, B, Cr and Ti, and being composed of inevitable impurities and copper as remainders.

The aluminum and aluminum alloy usable are, for example, those containing 40% by mass or more of Al, or 80% by mass or more thereof, or 99% by mass or more thereof. For example, aluminum and aluminum alloys standardized in JIS H4000 to JIS H4180, JIS H5202, JIS H5303 and JIS Z3232 to JIS Z3263 can be used. For example, aluminum and aluminum alloys whose aluminum contents are 99.00% by mass or higher, represented by aluminum alloy numbers 1085, 1080, 1070, 1050, 1100, 1200, 1N00 and 1N30 standardized in JIS H4000, can be used.

The nickel and nickel alloys usable are, for example, those containing 40% by mass or more of Ni, or 80% by mass or more thereof, or 99.0% by mass or more thereof. For example, nickel and nickel alloys standardized in JIS H4541 to JIS H4554, JIS H5701, JIS G7604 to JIS G7605 and JIS C2531 can be used. For example, nickel and nickel alloys whose nickel contents are 99.0% by mass or higher, represented by alloy numbers NW2200 and NW2201 standardized in JIS H4551, can be used.

The iron alloys usable are, for example, mild steel, carbon steel, iron nickel alloys and steel. For example, iron and iron alloys described in JIS G3101 to JIS G7603, JIS C2502 to JIS C8380, JIS A5504 to JIS A6514 and JIS E1101 to JIS E5402-1 can be used. The mild steels usable are mild steels containing 0.15% by mass or less of carbon, and are mild steels described in JIS G3141, and the like. The iron nickel alloys contain 35 to 85% by mass of Ni, and are composed of Fe and inevitable impurities as remainders, and specifically usable are iron nickel alloys described in JIS C2531, and the like.

The zinc and zinc alloys usable are, for example, those containing 40% by mass or more of Zn, or 80% by mass or more thereof, or 99.0% by mass or more thereof. For example, zinc and zinc alloys described in JIS H2107 to JIS H5301 can be used.

The lead and lead alloys usable are, for example, those containing 40% by mass or more of Pb, or 80% by mass or more thereof, or 99.0% by mass or more thereof. For example, lead and lead alloys standardized in JIS H4301 to JIS H4312 and JIS H5601 can be used.

The magnesium and magnesium alloys usable are, for example, those containing 40% by mass or more of Mg, or 80% by mass or more thereof, or 99.0% by mass or more thereof. For example, magnesium and magnesium alloys standardized in JIS H4201 to JIS H4204, JIS H5203 to JIS H5303, and JIS H6125 can be used.

The tungsten and tungsten alloys usable are, for example, those containing 40% by mass or more of W, or 80% by mass or more thereof, or 99.0% by mass or more thereof. For example, tungsten and tungsten alloys standardized in JIS H4463 can be used.

The molybdenum and molybdenum alloys usable are, for example, those containing 40% by mass or more of Mo, or 80% by mass or more thereof, or 99.0% by mass or more thereof.

The tantalum and tantalum alloys usable are, for example, those containing 40% by mass or more of Ta, or 80% by mass or more thereof, or 99.0% by mass or more thereof. For example, tantalum and tantalum alloys standardized in JIS H4701 can be used.

The tin and tin alloys usable are, for example, those containing 40% by mass or more of Sn, or 80% by mass or more thereof, or 99.0% by mass or more thereof. For example, tin and tin alloys standardized in JIS H5401 can be used.

The indium and indium alloys usable are, for example, those containing 40% by mass or more of In, or 80% by mass or more thereof, or 99.0% by mass or more thereof.

The chromium and chromium alloys usable are, for example, those containing 40% by mass or more of Cr, or 80% by mass or more thereof, or 99.0% by mass or more thereof.

The silver and silver alloys usable are, for example, those containing 40% by mass or more of Ag, or 80% by mass or more thereof, or 99.0% by mass or more thereof.

The gold and gold alloys usable are, for example, those containing 40% by mass or more of Au, or 80% by mass or more thereof, or 99.0% by mass or more thereof.

The platinum group is a general term of ruthenium, rhodium, palladium, osmium, iridium and platinum. Platinum-group metals and platinum-group metal alloys usable are, for example those containing 40% by mass or more of at least one or more of elements selected from the elemental group of Pt, Os, Ru, Pd, Ir and Rh, or 80% by mass or more thereof, or 99.0% by mass or more thereof.

The heat conductivity of the metal material according to the present invention is 32 W/(m·K) or higher. If the heat conductivity of the metal material is 32 W/(m·K) or higher, conductive heat, radiant heat, convective heat and the like absorbed from a heat generating body are not locally concentrated but transferred to the whole metal material to thereby make the release of the heat to the outside easy. The heat conductivity of the metal material according to the present invention is preferably 50 W/(m·K) or higher, further preferably 70 W/(m·K) or higher, further preferably 90 W/(m·K) or higher, further preferably 150 W/(m·K) or higher, further preferably 170 W/(m·K) or higher, further preferably 210 W/(m·K) or higher, further preferably 230 W/(m·K) or higher, further preferably 250 W/(m·K) or higher, further preferably 270 W/(m·K) or higher, further preferably 300 W/(m·K) or higher, and further preferably 350 W/(m·K) or higher. Here, although there is no need to especially establish the upper limit on the heat conductivity, the heat conductivity is, for example, 600 W/(m·K) or lower, for example, 500 W/(m·K) or lower, or for example, 450 W/(m·K) or lower.

The shape of a metal material used in the present invention is not especially limited, but the shape may be one processed into a final shape of an electronic component, or may be in a partially stamped state. The shape may be in a form of a plate or a foil which has been subjected to no shape processing.

The thickness of a metal material is not especially limited, and the metal material can be used, for example, by adjusting its thickness to a thickness suitable for each application. The thickness can be made to be, for example, about 1 to 5,000 μm, or about 2 to 1,000 μm; and the metal material can be applied as a thin one of 35 μm or thinner particularly in the case of using the metal material by forming circuits, and of 18 μm or thinner for a shielding tape, and further as a thick material of 70 to 1,000 μm in the case of using the metal material as a connector, a shielding material, a cover and the like in an electronic device, thus not especially establishing the upper limit thickness.

The surface-treated metal material according to the present invention may be one in which treated surface layers such as a plating layer, a roughening-treated layer, a heat resistance-treatment layer, a rust prevention-treatment layer and an oxide layer (an oxide layer is formed on the surface of a metal material by heating or the like) are formed on the surface of a metal material. Here, the plating layer can be formed by a wet plating such as electroplating, electroless plating or immersion plating, or a dry plating such as sputtering, CVD or PDV. Electroplating is preferable from the viewpoint of the cost. The surface-treated metal material according to the present invention may not necessarily be one in which a treated surface layer is formed, and may be a metal material whose surface is treated with polishing (including chemical polishing and mechanical polishing), a chemical or the like and which has no treated surface layer.

The surface-treated metal material according to the present invention is so controlled that the color difference ΔL of its surface based on JIS Z8730 satisfies ΔL≦−40. If the surface of a metal material is thus controlled so as to satisfy ΔL≦−40, conductive heat, radiant heat, convective heat and the like absorbed from a heat generating body can well be absorbed.

The color differences (ΔL, Δa, Δb) based on JIS Z8730 of the surface can be measured using a color difference meter MiniScan XE Plus, manufactured by HunterLab Inc.

The surface-treated metal material according to the present invention is preferably so controlled that with respect to the color differences Δa, ΔL based on JIS Z8730 of the surface thereof,

when Δa≦0.23, ΔL satisfies ΔL≦−40;

when 0.23<Δa≦2.8, ΔL satisfies ΔL≦−8.5603×Δa−38.0311; and

when 2.8<Δa, ΔL satisfies ΔL≦−62.

According to such a constitution, conductive heat, radiant heat, convective heat and the like absorbed from a heat generating body can better be absorbed.

The surface-treated metal material according to the present invention is preferably further so controlled that with respect to the color differences Δb, ΔL based on JIS Z8730 of the surface thereof,

when Δb≦−0.68, ΔL satisfies ΔL≦−40;

when −0.68<Δb≦0.83, ΔL satisfies ΔL≦−2.6490×Δb−41.8013;

when 0.83<Δb≦1.2, ΔL satisfies ΔL≦−48.6486×Δb−3.6216; and

when 1.2<Δb, ΔL satisfies ΔL≦−62.

According to such a constitution, conductive heat, radiant heat, convective heat and the like absorbed from a heat generating body can better be absorbed.

In the surface-treated metal material according to the present invention, the color difference ΔL satisfies preferably ΔL≦−45, more preferably ΔL≦−50, further preferably ΔL≦−55, further preferably ΔL≦−58, further preferably ΔL≦−60, further preferably ΔL≦−65, further preferably ΔL≦−68, and further preferably ΔL≦−70. Although there is no need to especially establish the lower limit on the ΔL, the ΔL may satisfy, for example, ΔL≧−90, ΔL≧−88, ΔL≧−85, ΔL≧−83, ΔL≧−80, ΔL≧−78 or ΔL≧−75.

In the surface-treated metal material according to the present invention, the color difference Δa may be Δa≧−10 or Δa≧−5. Further the color difference Δa may be Δa≦40, Δa≦45, or Δa≦50.

In the surface-treated metal material according to the present invention, the color difference Δb may be Δb≧−15 or Δb≧−10. Further the color difference Δb may be Δb≦25 or Δb≦30. The above-mentioned color differences can also be regulated by providing a roughening-treated layer by subjecting the surface of a metal material to a roughening treatment. In the case of providing a roughening-treated layer, the color differences can be regulated by using an electrolytic solution containing copper and one or more elements selected from the group consisting of nickel, cobalt, tungsten and molybdenum, and making the current density higher (for example, 35 to 60 A/dm², preferably 40 to 60 A/dm²) and the treatment time shorter (for example, 0.1 to 1.5 sec, preferably 0.2 to 1.4 sec) than conventionally. In the case of providing no roughening-treated layer on the surface of a metal material, the color differences can be achieved, for example, by using a plating bath containing Ni and/or Co, and one or more elements selected from the group consisting of W, Zn, Sn and Cu, and having a concentration of Ni and/or Co (in the case of containing Ni and Co, a total concentration of Ni and Co) made twice or more times (preferably 2.5 or more times) a total concentration of the other elements, and carrying out Ni alloy plating or Co alloy plating (for example, Ni—W alloy plating, Ni—Co—P alloy plating, Ni—Zn alloy plating and Co—Zn alloy plating) on the surface of a metal material, a heat resistance layer, a rust prevention layer, a chromate-treatment layer or a silane coupling-treatment layer by setting the current density lower (0.1 to 3 A/dm², preferably 0.1 to 2.8 A/dm²) and the treatment time longer (5 sec or longer, preferably 10 sec or longer, more preferably 20 sec or longer, for example, 20 sec to 190 sec, preferably, 20 sec to 180 sec) than conventionally.

The surface-treated metal material according to the present invention may have a 60° glossiness of 10 to 80%. According to such a constitution, conductive heat, radiant heat, convective heat and the like absorbed from a heat generating body can better be absorbed, and an effect of increasing the designability (beauty) is caused due to more luster generated on the surface of the surface-treated metal material than the surface-treated metal material having a 60° glossiness of lower than 10%. The 60° glossiness is more preferably 10 to 70%, further preferably 15 to 60%, and further preferably 15 to 50%.

Here, by carrying out polishing such as chemical polishing or mechanical polishing on the surface of a metal material or by high-glossiness rolling or the like before the metal material is subjected to the surface treatment to thereby previously control the 60° glossiness of the surface of the metal material, the 60° glossiness after the surface treatment of the surface-treated metal material can be controlled in the above range.

The chemical polishing is carried out by using an etchant such as a sulfuric acid-hydrogen peroxide-water type or an ammonia-hydrogen peroxide-water type, and making its concentration lower and the etching time longer than usually.

The mechanical polishing is carried out by polishing using a buff formed using an abrasive grain of #3000 or an abrasive grain finer than that, a nonwoven fabric, and a resin.

The high-glossiness rolling can be carried out by rolling a metal material under such a condition that the oil film equivalent specified by the following expression is 12,000 or higher and 24,000 or lower.

Oil film equivalent={(rolling oil viscosity [cSt])×(plate passing speed [mpm]+roll peripheral speed [mpm])}/{(roll bite angle [rad])×(material yield stress [kg/mm²])}

The rolling oil viscosity [cSt] is a kinematic viscosity at 40° C. In order to make the oil film equivalent to be 12,000 to 24,000, a well-known method may be used such as using a low-viscosity rolling oil or making the plate passing speed slow.

The surface-treated metal material according to the present invention may have a 60° glossiness of lower than 10%. According to such a constitution, such an effect is caused that conductive heat, radiant heat, convective heat and the like absorbed from a heat generating body are better absorbed. The 60° glossiness is more preferably 9% or lower, further preferably 8% or lower, further preferably 7% or lower, and further preferably 5% or lower. Although there is no need to especially establish the lower limit of the 60° glossiness, the 60° glossiness is typically, for example, 0.001% or higher, for example, 0.01% or higher, for example 0.05% or higher, and for example, 0.1% or higher.

In the surface-treated metal material according to the present invention, the treated surface layer may contain a metal. According to such a constitution, the contact resistance is made lower than that of a treated surface layer formed of a resin. The metal contained in the treated surface layer includes, for example, copper, gold, silver, platinum-group metals, chromium, phosphorus, zinc, arsenic, nickel, cobalt, tungsten, tin and molybdenum. In the surface-treated metal material according to the present invention, the treated surface layer preferably contains a metal and/or an alloy the oxides of which have a ΔL of −30 or lower. Examples of the metal and/or the alloy the oxides of which have a ΔL of −30 or lower include nickel, cobalt, tungsten and tin, and include alloys containing one or more elements selected from the group consisting of nickel, cobalt, zinc, tin, tungsten and tin. The above-mentioned nickel, cobalt, tungsten and tin and alloys containing one or more elements selected from the group consisting of nickel, cobalt, zinc, tin, tungsten and tin may contain copper. Here, ΔL of an oxide can be measured also by fabricating a layer of the powdery oxide and measuring ΔL of the layer of the oxide. This is because when a treated surface layer is formed by plating or the like, the color difference of the surface of a metal material is enabled to be controlled by making a part of the metal become an oxide.

The treated surface layer according to the present invention may be constituted by forming a Ni—Zn alloy plating layer or a Co—Zn alloy plating layer on the surface of a metal material. The Ni—Zn alloy plating layer or the Co—Zn alloy plating layer can be obtained, for example, by a wet plating such as electroplating, electroless plating or immersion plating. Electroplating is preferable from the viewpoint of the cost. Alternatively, the treated surface layer according to the present invention may be constituted by forming a Ni plating layer and a Ni—Zn alloy plating layer or a Co—Zn alloy plating layer in this order on the surface of a metal material.

The condition of the Ni—Zn alloy plating or the Co—Zn alloy plating is described below.
Plating solution composition: a Ni concentration or Co concentration of 15 to 60 g/L, and a Zn concentration of 3 to 15 g/L
pH: 3.5 to 5.0
Temperature: 25 to 55° C.
Current density: 0.2 to 3.0 A/dm²
Plating time: 4 to 181 sec, preferably 9 to 181 sec, more preferably 15 to 181 sec, and still more preferably 20 to 181 sec
Ni deposition amount or Co deposition amount: 700 μg/dm² or larger and 20,000 μg/dm² or smaller, preferably 1,400 μg/dm² or larger and 20,000 μg/dm² or smaller, preferably 2,000 μg/dm² or larger and 20,000 μg/dm² or smaller, and preferably 4,000 μg/dm² or larger and 20,000 μg/dm² or smaller
Zn deposition amount: 600 μg/dm² or larger and 25,000 μg/dm² or smaller, preferably 1,100 μg/dm² or larger and 24,000 μg/dm² or smaller, preferably 2,200 μg/dm² or larger and 23,000 μg/dm² or smaller, and preferably 4,000 μg/dm² or larger and 22,000 μg/dm² or smaller
Ni ratio, Co ratio or the total ratio of Ni and Co: preferably 7.5% or higher and 90% or lower, preferably 15% or higher and 85% or lower, preferably 20% or higher and 82% or lower, and more preferably 23% or higher and 80.2% or lower.

The above-mentioned Ni—Zn alloy plating layer or Co—Zn alloy plating layer may contain one or more elements selected from the group consisting of W, Sn and Cu.

The condition of the Ni plating is described below.
Plating solution composition: a Ni concentration of 15 to 40 g/L
pH: 2 to 4
Temperature: 30 to 50° C.
Current density: 0.1 to 3.0 A/dm²
Plating time: 0.1 to 60 sec

Here, the remainder of a treatment solution used in desmearing treatment, electrolysis, surface treatment, plating, or the like used in the present invention is water unless otherwise specified.

Further the treated surface layer according to the present invention may be constituted by forming a black resin on the surface of a metal material. The black resin can be formed, for example, by making a black coating material infiltrated in an epoxy resin, and applying and drying the epoxy resin in a predetermined thickness.

Further the treated surface layer according to the present invention can be formed by providing a primary particle layer (Cu) and a secondary particle layer (copper-cobalt-nickel alloy plating or the like) under the following plating condition as the surface treatment on a metal material.

### (A) Formation of a Primary Particle Layer (Cu Plating)

Solution composition: Cu of 10 to 40 g/L, and sulfuric acid of 60 to 100 g/L

Solution temperature: 25 to 30° C.

Current density: 1 to 70 A/dm²

Coulomb quantity: 2 to 90 As/dm²

### (B) Formation of a Secondary Particle Layer (Cu—Co—Ni Alloy Plating)

Solution composition: copper of 10 to 20 g/L, nickel of 1 to 15 g/L, and cobalt of 1 to 15 g/L

pH: 2 to 4

Solution temperature: 30 to 50° C.

Current density: 10 to 60 A/dm² or 10 to 50 A/dm²

Coulomb quantity: 10 to 80 As/dm²

Further the treated surface layer according to the present invention can also be formed by providing a secondary particle layer under the above plating condition without forming a primary particle layer (Cu) as the surface treatment on a metal material. In this case, the current density needs to be made higher (for example, 35 to 60 A/dm²) than conventionally and the plating time needs to be made shorter (for example, 0.1 to 1.5 sec, preferably 0.2 to 1.4 sec) than conventionally.

In the case of using the above treated surface layer, the upper limit of the Ni deposition amount can be made to be typically 3,000 μg/dm² or smaller, more preferably 1,400 μg/dm² or smaller, and more preferably 1,000 μg/dm² or smaller. The lower limit of the Ni deposition amount can be made to be typically 50 μg/dm² or larger, more preferably 100 μg/dm² or larger, and more preferably 300 μg/dm² or larger.

In the case of the above treated surface layer, the upper limit of the Co deposition amount can be made to be typically 5,000 μg/dm² or smaller, more preferably 3,000 μg/dm² or smaller, more preferably 2,400 μg/dm² or smaller, and more preferably 2,000 μg/dm² or smaller. The lower limit of the Co deposition amount can be made to be typically 50 μg/dm² or larger, more preferably 100 μg/dm² or larger, and more preferably 300 μg/dm² or larger. Further in the case where the treated surface layer has, in addition to a Cu—Co—Ni alloy plating layer, a layer containing Co and/or Ni, the total deposition amount of Ni and the total deposition amount of Co in the whole treated surface layer can be made in the above-mentioned ranges.

Between a metal material and a treated surface layer, an underlayer may be provided as long as not inhibiting a plating constituting a treated surface layer.

The treated surface layer may contain a roughening-treated layer, and may contain a chromium layer or a chromate layer, and/or a silane-treated layer. The order of forming the roughening-treated layer, the chromium layer or the chromate layer and the silane-treated layer is not especially limited, and can be determined according to applications. It is usually preferable that a roughening-treated layer, a chromium layer or chromate layer and a silane-treated layer be formed in this order on the surface of the metal material, because the heat resistance and the corrosion resistance of the roughening-treated layer become good.

A laminate such as a shielding tape or a shielding material can be manufactured by laminating the surface-treated metal material according to the present invention on a resin substrate. Further as required, a printed wiring board or the like can be manufactured by forming circuits by processing the metal material. Resin substrates usable are, for example, for rigid PWBs, paper base phenol resins, paper base epoxy resins, synthetic fiber fabric base epoxy resins, glass fabric-paper composite base epoxy resins, glass fabric-glass nonwoven fabric composite base epoxy resins, glass fabric base epoxy resins and the like, and for FPCs and tapes, polyester films, polyimide films, liquid crystal polymers (LCP), PET films and the like. Here, in the present invention, “printed wiring boards” are regarded as also including printed wiring boards, printed circuit boards and printed boards installed with components. A printed wiring board of two or more printed wiring boards connected can be manufactured by connecting two or more of the printed wiring boards according to the present invention; further, at least one printed wiring board according to the present invention and another printed wiring board according to the present invention or a printed wiring board not according to the present invention can be connected; and electronic devices can also be manufactured using such printed wiring boards. In the present invention, “copper circuits” are regarded as also including copper wiring.

Processed metal members can further be fabricated by using the surface-treated metal material according to the present invention for heat releasing plates, structural plates, shielding materials, shielding plates, reinforcing materials, covers, chassis, cases, boxes and the like. The surface-treated metal material according to the present invention is especially preferably used as a heat releasing plate because the metal material is very excellent as a metal material for heat release since being good in heat absorbency and absorbed-heat releasability, heat being from a heat generating body.

The processed metal members fabricated using the surface-treated metal material according to the present invention for the heat releasing plates, structural plates, shielding materials, shielding plates, reinforcing materials, covers, chassis, cases, boxes and the like can be used for electronic devices.

[Metal Foil with a Carrier]

A metal foil with a carrier as another embodiment according to the present invention has a middle layer and an ultrathin metal layer in this order on one surface or both surfaces of a carrier. Then, the ultrathin metal layer is the surface-treated metal material as one embodiment according to the present invention as described above.

<Carrier>

A carrier usable in the present invention is typically a metal foil or a resin film, and is provided, for example, in a form of a copper foil, a copper alloy form, a nickel foil, a nickel alloy foil, an iron foil, an iron alloy foil, a stainless steel foil, an aluminum foil, an aluminum alloy foil, an insulating resin film (for example, a polyimide film, a liquid crystal polymer (LCD) film, a polyethylene terephthalate (PET) film, a polyamide film, a polyester film, or a fluororesin film).

A carrier usable in the present invention is preferably a copper foil. This is because the formation of a middle layer and an ultrathin metal layer thereafter becomes easy since the copper foil has a high electroconductivity. A carrier is usually provided in a form of a rolled copper foil or an electrodeposited copper foil. The electrodeposited copper foil is usually manufactured by electrodepositing copper from a copper sulfate plating bath on a titanium or stainless steel drum; and the rolled copper foil is usually manufactured by repeating a plastic working by a rolling roll and a heat treatment. Copper foil materials usable are, in addition to high-purity copper such as tough pitch copper and oxygen-free copper, for example, Sn-containing copper, Ag-containing copper, copper alloys having Cr, Zr, Mg or the like added therein, and copper alloys such as Corson-based copper alloys having Ni, Si and the like added therein.

The thickness of a carrier usable in the present invention is not especially limited, but the thickness may suitably be adjusted to a thickness suitable to function as a carrier, and can be made to be, for example 5 μm or larger. However, since being too thick raises the production cost, the thickness is usually preferably 35 μm or smaller. Therefore, the thickness of a carrier is typically 12 to 70 μm, and more typically 18 to 35 μm.

The surface roughness Rz and the glossiness of the surface of an ultrathin metal layer after the surface treatment can be controlled by controlling the surface roughness Rz and the glossiness of the side of the carrier used in the present invention on which a middle layer is formed.

It is also important that for a carrier used in the present invention, the roughness (Rz) in TD and the glossiness of the surface of the side of the carrier before the middle layer formation on which a middle layer is to be formed are previously controlled. Specifically, the surface roughness (Rz) in TD of a carrier before the middle layer formation is 0.20 to 0.80 μm, and preferably 0.20 to 0.50 μm; and the glossiness at an incident angle of 60° in the rolling direction (MD) is 350 to 800%, and preferably 500 to 800%. Such a copper foil can be fabricated by carrying out rolling by regulating the oil film equivalent of a rolling oil (high-gloss rolling), by carrying out chemical polishing such as chemical etching or electropolishing in a phosphoric acid solution, or by adding a predetermined additive to thereby manufacture an electrodeposited copper foil. By making the surface roughness (Rz) in TD and the glossiness of a copper foil before the treatment to be in the above ranges, the surface roughness (Rz) of the copper foil after the treatment can easily be controlled.

In a carrier before the middle layer formation, the 60° glossiness in MD is preferably 500 to 800%, more preferably 501 to 800%, and still more preferably 510 to 750%. If the 60° glossiness in MD of a copper foil before the surface treatment is lower than 500%, there arises a risk that Rz becomes higher than that in a case of 500% or higher; and if exceeding 800%, there arises a risk that the manufacture becomes difficult.

The high-glossiness rolling can be carried out by making the oil film equivalent specified by the following expression to be 13,000 or higher and 18,000 or lower.

Oil film equivalent={(rolling oil viscosity [cSt])×(plate passing speed [mpm]+roll peripheral speed [mpm])}/{(roll bite angle [rad])×(material yield stress [kg/mm²])}

The rolling oil viscosity [cSt] is a kinematic viscosity at 40° C.

In order to make the oil film equivalent to be 13,000 to 18,000, a well-known method may be used such as using a low-viscosity rolling oil or making the plate passing speed slow.

An electrodeposited copper foil whose surface roughness Rz and glossiness are made to be in the above ranges can be fabricated by the following method. The electrodeposited copper foil can be used as a carrier.

<Electrolytic Solution Composition>

Copper: 90 to 110 g/L

Sulfuric acid: 90 to 110 g/L

Chlorine: 50 to 100 ppm

Leveling agent 1 (bis(3-sulfopropyl)disulfide): 10 to 30 ppm

Leveling agent 2 (an amine compound): 10 to 30 ppm

As the amine compound, an amine compound of the following formula can be used.

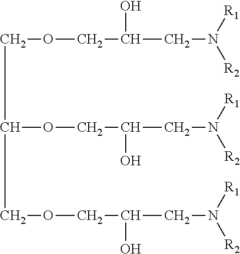

wherein R₁ and R₂ are selected from the group consisting of a hydroxyalkyl group, an ether group, an aryl group, an aromatic-substituted alkyl group, an unsaturated hydrocarbon group and an alkyl group.

<Manufacturing Condition>

Current density: 70 to 100 A/dm²

Electrolytic solution temperature: 50 to 60° C.

Electrolytic solution linear velocity: 3 to 5 m/sec

Electrolysis time: 0.5 to 10 min (adjusted according to the copper thickness to be deposited, and the current density)

Then, a roughening-treated layer may be provided on the surface of the opposite side to the surface of the side of a carrier on which an ultrathin metal layer is to be provided. The roughening-treated layer may be provided using a well-known method, or may be provided using the above-mentioned roughening treatment. The case where a roughening-treated layer is provided on the surface of the opposite side to the surface of the side of a carrier on which an ultrathin metal layer is to be provided has such an advantage that when the carrier is laminated on a supporter such as a resin substrate from the surface side having the roughening-treated layer, the carrier and the resin substrate hardly exfoliate.

<Middle Layer>

A middle layer is provided on the carrier. Another layer may be provided between the carrier and the middle layer. The middle layer used in the present invention is not especially limited as long as having such a constitution that whereas an ultrathin metal layer hardly exfoliates from the carrier before a lamination step of a metal foil with the carrier on an insulating substrate, the ultrathin metal layer is allowed to exfoliate from the carrier after the lamination step on the insulating substrate. For example, a middle layer of the metal foil with a carrier according to the present invention may contain one or two or more selected from the group consisting of Cr, Ni, Co, Fe, Mo, Ti, W, P, Cu, Al, Zn, alloys thereof, hydrates thereof, oxides thereof, and organic substances. Alternatively, a middle layer may be constituted of a plurality of layers.

Further, for example, a middle layer can be constituted by forming, from the carrier side, a single metal layer composed of one element selected from the element group consisting of Cr, Ni, Co, Fe, Mo, Ti, W, P, Cu, Al and Zn, or an alloy layer composed of one or two or more elements selected from the element group consisting of Cr, Ni, Co, Fe, Mo, Ti, W, P, Cu, Al and Zn, and forming thereon, a layer composed of a hydrate(s) or an oxide(s) of one or two or more elements selected from the element group consisting of Cr, Ni, Co, Fe, Mo, Ti, W, P, Cu, Al and Zn, or an organic substance(s).

Further, for example, a middle layer can be constituted by forming, from the carrier side, a single metal layer composed of one element selected from the element group consisting of Cr, Ni, Co, Fe, Mo, Ti, W, P, Cu, Al and Zn, or an alloy layer composed of one or two or more elements selected from the element group consisting of Cr, Ni, Co, Fe, Mo, Ti, W, P, Cu, Al and Zn, and forming thereon, a single metal layer composed of one element selected from the element group consisting of Cr, Ni, Co, Fe, Mo, Ti, W, P, Cu, Al and Zn, or an alloy layer composed of one or two or more elements selected from the element group consisting of Cr, Ni, Co, Fe, Mo, Ti, W, P, Cu, Al and Zn.

Further, a middle layer can use a well-known organic substance as the above organic substance, and one or more of a nitrogen-containing organic compound, a sulfur-containing organic compound and a carboxylic acid are preferably used. As specific examples of the nitrogen-containing organic compounds, preferably used are 1,2,3-benzotriazole, carboxybenzotriazole, N′,N′-bis(benzotriazolylmethyl)urea, 1H-1,2,4-triazole, 3-amino-1H-1,2,4-triazole and the like, which are triazole compounds having a substituent.

As the sulfur-containing organic compound, preferably used are mercaptobenzothiazole, sodium 2-mercaptobenzothiazole, thiocyanuric acid, 2-benzoimidazolethiol and the like.

As the carboxylic acids, especially preferably used are monocarboxylic acids; and among these, preferably used are oleic acid, linoleic acid, linolenic acid and the like.

Further, for example, a middle layer can be constituted by laminating a nickel layer, nickel-phosphorus alloy layer or nickel-cobalt alloy layer, and a chromium-containing layer in this order on a carrier. Since the adhesive force between nickel and copper is higher than that between chromium and copper, when an ultrathin metal layer is peeled off, the peeling-off comes to be caused at the interface between the ultrathin metal layer and the chromium-containing layer. Further nickel of the middle layer is expected to have a barrier effect of preventing the copper component from diffusing from the carrier to the ultrathin metal layer. The deposition amount of nickel in a middle layer is preferably 100 μg/dm² or larger and 40,000 μg/dm² or smaller, further preferably 100 μg/dm² or larger and 4,000 μg/dm² or smaller, further preferably 100 μg/dm² or larger and 2,500 μg/dm² or smaller, and further preferably 100 μg/dm² or larger and smaller than 1,000 μg/dm²; and the deposition amount of chromium in the middle layer is preferably 5 μg/dm² or larger and 100 μg/dm² or smaller. In the case where a middle layer is provided only on one surface, it is preferable that a rust prevention layer such as a Ni plating layer be provided on the opposite surface of the carrier. A chromium layer in the middle layer can be provided by chromium plating or chromate treatment.

If the thickness of a middle layer is too large, there arise some cases where the thickness of the middle layer has an influence on the surface roughness Rz and the glossiness of the surface of an ultrathin metal layer after the surface treatment; so the thickness of the middle layer is preferably 1 to 1,000 nm, preferably 1 to 500 nm, preferably 2 to 200 nm, preferably 2 to 100 nm, and more preferably 3 to 60 nm. Here, the middle layer may be provided on both surfaces of the carrier.

<Ultrathin Metal Layer>

An ultrathin metal layer is provided on the middle layer. Another layer may be provided between the middle layer and the ultrathin metal layer. The ultrathin metal layer having the carrier is the surface-treated metal material as one embodiment according to the present invention. The thickness of an ultrathin metal layer is not especially limited, but is usually thinner than the carrier, and is, for example, 12 μm or smaller. The thickness is typically 0.5 to 12 μm, and more typically 1.5 to 5 μm. In order to reduce pinholes of an ultrathin metal layer, strike plating using a copper-phosphorus alloy or the like may be carried out before the ultrathin metal layer is provided on the middle layer. A strike plating includes a copper pyrophosphate plating solution. Here, an ultrathin metal layer may be provided on both surfaces of the carrier. An ultrathin metal layer may be an ultrathin metal layer which comprises a metal, such as copper, a copper alloy, aluminum, an aluminum alloy, iron, an iron alloy, nickel, a nickel alloy, gold, a gold alloy, silver, a silver alloy, a platinum-group metal, a platinum-group metal alloy, chromium, a chromium alloy, magnesium, a magnesium alloy, tungsten, a tungsten alloy, molybdenum, a molybdenum alloy, lead, a lead alloy, a tantalum, a tantalum alloy, tin, a tin alloy, indium, an indium alloy, zinc and a zinc alloy, having a heat conductivity of 32 W/(m·K) or higher, or which is composed of the metal(s), or which is a metal material being well-known and having a heat conductivity of 32 W/(m·K) or higher. Further also a metal material which is one standardized in JIS Standard, CDA or the like and has a heat conductivity of 32 W/(m·K) or higher can be used as an ultrathin metal layer. An ultrathin copper layer is preferably used as an ultrathin metal layer. This is because an ultrathin copper layer has a high electroconductivity and is suitable for applications to circuits and the like.

The ultrathin metal layer according to the present invention may be an ultrathin copper layer formed under the following condition. This is to control the surface roughness Rz and the glossiness of the ultrathin copper layer surface by forming a smooth ultrathin copper layer.

Electrolytic Solution Composition

Copper: 80 to 120 g/L

Sulfuric acid: 80 to 120 g/L

Chlorine: 30 to 100 ppm

Leveling agent 1 (bis(3-sulfopropyl)disulfide): 10 to 30 ppm

Leveling agent 2 (an amine compound): 10 to 30 ppm

As the amine compound, an amine compound of the following formula can be used.

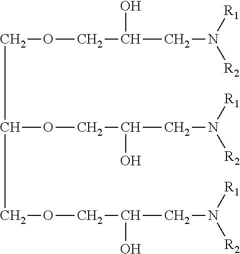

wherein R₁ and R₂ are selected from the group consisting of a hydroxyalkyl group, an ether group, an aryl group, an aromatic-substituted alkyl group, an unsaturated hydrocarbon group and an alkyl group.

Manufacturing Condition

Current density: 70 to 100 A/dm²

Electrolytic solution temperature: 50 to 65° C.

Electrolytic solution linear velocity: 1.5 to 5 m/sec

Electrolysis time: 0.5 to 10 min (adjusted according to the copper thickness to be deposited, and the current density)

[Resin Layer on the Treated Surface]

A resin layer may be provided on the treated surface of the surface-treated metal material according to the present invention. The resin layer may be an insulating resin layer. The “treated surface” in the surface-treated metal material according to the present invention, in the case where surface treatments are carried out to provide a heat resistance layer, a rust prevention layer, a weather resistance layer and the like after roughening treatment, refers to the surface of the surface-treated metal material after the surface treatments have been carried out. Further the “treated surface”, in the case where the surface-treated metal material is an ultrathin metal layer of a metal foil with a carrier and in the case where surface treatments are carried out to provide a heat resistance layer, a rust prevention layer, a weather resistance layer and the like after roughening treatment, refers to the surface of the ultrathin metal layer after the surface treatments have been carried out.

The resin layer may be an adhesive agent, and may be an insulating resin layer for adhesion in a semi-cured state (B-stage state). The semi-cured state (B-stage state) involves such states that there occurs no tackiness feeling even if its surface is touched with a finger; the insulating resin layers can be superposed for storage; and the curing reaction occurs if being further subjected to a heat treatment.

The resin layer may be a resin for adhesion, that is, an adhesive agent, and may be an insulating resin layer for adhesion in a semi-cured state (B-stage state). The semi-cured state (B-stage state) involves such states that there occurs no tackiness feeling even if its surface is touched with a finger; the insulating resin layers can be superposed for storage; and the curing reaction occurs if being further subjected to a heat treatment.

The resin layer may contain a thermosetting resin, or may be a thermoplastic resin. Further the resin layer may contain a thermoplastic resin. The resin layer may contain well-known resins, resin curing agents, compounds, curing accelerators, dielectrics, reaction catalysts, crosslinking agents, polymers, prepregs, aggregates, and the like. The resin layers may be formed using methods and apparatuses for forming substances (resins, resin curing agents, compounds, curing accelerators, dielectrics, reaction catalysts, crosslinking agents, polymers, prepregs, aggregates, and the like) and/or resin layers described in, for example, International Publication No. WO2008/004399, International Publication No. WO2008/053878, International Publication No. WO2009/084533, Japanese Patent Laid-Open No. 11-5828, Japanese Patent Laid-Open No. 11-140281, Japanese Patent No. 3184485, International Publication No. WO97/02728, Japanese Patent No. 3676375, Japanese Patent Laid-Open No. 2000-43188, Japanese Patent No. 3612594, Japanese Patent Laid-Open No. 2002-179772, Japanese Patent Laid-Open No. 2002-359444, Japanese Patent Laid-Open No. 2003-304068, Japanese Patent No. 3992225, Japanese Patent Laid-Open No. 2003-249739, Japanese Patent No. 4136509, Japanese Patent Laid-Open No. 2004-82687, Japanese Patent No. 4025177, Japanese Patent Laid-Open No. 2004-349654, Japanese Patent No. 4286060, Japanese Patent Laid-Open No. 2005-262506, Japanese Patent No. 4570070, Japanese Patent Laid-Open No. 2005-53218, Japanese Patent No. 3949676, Japanese Patent No. 4178415, International Publication No. WO2004/005588, Japanese Patent Laid-Open No. 2006-257153, Japanese Patent Laid-Open No. 2007-326923, Japanese Patent Laid-Open No. 2008-111169, Japanese Patent No. 5024930, International Publication No. WO2006/028207, Japanese Patent No. 4828427, Japanese Patent Laid-Open No. 2009-67029, International Publication No. WO2006/134868, Japanese Patent No. 5046927, Japanese Patent Laid-Open No. 2009-173017, International Publication No. WO2007/105635, Japanese Patent No. 5180815, International Publication No. WO2008/114858, International Publication No. WO2009/008471, Japanese Patent Laid-Open No. 2011-14727, International Publication No. WO2009/001850, International Publication No. WO2009/145179, International Publication No. WO2011/068157, and Japanese Patent Laid-Open No. 2013-19056.

The kind of the resin layer is not especially limited, but favorably includes resins containing one or more selected from the group of, for example, epoxy resins, polyimide resins, polyfunctional cyanate ester compounds, maleimide compounds, polymaleimide compounds, maleimide-based resins, aromatic maleimide resins, polyvinylacetal resins, urethane resins, polyether sulfones, polyether sulfone resins, aromatic polyamide resins, aromatic polyamide resin polymers, rubbery resins, polyamines, aromatic polyamines, polyamidoimide resins, rubber-modified epoxy resins, phenoxy resins, carboxyl group-modified acrylonitrile-butadiene resins, polyphenylene oxides, bismaleimide triazine resins, thermosetting polyphenylene oxide resins, cyanate ester-based resins, anhydrides of carboxylic acids, anhydrides of polyvalent carboxylic acids, liner polymers having a crosslinkable functional group(s), polyphenylene ether resins, 2,2-bis(4-cyanatophenyl)propane, phosphorus-containing phenolic compounds, manganese naphthenate, 2,2-bis(4-glycidylphenyl)propane, polyphenylene ether-cyanate-based resins, siloxane-modified polyamidoimide resins, cyanoester resins, phosphazene-based resins, rubber-modified polyamidoimide resins, isoprene, hydrogenated polybutadienes, polyvinyl butyrals, phenoxy, polymeric epoxy, aromatic polyamides, fluororesins, bisphenols, block copolymerized polyimide resins, and cyanoester resins.

The above epoxy resins can be used especially with no problem as long as having two or more epoxy groups in their molecule, and being usable in applications to electric and electronic materials. The epoxy resins are preferably epoxy resins obtained by epoxidation using a compound having two or more glycidyl groups in its molecule. The epoxy resins can be used by mixing one or two or more selected from the group of bisphenol A type epoxy resins, bisphenol F type epoxy resins, bisphenol S type epoxy resins, bisphenol AD type epoxy resins, novolac type epoxy resins, cresol novolac type epoxy resins, cycloaliphatic epoxy resins, brominated epoxy resins, phenol novolac type epoxy resins, naphthalene type epoxy resins, brominated bisphenol A type epoxy resins, orthocresol novolac type epoxy resins, rubber-modified bisphenol A type epoxy resins, glycidylamine type epoxy resins, compounds of glycidylamine such as triglycidyl isocyanurate or N,N-diglycidylaniline, compounds of glycidyl ester such as diglycidyl tetrahydrophthalate ester, phosphorus-containing epoxy resins, biphenyl type epoxy resins, biphenyl novolac type epoxy resins, trishydroxyphenylmethane type epoxy resins, and tetraphenylethane type epoxy resins; or hydrogenated and halogenated resins of the epoxy resins can be used.

As the phosphorus-containing epoxy resins, well-known epoxy resins having phosphorus can be used. The phosphorus-containing epoxy resins are preferably, for example, epoxy resins obtained as derivatives from 9,10-dihydro-9-oxa-10-phosphaphenanthrene-10-oxide, which has two or more epoxy groups in its molecule.

(A Case where the Resin Layer Contains a Dielectric (Dielectric Filler))

The resin layer may contain a dielectric (dielectric filler).

In the case where a dielectric (dielectric filler) is made to be contained in one of the above resin layers or resin compositions, the resin layer or the resin composition is used for an application to form a capacitor layer, which can increase the electric capacity of a capacitor circuit. As the dielectric (dielectric filler), a dielectric powder of a compound oxide having a perovskite structure, such as BaTiO3, SrTiO3, Pb(Zr—Ti)O3 (common name: PZT), PbLaTiO3.PbLaZrO (common name: PLZT) and SrBi2Ta2O9 (common name: SBT), is used.

The dielectric (dielectric filler) may be powdery. In the case where a dielectric (dielectric filler) is powdery, with respect to the powder property of the dielectric (dielectric filler), the particle diameter is in the range of 0.01 μm to 3.0 μm, and preferably in the range of 0.02 μm to 2.0 μm. Here, when a photograph of a dielectric is taken by a scanning electron microscope (SEM), and straight lines are drawn across a particle of the dielectric on the photograph, a length of a portion, giving a longest straight line length among the straight lines crossing the particle of the dielectric, of the particle of the dielectric is taken to be a diameter of the particle of the dielectric. Then, an average value of diameters of particles of the dielectric in the measured view is taken as a particle diameter of the dielectric.

Resins and/or resin compositions and/or compounds contained in the above-mentioned resin layer are dissolved in a solvent such as methyl ethyl ketone (MEK), cyclopentanone, dimethylformamide, dimethylacetoamide, N-methylpyrrolidone, toluene, methanol, ethanol, propylene glycol monomethyl ether, dimethylformamide, dimethylacetoamide, cyclohexanone, ethyl cellosolve, N-methyl-2-pyrrolidone, N,N-dimethylacetoamide or N,N-dimethylformamide to thereby make a resin solution (resin vanish); the resin solution is applied on the roughening-treated surface of the surface-treated metal material, for example, by a roll coater method; then, as required, the applied resin solution is heated and dried to remove the solvent to thereby make a B stage state. The drying may use, for example, a hot air drying oven, and the drying temperature may be 100 to 250° C., and preferably 130 to 200° C. A composition of the resin layer may be dissolved using a solvent to thereby make a resin solution whose resin solid content is 3% by weight to 70% by weight, preferably 3% by weight to 60% by weight, preferably 10% by weight to 40% by weight, and more preferably 25% by weight to 40% by weight. It is most preferable at this stage from the environmental viewpoint that the dissolution be carried out using a mixed solvent of methyl ethyl ketone and cyclopentanone. Here, as the solvent, a solvent having a boiling point in the range of 50° C. to 200° C. is preferably used.

The resin layer is preferably a semi-cured resin film whose resin flow measured according to MIL-P-13949G of MIL Standards is in the range of 5% to 35%.

In the present description, the resin flow refers to a value acquired by sampling 4 sheets of a 10 cm-square specimen from the surface-treated metal material with a resin whose resin thickness is made to be 55 μm, laminating the 4 specimen sheets made into a superposed state (laminate) under the condition of a press temperature of 171° C., a press pressure of 14 kgf/cm² and a press time of 10 min, and calculating a resin flow based on Expression 1 from a measurement result of a resin outflow weight at this time, according to MIL-P-13949G of MIL Standards.

$$Resin flow ( \% ) = \frac{resin outflow weight}{( laminate weight - copper foil weight )} \times 100 \qquad [ Expression 1 ]$$

The surface-treated metal material having the resin layer (surface-treated metal material with a resin) is used in such a mode that the resin layer is superposed on a base material and thereafter wholly thermally pressure-bonded to thereby thermally cure the resin layer; then, in the case where the surface-treated metal material is an ultrathin metal layer of a metal foil with a carrier, the carrier is peeled off to expose the ultrathin metal layer (naturally, exposed is the surface of the middle layer side of the ultrathin metal layer), and a predetermined wiring pattern is formed on the surface of the opposite side to the side of the surface-treated metal material having been subjected to a roughening treatment.

If the surface-treated metal material with a resin is used, the number of prepreg material sheets to be used in manufacture of a multilayer printed wiring board can be reduced. Moreover, the thickness of the resin layer can be made to a thickness allowing securing interlayer insulation, and a metal-clad laminated plate can be manufactured without using any prepreg material at all. Then, the smoothness of the surface of the base material can also be improved further by undercoating an insulating resin on the surface of the base material.

The case of using no prepreg material is economically advantageous because the material cost of a prepreg material is saved and a lamination step is made simpler, and furthermore has such an advantage that the thickness of a multilayer printed wiring board to be manufactured is made thinner by the thickness of the prepreg material, and a ultrathin multilayer printed wiring board whose each one layer thickness is 100 μm or smaller can be manufactured.

The thickness of the resin layer is preferably 0.1 to 120 μm.

If the thickness of the resin layer is thinner than 0.1 μm, the adhesive force decreases, and when the surface-treated metal material with the resin is laminated on a base material having an inner layer material without a prepreg material being interposed therebetween, the interlayer insulation between the metal material and circuits of the inner layer material becomes difficult to secure in some cases. By contrast, if the thickness of the resin layer is made thicker than 120 μm, the resin layer of a target thickness becomes difficult to form by one-time application step, leading to an economic disadvantage in some cases because an extra material cost and manpower are necessitated.

In the case where the surface-treated metal material having a resin layer is used for manufacture of an ultrathin multilayer printed wiring board, the thickness of the resin layer is made to be preferably 0.1 μm to 5 μm, further preferably 0.5 μm to 5 μm, and further preferably 1 μm to 5 μm, in order to reduce the thickness of the multilayer printed wiring board.

Hereinafter, some examples of manufacture processes of a printed wiring board using the metal foil with a carrier according to the present invention will be described.

One embodiment of the method for manufacturing a printed wiring board according to the present invention comprises the steps of providing the metal foil with a carrier according to the present invention and an insulating substrate; laminating the metal foil with a carrier and the insulating substrate; after the metal foil with a carrier and the insulating substrate are laminated so that an ultrathin metal layer side of the metal foil faces the insulating substrate, peeling off the carrier of the metal foil with a carrier to thereby form a copper-clad laminated plate; and thereafter forming circuits by any one process of a semi-additive process, a modified semi-additive process, a partly additive process and a subtractive process. The insulating substrate can be one containing inner layer circuits.

In the present invention, the semi-additive process refers to a process in which a thin electroless plating is applied on an insulating substrate or a metal foil seed layer; a pattern is formed; and thereafter, a conductor pattern is formed using electroplating or etching.

Therefore, one embodiment of the method for manufacturing a printed wiring board according to the present invention using a semi-additive process comprises the steps of providing the metal foil with a carrier according to the present invention and an insulating substrate; laminating the metal foil with a carrier and the insulating substrate; after the metal foil with a carrier and the insulating substrate are laminated, peeling off the carrier of the metal foil with a carrier; entirely removing an ultrathin metal layer exposed by the peeling-off of the carrier by a process such as etching using a corrosive solution such as an acid or plasma; providing through-holes and/or blind vias in the resin exposed by the removal by etching of the ultrathin metal layer; subjecting a region containing the through-holes and/or the blind vias to a desmearing treatment; providing an electroless plating layer on the resin and the region containing the through-holes and/or the blind vias; providing a plating resist on the electroless plating layer; exposing the plating resist and thereafter removing the plating resist in a region where circuits are to be formed; providing an electroplating layer on the region where the plating resist has been removed and the circuits are to be formed; removing the plating resist; and removing the electroless plating layer in the region excluding the region where the circuits are to be formed, by flash etching or the like.

Another embodiment of the method for manufacturing a printed wiring board according to the present invention using a semi-additive process comprises the steps of providing the metal foil with a carrier according to the present invention and an insulating substrate; laminating the metal foil with a carrier and the insulating substrate; after the metal foil with a carrier and the insulating substrate are laminated, peeling off the carrier of the metal foil with a carrier; entirely removing an ultrathin metal layer exposed by the peeling-off of the carrier by a process such as etching using a corrosive solution such as an acid or plasma; providing an electroless plating layer on the surface of the resin exposed by the removal by etching of the ultrathin metal layer; providing a plating resist on the electroless plating layer; exposing the plating resist and thereafter removing the plating resist in a region where circuits are to be formed; providing an electroplating layer on the region where the plating resist has been removed and the circuits are to be formed; removing the plating resist; and removing the electroless plating layer and the ultrathin metal layer in the region excluding the region where the circuits are to be formed, by flash etching or the like.

In the present invention, the modified semi-additive process refers to a process in which a metal foil is laminated on an insulating layer; a circuit-non-forming portion is protected by a plating resist; a copper electroplating is thickly applied on a circuit-forming portion; the resist is thereafter removed; and the metal foil excluding the circuit-forming portion is removed by (flash) etching to thereby form circuits on the insulating layer.

Therefore, one embodiment of the method for manufacturing a printed wiring board according to the present invention using a modified semi-additive process comprises the steps of providing the metal foil with a carrier according to the present invention and an insulating substrate; laminating the metal foil with a carrier and the insulating substrate; after the metal foil with a carrier and the insulating substrate are laminated, peeling off the carrier of the metal foil with a carrier; providing through-holes and/or blind vias in an ultrathin metal layer exposed by the peeling-off of the carrier and in the insulating substrate; subjecting a region containing the through-holes and/or the blind vias to a desmearing treatment; providing an electroless plating layer on the region containing the through-holes and/or the blind vias; providing a plating resist on the surface of the ultrathin metal layer exposed by the peeling-off of the carrier; after the plating resist has been provided, forming circuits by electroplating; removing the plating resist; and removing the ultrathin metal layer exposed by the removal of the plating resist, by flash etching.

The step of forming circuits on the resin layer may be a step in which another metal foil with a carrier is laminated on the resin layer from the ultrathin metal layer side, and the circuits are formed by using the metal foil with a carrier laminated on the resin layer. Further the another metal foil with a carrier to be laminated on the resin layer may be the metal foil with a carrier according to the present invention. Further the step of forming circuits on the resin layer may be carried out by any one process of a semi-additive process, a subtractive process, a partly additive process and a modified semi-additive process. Further the metal foil with a carrier on whose surface circuits are to be formed may have a substrate or a resin layer on the surface of the carrier of the metal foil with a carrier.

Another embodiment of the method for manufacturing a printed wiring board according to the present invention using a modified semi-additive process comprises the steps of providing the metal foil with a carrier according to the present invention and an insulating substrate; laminating the metal foil with a carrier and the insulating substrate; after the metal foil with a carrier and the insulating substrate are laminated, peeling off the carrier of the metal foil with a carrier; providing a plating resist on an ultrathin metal layer exposed by the peeling-off of the carrier; exposing the plating resist, and thereafter removing the plating resist in a region where circuits are to be formed; providing an electroplating layer in the region where the plating resist has been removed and the circuits are to be formed; removing the plating resist; and removing the electroless plating layer and the ultrathin metal layer in the region excluding the region where the circuits are to be formed, by flash etching or the like.

In the present invention, the partly additive process refers to a process in which catalyst nuclei are imparted on a substrate provided with a conductor layer, as required on a substrate having holes for through-holes or via-holes drilled therein; conductor circuits are formed by etching; as required, a solder resist or plating resist is provided; and thereafter, an electroless plating is thickly applied on the through-holes, the via-holes or the like on the conductor circuits to thereby manufacture a printed wiring board.

Therefore, one embodiment of the method for manufacturing a printed wiring board according to the present invention using a partly additive process comprises the steps of providing the metal foil with a carrier according to the present invention and an insulating substrate; laminating the metal foil with a carrier and the insulating substrate; after the metal foil with a carrier and the insulating substrate are laminated, peeling off the carrier of the metal foil with a carrier; providing through-holes and/or blind vias in an ultrathin metal layer exposed by the peeling-off of the carrier and in the insulating substrate; subjecting a region containing the through-holes and/or the blind vias to a desmearing treatment; imparting catalyst nuclei to the region containing the through-holes and/or the blind vias; providing an etching resist on the surface of the ultrathin metal layer exposed by the peeling-off of the carrier; exposing the etching resist to thereby form a circuit pattern; removing the ultrathin metal layer and the catalyst nuclei by a process such as etching using a corrosive solution such as an acid or plasma to thereby form circuits; removing the etching resist; providing a solder resist or a plating resist on the surface of the insulating substrate exposed by the removal of the ultrathin metal layer and the catalyst nuclei by the process such as etching using the corrosive solution such as an acid or plasma; and providing an electroless plating layer on the region where the solder resist or the plating resist has not been provided.

In the present invention, the subtractive process refers to a process in which unnecessary portions of a copper foil on a copper-clad laminated plate are selectively removed by etching or the like to thereby form a conductor pattern.

Therefore, one embodiment of the method for manufacturing a printed wiring board according to the present invention using a subtractive process comprises the steps of providing the metal foil with a carrier according to the present invention and an insulating substrate; laminating the metal foil with a carrier and the insulating substrate; after the metal foil with a carrier and the insulating substrate are laminated, peeling off the carrier of the metal foil with a carrier; providing through-holes and/or blind vias in an ultrathin metal layer exposed by the peeling-off of the carrier and in the insulating substrate; subjecting a region containing the through-holes and/or the blind vias to a desmearing treatment; providing an electroless plating layer in the region containing the through-holes and/or the blind vias; providing an electroplating layer on the surface of the electroless plating layer; providing an etching resist on the surface of the electroplating layer and/or the ultrathin metal layer; exposing the etching resist to thereby form circuit patterns; removing the ultrathin metal layer, the electroless plating layer and the electroplating layer by a process such as etching using a corrosive solution such as an acid or plasma to thereby form circuits; and removing the etching resist.

Another embodiment of the method for manufacturing a printed wiring board according to the present invention using a subtractive process comprises the steps of providing the metal foil with a carrier according to the present invention and an insulating substrate; laminating the metal foil with a carrier and the insulating substrate; after the metal foil with a carrier and the insulating substrate are laminated, peeling off the carrier of the metal foil with a carrier; providing through-holes and/or blind vias in an ultrathin metal layer exposed by the peeling-off of the carrier and in the insulating substrate; subjecting a region containing the through-holes and/or the blind vias to a desmearing treatment; providing an electroless plating layer in the region containing the through-holes and/or the blind vias; providing a mask on a surface of the electroless plating layer; providing an electroplating layer on the surface of the electroless plating layer where the mask has not been formed; providing an etching resist on the surface of the electroplating layer and/or the ultrathin metal layer; exposing the etching resist to thereby form a circuit pattern; removing the ultrathin metal layer and the electroless plating layer by a process such as etching using a corrosive solution such as an acid or plasma to thereby form circuits; and removing the etching resist.

The step of providing through-holes and/or blind vias and the desmearing step thereafter may not be carried out.

Here, a specific example of a method for manufacturing a printed wiring board by using the metal foil with a carrier according to the present invention will be described in detail. The description will be made by herein taking, as an example, the metal foil with a carrier having an ultrathin metal layer having a roughening-treated layer formed thereon; but the metal foil with a carrier is not limited thereto, and even if a metal foil with a carrier having an ultrathin metal layer having no roughening-treated layer formed thereon is used, the following method for manufacturing a printed wiring board can be carried out similarly.

First, a metal foil with a carrier (first layer) having an ultrathin metal layer having a roughening-treated layer formed on the surface of the ultrathin metal layer is provided.

Then, a resist is applied on the roughening-treated layer of the ultrathin metal layer, exposed and developed, and etched into a predetermined shape.

Then, a plating for circuits is formed, and thereafter the resist is removed to thereby form a circuit plating of a predetermined shape.

Then, a resin layer is laminated by providing an embedding resin on the ultrathin metal layer so as to cover the circuit plating (so the circuit plating as to be embedded), and another metal foil with a carrier (second layer) is then adhered from the ultrathin metal layer side.

Then, the carrier is peeled off the metal foil with a carrier as the second layer.

Then, laser drilling is carried out at a predetermined position of the resin layer to expose the circuit plating to thereby form blind vias.

Then, copper is embedded in the blind vias to thereby form via fills.

Then, a circuit plating is formed on the via fills as described above.

Then, the carrier is peeled off the metal foil with a carrier as the first layer.

Then, the ultrathin metal layers of both the surfaces are removed by flash etching to thereby expose the surfaces of the circuit platings in the resin layer.

Then, bumps are formed on the circuit platings in the resin layer, and copper pillars are formed on the solders. A printed wiring board using the metal foil with a carrier according to the present invention is thus fabricated.

The another metal foil with a carrier (second layer) to be used may be the metal foil with a carrier according to the present invention, may be a conventional metal foil with a carrier, or may be a usual copper foil. Further on the circuits of the second layer, circuits may be formed in one layer or in a plurality of layers; and the formation of these circuits may be carried out by any one process of a semi-additive process, a subtractive process, a partly additive process and a modified semi-additive process.

In the metal foil with a carrier according to the present invention, the color difference of the surface of the ultrathin metal layer is preferably controlled so as to satisfy the following (1). In the present invention, the “color difference of the surface of the ultrathin metal layer” refers to a color difference of the surface of the ultrathin metal layer or in the case where various types of surface treatments such as roughening treatment are carried out, a color difference of the surface of the treated surface layer. That is, in the metal foil with a carrier according to the present invention, the color difference of the roughening-treated surface of the ultrathin metal layer is preferably controlled so as to satisfy the following (1). Here, in the surface-treated metal material according to the present invention, a “roughening-treated surface” refers to, in the case where after a roughening treatment, surface treatments in order to provide a heat resistance layer, a rust prevention layer, a weather resistance layer and the like are carried out, the surface of the surface-treated metal material (ultrathin metal layer) after the surface treatments have been carried out. Further in the case where the surface-treated metal material is an ultrathin metal layer of a metal foil with a carrier, a “roughening-treated surface” refers to, in the case where after a roughening treatment, surface treatments in order to provide a heat resistance layer, a rust prevention layer, a weather resistance layer and the like are carried out, the surface of the ultrathin metal layer after the surface treatments have been carried out. (1) The color difference ΔE*ab based on JIS Z8730 of the surface of an ultrathin metal layer is 45 or larger.

Here, the color differences ΔL, Δa, Δb are each measured by a color difference meter, and are general indices indicated using the L*a*b color space based on JIS Z8730 in the color space of black/white/red/green/yellow/blue, and are represented as ΔL: white-black, Δa: red-green and Δb: yellow-blue. ΔE*ab is represented by the following expression by using these color differences.

ΔE*ab=\sqrt{ΔL²+Δa²+Δb²} [Expression 2]

The above-mentioned color difference can be regulated by raising the current density, reducing the copper concentration in a plating solution, and raising the linear velocity of the plating solution, in the formation time of an ultrathin metal layer.

The above-mentioned color difference can also be regulated by subjecting the surface of an ultrathin metal layer to a roughening treatment to thereby provide a roughening-treated layer. In the case of providing a roughening-treated layer, the color differences can be regulated by using an electrolytic solution containing copper and one or more elements selected from the group consisting of nickel, cobalt, tungsten and molybdenum, and making the current density higher (for example, 40 to 60 A/dm²) and the treatment time shorter (for example, 0.1 to 1.3 sec) than conventionally. In the case of providing no roughening-treated layer on the surface of an ultrathin metal layer, the color difference can be achieved by using a plating bath in which the concentration of Ni is made to be two or more times those of other elements, and carrying out a Ni alloy plating (for example, Ni—W alloy plating, Ni—Co—P alloy plating or Ni—Zn alloy plating) on the surface of an ultrathin metal layer, a heat resistance layer, a rust prevention layer, a chromate-treatment layer or a silane coupling treatment layer at a lower current density (0.1 to 1.3 A/dm²) and for a longer treatment time (20 to 40 sec) than conventionally.

If the color difference ΔE*ab based on JIS Z8730 of the surface of an ultrathin metal layer is 45 or higher, for example, when circuits are formed on the ultrathin metal layer surface of a metal foil with a carrier, the contrast between the ultrathin metal layer and the circuits becomes distinct, and consequently, the visibility becomes good and the alignment of the circuits can be carried out well precisely. The color difference ΔE*ab based on JIS Z8730 of the surface of an ultrathin metal layer is preferably 50 or higher, more preferably 55 or higher, and still more preferably 60 or higher.

In the case where the color difference of the surface of an ultrathin metal layer is controlled as described above, the contrast to circuit plating becomes distinct and the visibility becomes good. Therefore, in a process of manufacturing a printed wiring board as described above, circuit plating is enabled to be formed well precisely at a predetermined position. According to the method for manufacturing a printed wiring board as described above, since the circuit plating has a constitution embedded in a resin layer, for example when an ultrathin metal layer is removed by flash etching, the circuit plating is protected by the resin layer and its shape is held, and the formation of microcircuits thereby becomes easy. Since the circuit plating is protected by the resin layer, the migration resistance is improved and the conduction of wiring of circuits is well suppressed. Hence, the formation of microcircuits becomes easy. When the ultrathin metal layer is removed by flash etching, since the exposed surface of the circuit plating assumes a shape recessed from the resin layer, bumps, further copper pillars thereon, are easily formed on the circuit plating and the manufacture efficiency is improved.

Here, as the embedding resin, a well-known resin and prepreg can be used. For example, a BT (bismaleimide triazine) resin, a prepreg which is a glass fabric impregnated with a BT resin, and an ABF film and ABF, manufactured by Ajinomoto Fine-Techno Co., Inc. can be used. Further for the embedding resin, a resin layer and/or a resin and/or a prepreg described in the present description can be used.

A metal foil with a carrier used as the first layer may have a substrate or a resin layer on the surface of the metal foil with a carrier. When a metal foil with a carrier has the substrate or the resin layer, since the metal foil with a carrier used as the first layer is supported and hardly generates wrinkles, the productivity is advantageously improved. Here, the substrate or the resin layer usable is every substrate or resin layer as long as the every substrate or resin layer has an effect of supporting the metal foil with a carrier used as the first layer. As the substrate or resin layer, usable are a carrier, prepreg and resin layer described in the present description, and a well-known carrier, prepreg, resin layer, metal plate, metal foil, plate of an inorganic compound, foil of an inorganic compound, plate of an organic compound and foil of an organic compound.

A laminate can be manufactured by laminating the surface-treated metal material according to the present invention on a resin substrate from the treated surface layer side. The resin substrate is not especially limited as long as having a property applicable to printed wiring boards and the like, but usable examples thereof are, for rigid PWBs, paper base phenol resins, paper base epoxy resins, synthetic fiber fabric base epoxy resins, fluororesin-impregnated cloths, glass fabric-paper composite base epoxy resins, glass fabric-glass nonwoven fabric composite base epoxy resins, glass fabric base epoxy resins and the like, and for flexible printed boards (FPCs), polyester films, polyimide films, liquid crystal polymer (LCP) films, fluororesins, fluororesin-polyimide composite materials and the like. Since the liquid crystal polymers (LCPs) have a low dielectric loss, liquid crystal polymer (LCP) films are preferably used for printed wiring boards for applications to high-frequency circuits.

The lamination method involves, in the case of a rigid PWB, providing a prepreg obtained by impregnating a base material such as a glass fabric with a resin, and curing the resin to a semi-cured state. Lamination can be carried out by stacking a copper foil on the prepreg, and heating and pressing the stacked prepreg. In the case of FPCs, a base material such as a liquid crystal polymer or a polyimide film is laminated and adhered on a copper foil under a high-temperature and a high-pressure through an adhesive agent or without using any adhesive agent, or a polyimide precursor is applied on a copper foil, and dried and cured or the like, to thereby enable to manufacture a laminate.

The laminate according to the present invention can be used for various types of printed wiring boards (PWBs); and the types are not especially limited, but the laminate can be applied to single-sided PWBs, double-sided PWBs and multilayer PWBs (3 or more layers) from the viewpoint of the number of layers of conductor patterns, and can be applied to rigid PWBs, flexible PWBs (FPCs) and rigid and flex PWBs from the viewpoint of the kind of insulating substrate materials.

### EXAMPLES

### Examples 1 to 21 and Comparative Examples 1 to 15

As Examples 1 to 21 and Comparative Examples 1 to 15, various types of metal materials having a thickness of 0.2 mm and heat conductivities described in Tables 1 to 3 were provided. Then, a surface treatment was carried out on the metal materials each to thereby form a treated surface layer. Here, the glossiness of the metal material before the surface treatment was so regulated that the glossiness of the surface thereof after the surface treatment became 20.

As a formation condition of the treated surface layer, a “Ni—Zn plating” in Tables 1 to 3 was formed under the following condition.
Plating solution composition: a Ni concentration of 21.5 g/L and a Zn concentration of 9 g/L
pH: 3.5
Temperature: 35° C.
Current density: 3 A/dm²
Plating time: 14 sec

As a formation condition of the treated surface layer, a “Ni plating” in Tables 1 to 3 was formed under the following condition. Here, in Tables 1 to 3, for example, cases described as “Ni plating of 1 μm” indicate that a Ni plating was formed by a thickness of 1 μm.
Plating solution composition: a Ni concentration of 40 g/L
pH: 3.8
Temperature: 40° C.
Current density: 0.3 A/dm²
Plating time: 25 to 300 sec

As a formation condition of the treated surface layer, a “Ni plating of 1 μm/Ni—Zn plating” in Tables 1 to 3 indicates that after a Ni plating was formed by a thickness of 1 μm, a Ni—Zn plating was carried out.

As a formation condition of the treated surface layer, a “black resin” in Tables 1 to 3 was formed by mixing an epoxy resin with a black coating material, applying the mixture by a predetermined thickness, and drying the applied mixture. Here, in Tables 1 to 3, for example, cases described as “black resin of 30 μm” indicate that the black resin was formed by a thickness of 30 μm.

### Examples 22 to 128, and Comparative Examples 16 to 43

As Examples 22 to 128 and Comparative Examples 16 to 43, various types of metal materials having a thickness of 0.2 mm and a heat conductivity described in Tables 4 to 11 were provided. Then, a plating formation as a surface treatment was carried out on the metal materials each under the plating condition described in Tables 4 to 11 to thereby form a treated surface layer. Here, the glossiness of the metal material before the surface treatment was so regulated that the glossiness of the surface thereof after the surface treatment became 20.

### Examples 129 to 137, and Comparative Examples 44 to 47

As Examples 129 to 137 and Comparative Examples 44 to 47, various types of metal materials having a thickness of 0.2 mm and a heat conductivity described in Table 12 were provided. Then, a primary particle layer (Cu) and a secondary particle layer (copper-cobalt-nickel alloy plating or the like) were formed as a surface treatment on the metal materials each under the plating conditions described in Table 12 to thereby form a treated surface layer.

Bath compositions and plating conditions used were as follows.

(A) Formation of a Primary Particle Layer (Cu Plating)

Solution composition: copper of 15 g/L and sulfuric acid of 75 g/L

Solution temperature: 25 to 30° C.

(B) Formation of a Secondary Particle Layer (Cu—Co—Ni Alloy Plating)

Solution composition: copper of 15 g/L, nickel of 8 g/L and cobalt of 8 g/L

pH: 2

Solution temperature: 40° C.

Examples where two sets of the current condition and the coulomb quantity are described in the primary particle current condition column in Table 12 are cases where after a plating was carried out under the condition described in the left, a plating was further carried out under the condition described in the right. For example, in the primary particle current condition column of Example 104, the condition is described as “(63 A/dm², 80 As/dm²)+(1 A/dm², 2 As/dm²)”, and this indicates that a plating to form primary particles was carried out at a current density of 63 A/dm² and at a coulomb quantity of 80 As/dm², and thereafter, a plating to form primary particles was further carried out at a current density of 1 A/dm² and at a coulomb quantity of 2 As/dm².

### Examples 138 to 140

As Examples 138 to 140, various types of metal materials having a thickness of 0.2 mm and a heat conductivity described in Table 13 were provided. Then, a treated surface layer was formed as a surface treatment on the metal materials each under the plating condition described in Table 13.

Bath compositions and plating conditions used were as follows.

Ni—W Plating

Plating solution composition: nickel of 25 g/L and tungsten of 20 mg/L

(the supply source of nickel was nickel sulfate hexahydrate, and the supply source of tungsten was sodium tangustate)

pH: 3.6 (an acid added to regulate the pH: sulfuric acid)

Solution temperature: 40° C.

Current density: 1 A/dm², Plating time: 100 sec

Ni of 21,000 μg/dm², and W of 21 μg/dm²

Co—Zn Plating

Plating solution composition: cobalt of 40 g/L and zinc of 15 g/L

pH: 3.8 (an acid added to regulate the pH: sulfuric acid)

Solution temperature: 40° C.

Current density: 0.3 A/dm², Plating time: 75 sec

Co of 2,812 μg/dm², and Zn of 4,645 μg/dm²

Ni—Zn—W Plating

Plating solution composition: nickel of 40 g/L, zinc of 15 g/L and tungsten of 20 mg/L

pH: 3.8 (an acid added to regulate the pH: sulfuric acid)

Solution temperature: 40° C.

Current density: 0.3 A/dm², Plating time: 75 sec

Ni of 2,712 μg/dm², Zn of 4,545 μg/dm², and W of 2.7 μg/dm²

### Examples 141 to 149

As Examples 141 to 149, various types of metal materials having a thickness of 0.2 mm and a heat conductivity described in Table 14 were provided. Then, an underlayer treatment described in Table 14, or no underlayer treatment was carried out on the metal materials each, and then, a treated surface layer was formed as a surface treatment thereon under the plating condition described in Table 14.

Each underlayer treatment condition of Table 14 was as follows.
The treatment of “copper roughening” involved carrying out the following (1) and (2) in this order to thereby form roughening particles:
   (1) Cu: 10 g/L, H₂SO₄: 60 g/L, temperature: 35° C., current density: 50 A/dm², and plating time: 1.5 sec
   (2) Cu: 23 g/L, H₂SO₄: 80 g/L, temperature: 40° C., current density: 8 A/dm², and plating time: 2.5 sec.
The treatment of “texturing” involved carrying out rolling by using a rolling roll having a large arithmetic average roughness Ra (rolling roll having an Ra of 0.20 μm or larger) as a rolling roll for the final cold rolling of a material to be plated on. The roughness may have been regulated so as to become the target roughness when the rolling roll was ground. The regulation of the roughness could be made by a well-known method. A material to be rolled was rolled by using the rolling roll to regulate the surface roughness of the material to thereby enable to finish the surface of the material to low gloss.
The treatment of “high-gloss plating” involved carrying out plating treatment under the condition of Cu: 90 g/L, H₂SO₄: 80 g/L, polyethylene glycol: 20 mg/L, disodium bis(3-sulfopropyl)disulfide: 50 mg/L, a mixture of dialkylamino group-containing polymers: 100 mg/L, temperature: 55° C., current density: 2 A/dm², and plating time: 200 sec.
The treatment of “soft etching” involved carrying out etching under the condition of H₂SO₂: 20 g/L, H₂SO₄: 160 g/L, temperature: 40° C., and immersion time: 5 min.

Here, for a metal material of no underlayer treatment, the glossiness before the surface treatment (after the underlayer treatment) was regulated by controlling the above-mentioned oil film equivalent at the rolling time. For a metal material having a high glossiness, the oil film equivalent of a low value in the above-mentioned range was used; and for a metal material having a low glossiness, the oil film equivalent of a high value in the above-mentioned range was used.

As base materials for Examples 150 to 154, copper foils with a carrier described below were provided.

For Examples 150 to 152 and 154, electrodeposited copper foils of 18 μm in thickness were provided as carriers; and for Example 153, a rolled copper foil (C1100, manufactured by JX Nippon Mining & Metals Corp.) of 18 μm in thickness was provided as a carrier. Then, under the following conditions, a middle layer was formed on the surface of the carriers each, and an ultrathin metal layer was formed on the surface of the middle layer. As required, the carrier was controlled by the above-mentioned method in the surface roughness Rz and the glossiness of the surface of the side of the carrier, before the middle layer was formed, on which the middle layer was to be formed.

### Example 150

### Middle Layer

### (1) A Ni Layer (Ni Plating)

Electroplating was carried out on the carrier by a roll-to-roll continuous plating line under the following condition to thereby form a Ni layer having a deposition amount of 1,000 μg/dm². The specific plating condition was as follows.

Nickel sulfate: 270 to 280 g/L

Nickel chloride: 35 to 45 g/L

Nickel acetate: 10 to 20 g/L

Boric acid: 30 to 40 g/L

Brightening agent: saccharin, butynediol, and the like

Sodium dodecylsulfate: 55 to 75 ppm

pH: 4 to 6

Bath temperature: 55 to 65° C.

Current density: 10 A/dm²

### (2) A Cr Layer (Electrolytic Chromate Treatment)

Then, after the surface of the Ni layer formed in (1) was washed with water and washed with an acid, a Cr layer having a deposition amount of 11 μg/dm² was successively deposited on the Ni layer by an electrolytic chromate treatment under the following condition on a roll-to-roll continuous plating line.

Potassium bichromate: 1 to 10 g/L, and zinc: 0 g/L

pH: 7 to 10

Solution temperature: 40 to 60° C.

Current density: 2 A/dm²

### <Ultrathin Copper Layer>

Then, after the surface of the Cr layer formed in (2) was washed with water and washed with an acid, an ultrathin copper layer having a thickness of 1.5 μm was successively formed on the Cr layer by an electroplating under the following condition on a roll-to-roll continuous plating line to thereby fabricate an ultrathin copper foil with a carrier.

Copper concentration: 90 to 110 g/L

Sulfuric acid concentration: 90 to 110 g/L

Chloride ion concentration: 50 to 90 ppm

Leveling agent 1 (bis(3-sulfopropyl)disulfide): 10 to 30 ppm

Leveling agent 2 (an amine compound): 10 to 30 ppm

The leveling agent 2 used was the following amine compound.

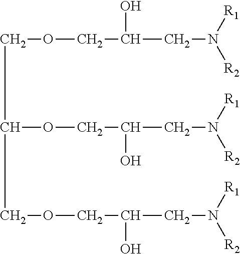

wherein R₁ and R₂ are selected from the group consisting of a hydroxyalkyl group, an ether group, an aryl group, an aromatic-substituted alkyl group, an unsaturated hydrocarbon group and an alkyl group.

Electrolytic solution temperature: 50 to 80° C.

Current density: 100 A/dm²

Electrolytic solution linear velocity: 1.5 to 5 m/sec

### Example 151

### Middle Layer

### (1) A Ni—Mo Layer (Nickel-Molybdenum Alloy Plating)

An electroplating was carried out on the carrier by a roll-to-roll continuous plating line under the following condition to thereby form a Ni—Mo layer having a deposition amount of 3,000 μg/dm². The specific plating condition was as follows.

(Solution composition) nickel sulfate hexahydrate: 50 g/dm³, sodium molybdate dihydrate: 60 g/dm³, and sodium citrate: 90 g/dm³

(Solution temperature) 30° C.

(Current density) 1 to 4 A/dm²

(Energized time) 3 to 25 sec

### <Ultrathin Copper Layer>

An ultrathin copper layer was formed on the Ni—Mo layer formed in (1). The ultrathin copper layer was formed under the same condition as in Example 150, except for altering the thickness of the ultrathin copper layer to 2 μm.

### Example 152

### Middle Layer

### (1) A Ni Layer (Ni Plating)

A Ni layer was formed under the same condition as in Example 150.

### (2) An Organic Substance Layer (Organic Substance Layer-Forming Treatment)

Then, after the surface of the Ni layer formed in (1) was washed with water and washed with an acid, an aqueous solution containing carboxybenzotriazole (CBTA) of a concentration of 1 to 30 g/L under the condition of a solution temperature of 40° C. and a pH of 5 was successively sprayed by showering for 20 to 120 sec on the surface of the Ni layer under the following condition to thereby form an organic substance layer.

### <Ultrathin Copper Layer>

An ultrathin copper layer was formed on the organic substance layer formed in (2). The ultrathin copper layer was formed under the same condition as in Example 150, except for altering the thickness of the ultrathin copper layer to 3 μm.

### Examples 153 and 154

### Middle Layer

### (1) A Co—Mo Layer (Cobalt-Molybdenum Alloy Plating)

An electroplating was carried out on the carrier by a roll-to-roll continuous plating line under the following condition to thereby form a Co—Mo layer having a deposition amount of 4,000 μg/dm². The specific plating condition was as follows.

(Solution composition) cobalt sulfate: 50 g/dm³, sodium molybdate dihydrate: 60 g/dm³, and sodium citrate: 90 g/dm³

(Solution temperature) 30° C.

(Current density) 1 to 4 A/dm²

(Energized time) 3 to 25 sec

### <Ultrathin Copper Layer>

An ultrathin copper layer was formed on the Co—Mo layer formed in (1). The ultrathin copper layer was formed under the same condition as in Example 150, except for altering the thickness of the ultrathin copper layer of Example 153 to 5 μm, and that of Example 154 to 3 μm.

For each sample fabricated as described above, various types of evaluations were made as follows.
Measurement of the color differences (ΔL, Δa, Δb, ΔE) based on JIS Z8730

The color differences (ΔL, Δa, Δb, ΔE) of the surface of a surface-treated metal material were measured using a color difference meter MiniScan XE Plus, manufactured by HunterLab Inc. Here, the color difference (ΔE) is a general index indicated using the L*a*b color space in the color space of black/white/red/green/yellow/blue, and is represented by the following expression where ΔL: white-black, Δa: red-green and Δb: yellow-blue. The color difference is calibrated by taking a measurement value of a white plate to be ΔE=0, and a measurement value thereof measured by covering the plate with a black bag and measuring it in the dark to be ΔE=90.

ΔE=\sqrt{ΔL²—Δa²+Δb²}

Glossiness:

The glossiness was measured at an incident angle of 60° by using a glossiness meter, Handy Gloss Meter PG-1, manufactured by Nippon Denshoku Industries Co., Ltd., according to JIS Z8741.

Contact Resistance:

The contact resistance was measured by a 4-terminal method under the following condition by using an electric contact simulator CRS-1, manufactured by Yamasaki-seiki Co., Ltd.

Probe: gold probe, contact load: 100 g, sliding velocity: 1 mm/min, sliding distance: 1 mm
Deposition amounts (μg/dm²) of Ni, Zn, Co and W, and the Ni ratio (%):

The deposition amounts (μg/dm²) of Ni, Zn, Co and W, and the Ni ratio (%) (=a Ni deposition amount (μg/dm²)/(the Ni deposition amount (μg/dm²)+a Zn deposition amount (μg/dm²))×100), which indicated a proportion of the Ni deposition amount (μg/dm²) to the total deposition amount (μg/dm²) of the Ni deposition amount and the Zn deposition amount, were each determined. Here, the Ni deposition amount, the Zn deposition amount, the Co deposition amount and the W deposition amount were measured by dissolving a sample in a nitric acid of 20% by mass in concentration, and carrying out a quantitative analysis by atomic absorption spectrometry by using an atomic absorption spectrometer (model: AA240FS), manufactured by Varian, Inc. Here, the measurement of the deposition amounts of the nickel (Ni), zinc (Zn), cobalt (Co) and tungsten (W) was carried out as follows. A prepreg (FR4) was thermally pressure-bonded on the surface of the side of a surface-treated metal material on which no surface treatment had been carried out; thereafter, a thickness of 2 μm of the surface of the side thereof on which the surface treatment had been carried out was dissolved, and the deposition amounts of nickel, zinc, cobalt and tungsten deposited on the surface of the side thereof on which the surface treatment had been carried out were measured. Then, the acquired deposition amounts of nickel, zinc, cobalt and tungsten were taken to be the deposition amounts of nickel, zinc, cobalt and tungsten of the roughening-treated surface (treated surface), respectively. Here, the thickness to be dissolved of the side of a surface-treated metal material on which the surface treatment had been carried out did not need to be exactly 2 μm, and the measurement may have been carried out by dissolving the treated-surface portion of a thickness (for example, 1.5 to 2.5 μm) by which the treated-surface portion was obviously entirely dissolved.

Further in the case where the metal material was a metal foil with a carrier, a prepreg (FR4) was thermally pressure-bonded and laminated on the surface of the carrier side; thereafter, the end parts of the metal foil with a carrier were masked with an acid-resistant tape or the like to thereby prevent dissolving-out of the middle layer; thereafter, the surface of the side of the surface-treated metal material (ultrathin metal layer) on which the surface treatment had been carried out was dissolved by a thickness of 0.5 μm in the case where the thickness of the ultrathin metal layer was 1.5 μm or larger, and by a thickness of 30% of a thickness of the ultrathin metal layer in the case where the thickness of the ultrathin metal layer was smaller than 1.5 μm; then, the measurement was carried out by carrying out the quantitative analysis by atomic absorption spectrometry using an atomic absorption spectrometer (model: AA240FS), manufactured by Varian, Inc.

Here, in the case where a sample was hardly dissolved in the nitric acid of 20% by mass in concentration, after the sample was dissolved in a solution which could dissolve the sample, such as a mixed solution of nitric acid and hydrochloric acid (nitric acid concentration: 20% by mass, hydrochloric acid concentration: 12% by mass), the above-mentioned measurement could be carried out.

Heat Absorbency and Heat Releasability in a Shielding Box

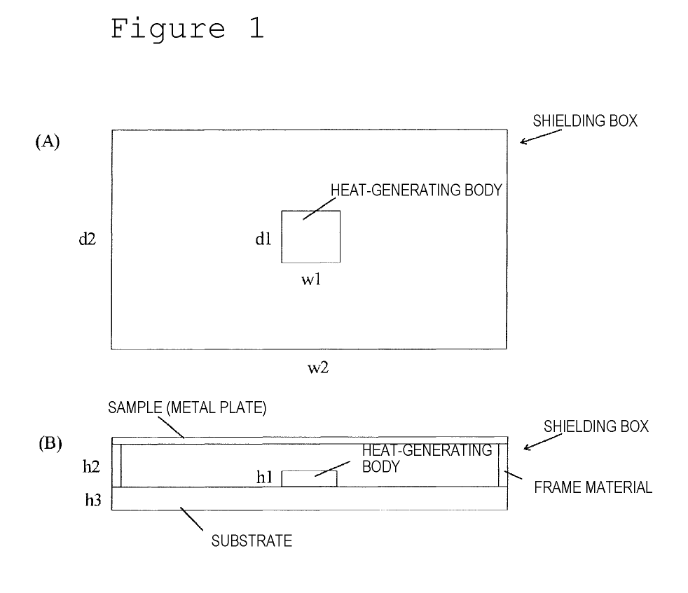

A shielding box was fabricated as follows: a substrate (FR4) of length d2×width w2×height h3=25 mm×50 mm×1 mm as shown in FIG. 1 was provided; a heat-generating body (heat-generating body in which an electric heating wire was solidified with a resin, corresponding to an IC chip) of length d1×width w1×height h1=5 mm×5 mm×0.5 mm was mounted on the center of the substrate surface; the circumference was covered with a frame material constituted of SUS and having a thickness of 0.2 mm; and a metal plate (surface-treated metal material) of each sample was installed as a ceiling plate so that the treated surface layer faced the heat-generating body. A thermocouple was installed at each of the center part and one of four corners of the upper surface of the heat-generating body. Further a thermocouple was installed at each of the center part and one of four corners of the surface of the heat-generating body side of the ceiling plate. Further a thermocouple was installed at each of the center part and one of four corners of the outer surface of the ceiling plate. FIG. 1(A) shows a schematic view of the upper surface of the shielding box fabricated in Examples. FIG. 1(B) shows a cross-sectional schematic view of the shielding box fabricated in Examples.

Then, a current was made to flow in the heat-generating body so that the generated heat quantity became 0.5 W. Then, a current was made to flow until the temperature of the central part of the upper surface of the heat-generating body assumed a constant value. Here, it was determined that at the time point at which the temperature of the central part of the upper surface of the heat-generating body did not change for 10 min, the temperature of the central part of the upper surface assumed a constant value. Meanwhile, the external environmental temperature of the shielding box was 20° C.

Then, after the temperature of the central part of the upper surface of the heat-generating body was held for 30 min after the temperature assumed the constant value, the indicated temperatures of the thermocouples were measured. For the thermocouples of the outer surface, a temperature difference of a maximum temperature−a minimum temperature was calculated. Maximum temperatures of the heat-generating body, the shield inner surface (the surface of the heat-generating body side of the ceiling plate) and the shield outer surface (the outer surface of the ceiling plate) were temperatures indicated by the thermocouples installed at the central parts thereof because these thermocouples were nearest the center of the heat-generating body. By contrast, minimum temperatures of the heat-generating body, the shield inner surface (the surface of the heat-generating body side of the ceiling plate) and the shield outer surface (the outer surface of the ceiling plate) were temperatures indicated by the thermocouples installed at their four corners because these thermocouples were farthest from the center of the heat-generating body.

The case where the maximum temperature of the heat-generating body was 150° C. or lower was so determined that the heat absorbency and the heat releasability of the shielding box were good. 150° C. was a temperature often established as an upper limit of the temperature range where IC chips could be used. Further the case where the difference between the maximum temperature and the minimum temperature of the shield outer surface was 13° C. or lower was so determined that the heat absorbency and the heat releasability of the shielding box were good. This was because in the case where the difference between the maximum temperature and the minimum temperature of the shield outer surface was small, it was conceivable that heat sufficiently diffused in a metal material and heat easily dissipated from the metal material.

Heat Conductivity

After a treated surface layer of a metal material was removed, the heat diffusivity α (m²/s) was measured by a flash method being an unstationary method. Here, the measurement of the heat diffusivity α was carried out by a half-time method.

Then, a heat conductivity λ (W/(K·m)) was calculated by the following expression.

λ=α×Cp×ρ (where Cp is a specific heat capacity (J/(kg·K)), and ρ is a density (kg/m³))

Here, the heat conductivity may be measured by a method other than the above method, or a well-known method.

Gloss (Designability)

By the visual observation of the surface of a sample, the designability was classified into “present”, “a little present” and “absent” according to the degree of the subjective designability feeling.

The conditions of the above tests and the test results are shown in Tables 1 to 14.

TABLE 1

| | Metal Material (thickness: 0.2 mm) | | | | | | | |
|---|---|---|---|---|---|---|---|---|
| | (% indicates mass %) | Heat | | | | | | |
| | (C-No. indicates an alloy number | Conductivity of | | | | | | |
| | standardized in JIS) | a Metal | Surface Treatment | | | | | Contact |
| | (an element having no % indication | Material | Surface | Color Difference | | | | Resistance |
| | indicates the remainder) | (W/m · K) | Treatment | ΔL | Δa | Δb | ΔE | (mΩ) |
| Example 1 | German silver (C7521, Cu—Ni: 18%- | 33 | Ni—Zn plating | −43.1 | 0.2 | −0.3 | 43.1 | 4.2 |
| | Zn: 18%) | | | | | | | |
| Example 2 | titanium copper (C1990, Cu—Ti: 3%) | 54 | Ni—Zn plating | −43.1 | 0.2 | −0.3 | 43.1 | 4.2 |
| Example 3 | phosphor bronze (C5102, Cu—Sn: 5%- | 71 | Ni—Zn plating | −43.1 | 0.2 | −0.3 | 43.1 | 4.2 |
| | P: trace) | | | | | | | |
| Example 4 | nickel | 90.9 | Ni—Zn plating | −43.1 | 0.2 | −0.3 | 43.1 | 4.2 |
| Example 5 | brass (C2600, Cu—Zn: 30%) | 121 | Ni—Zn plating | −43.1 | 0.2 | −0.3 | 43.1 | 4.1 |
| Example 6 | red brass (Cu—Zn: 17%) | 150 | Ni—Zn plating | −43.1 | 0.2 | −0.3 | 43.1 | 4.2 |
| Example 7 | magnesium | 159 | Ni—Zn plating | −43.1 | 0.2 | −0.3 | 43.1 | 4.2 |
| Example 8 | red brass (Cu—Zn: 8%-Sn: 0.3%) | 173 | Ni—Zn plating | −43.1 | 0.2 | −0.3 | 43.1 | 4.3 |
| Example 9 | Corson alloy (C7025, Cu—Ni: 3.0%- | 180 | Ni—Zn plating | −43.1 | 0.2 | −0.3 | 43.1 | 4.2 |
| | Si: 0.65%-Mg: 0.15%) | | | | | | | |
| Example 10 | aluminum | 204 | Ni—Zn plating | −43.1 | 0.2 | −0.3 | 43.1 | 4.2 |

| | | | | | Shield Outer Surface | | |
|---|---|---|---|---|---|---|---|
| | Chip Temperature | | Shield Inner Surface | | (° C.) | | |
| | (° C.) | | (° C.) | | | | Temperature |
| | Minimum | Maximum | Minimum | Maximum | Minimum | Maximum | Difference |
| Example 1 | 128.7 | 148.0 | 38.6 | 51.8 | 38.8 | 51.8 | 13.0 |
| Example 2 | 127.3 | 146.5 | 39.9 | 48.3 | 40.1 | 48.3 | 8.3 |
| Example 3 | 126.6 | 145.8 | 40.3 | 47.0 | 40.6 | 47.0 | 6.4 |
| Example 4 | 126.3 | 145.4 | 41.0 | 46.0 | 40.6 | 46.0 | 5.4 |
| Example 5 | 125.9 | 145.1 | 41.0 | 45.2 | 41.3 | 45.2 | 3.9 |
| Example 6 | 125.7 | 144.8 | 41.0 | 44.6 | 41.5 | 44.6 | 3.1 |
| Example 7 | 125.6 | 144.7 | 41.2 | 44.5 | 41.6 | 44.5 | 2.9 |
| Example 8 | 125.5 | 144.6 | 41.3 | 44.3 | 41.6 | 44.3 | 2.8 |
| Example 9 | 125.5 | 144.7 | 41.4 | 44.2 | 41.7 | 44.2 | 2.6 |
| Example 10 | 125.4 | 144.5 | 41.4 | 44.0 | 41.8 | 44.0 | 2.3 |

TABLE 2

| | Metal Material (thickness: 0.2 mm) | | | | | | |
|---|---|---|---|---|---|---|---|
| | (% indicates mass %) | | | | | | |
| | (C-No. indicates an alloy number | Heat | | | | | |
| | standardized in JIS) | Conductivity of a | Surface Treatment | | | | |
| | (an element having no % indication | Metal Material | | Color Difference | | | |
| | indicates the remainder) | (W/m · K) | Surface Treatment | ΔL | Δa | Δb | ΔE |
| Example | Corson alloy (Cu—Co: 1.9%—Si: 0.44%) | 260 | Ni—Zn plating | −43.1 | 0.2 | −0.3 | 43.1 |
| 11 | | | | | | | |
| Example | Corson alloy (Cu—Co: 1.9%—Si: 0.44%) | 260 | Ni plating: 1-μm/Ni—Zn | −43.1 | 0.2 | −0.3 | 43.1 |
| 12 | | | plating | | | | |
| Example | Corson alloy (Cu—Co: 1.9%—Si: 0.44%) | 260 | Ni plating: 5-μm/Ni—Zn | 43.1 | 0.2 | −0.3 | 43.1 |
| 13 | | | plating | | | | |
| Example | Corson alloy (Cu—Co: 1.9%—Si: | 260 | black resin: 30-μm | −43.6 | 0.3 | 0.3 | 43.6 |
| 14 | 0.44%) + black resin tape: 30-μm | | | | | | |
| Example | Corson alloy (Cu—Co: 1.9%—Si: | 260 | black resin: 100-μm | −43.6 | 0.3 | 0.3 | 43.6 |
| 15 | 0.44%) + black resin tape: 100-μm | | | | | | |
| Example | Corson alloy (Cu—Co: 1.9%—Si: | 260 | black resin: 200-μm | −43.6 | 0.3 | 0.3 | 43.6 |
| 16 | 0.44%) + black resin tape: 200-μm | | | | | | |
| Example | copper alloy (C194, Cu—Fe: 2.2%—P: 0.03%—Zn: | 284 | Ni—Zn plating | −43.1 | 0.2 | −0.3 | 43.1 |
| 17 | 0.15%) | | | | | | |
| Example | copper alloy (Cu—Fe: 0.3%—P: 0.1%) | 311 | Ni—Zn plating | −43.1 | 0.2 | −0.3 | 43.1 |
| 18 | | | | | | | |
| Example | copper alloy (Cu—Sn: 0.12%) | 350 | Ni—Zn plating | −43.1 | 0.2 | −0.3 | 43.1 |
| 19 | | | | | | | |
| Example | tough pitch copper (C1100, Cu: 99.90% or | 387 | Ni—Zn plating | −43.1 | 0.2 | −0.3 | 43.1 |
| 20 | more) | | | | | | |
| Example | silver | 418 | Ni—Zn plating | −43.1 | 0.2 | −0.3 | 43.1 |
| 21 | | | | | | | |

| | Contact | Chip Temperature | | Shield Inner Surface | | Shield Outer Surface (° C.) | | |
|---|---|---|---|---|---|---|---|---|
| | Resistance | (° C.) | | (° C.) | | | | Temperature |
| | (mΩ) | Minimum | Maximum | Minimum | Maximum | Minimum | Maximum | Difference |
| Example | 4.2 | 125.2 | 144.3 | 41.4 | 43.7 | 41.9 | 43.7 | 1.8 |
| 11 | | | | | | | | |
| Example | 4.4 | 125.2 | 144.4 | 41.4 | 43.7 | 41.9 | 43.7 | 1.8 |
| 12 | | | | | | | | |
| Example | 4.6 | 125.2 | 144.4 | 41.4 | 43.7 | 41.9 | 43.7 | 1.8 |
| 13 | | | | | | | | |
| Example | 0.9 × 10¹¹ | 125.4 | 144.6 | 41.5 | 44.2 | 41.9 | 43.7 | 1.8 |
| 14 | | | | | | | | |
| Example | 1.0 × 10¹¹ | 125.7 | 144.9 | 41.5 | 45.6 | 41.9 | 43.7 | 1.8 |
| 15 | | | | | | | | |
| Example | 1.0 × 10¹¹ | 126.2 | 145.4 | 41.5 | 47.4 | 41.8 | 43.7 | 1.9 |
| 16 | | | | | | | | |
| Example | 4.2 | 125.2 | 144.3 | 41.6 | 43.6 | 42.0 | 43.6 | 1.6 |
| 17 | | | | | | | | |
| Example | 4.2 | 125.2 | 144.3 | 41.6 | 43.6 | 42.0 | 43.6 | 1.6 |
| 18 | | | | | | | | |
| Example | 4.2 | 125.1 | 144.2 | 41.7 | 43.3 | 42.1 | 43.3 | 1.2 |
| 19 | | | | | | | | |
| Example | 4.2 | 125.1 | 144.2 | 41.7 | 43.3 | 42.1 | 43.3 | 1.2 |
| 20 | | | | | | | | |
| Example | 4.2 | 125.0 | 144.1 | 41.8 | 43.4 | 42.2 | 43.4 | 1.2 |
| 21 | | | | | | | | |

TABLE 3

| | Metal Material (thickness: 0.2 mm) | Heat | | | | | |
|---|---|---|---|---|---|---|---|
| | (% indicates mass %) | Conductivity | | | | | |
| | (C-No. indicates an alloy number standardized in JIS) | of a Metal | Surface Treatment | | | | |
| | (an element having no % indication indicates the | Material | | Color Difference | | | |
| | remainder) | (W/m · K) | Surface Treatment | ΔL | Δa | Δb | ΔE |
| Comparative | SUS304 (Fe—Cr: 18%—Ni: 8%) | 16 | none | −27.3 | 3.6 | 3.3 | 27.7 |
| Example 1 | | | | | | | |
| Comparative | SUS304 (Fe—Cr: 18%—Ni: 8%) | 16 | Ni—Zn plating | −43.1 | 0.2 | −0.3 | 43.1 |
| Example 2 | | | | | | | |
| Comparative | SUS304 (Fe—Cr: 18%—Ni: 8%) + adhesive tape + graphite | 16 | Ni—Zn plating | −42.2 | 0.3 | 0.1 | 42.2 |
| Example 3 | sheet | | | | | | |
| Comparative | titanium | 17 | Ni—Zn plating | −43.1 | 0.2 | −0.3 | 43.1 |
| Example 4 | | | | | | | |
| Comparative | titanium alloy (Ti—Al: 6-mass %—V: 4-mass %) | 7.5 | Ni—Zn plating | −43.1 | 0.2 | −0.3 | 43.1 |
| Example 5 | | | | | | | |
| Comparative | vanadium | 30.7 | Ni—Zn plating | −43.1 | 0.2 | −0.3 | 43.1 |
| Example 6 | | | | | | | |
| Comparative | manganese | 7.81 | Ni—Zn plating | −43.1 | 0.2 | −0.3 | 43.1 |
| Example 7 | | | | | | | |
| Comparative | nickel alloy (Ni—Mo: 28%—Fe: 5%—Cr: 1%—Mn: 2%—Si: 1%) | 11.1 | Ni—Zn plating | −43.1 | 0.2 | −0.3 | 43.1 |
| Example 8 | | | | | | | |
| Comparative | nickel alloy (Ni—Mo: 17%—Fe: 7%—Cr: 16%—W: 3%) | 12.5 | Ni—Zn plating | −43.1 | 0.2 | −0.3 | 43.1 |
| Example 9 | | | | | | | |
| Comparative | copper alloy (Cu—Ni: 46%) | 19.5 | Ni—Zn plating | −43.1 | 0.2 | −0.3 | 43.1 |
| Example 10 | | | | | | | |
| Comparative | nickel alloy (Ni—Cr: 21%) | 13 | Ni—Zn plating | −43.1 | 0.2 | −0.3 | 43.1 |
| Example 11 | | | | | | | |
| Comparative | nickel alloy (Ni—Cu: 33%—Fe: 2%) | 21 | Ni—Zn plating | −43.1 | 0.2 | −0.3 | 43.1 |
| Example 12 | | | | | | | |
| Comparative | iron alloy (Fe—Si: 2%—Mn: 0.9%—Cu: 0.6%—C: 0.5%) | 25 | Ni—Zn plating | −43.1 | 0.2 | −0.3 | 43.1 |
| Example 13 | | | | | | | |
| Comparative | manganese | 7.8 | Ni—Zn plating | −43.1 | 0.2 | −0.3 | 43.1 |
| Example 14 | | | | | | | |
| Comparative | Corson alloy (Cu—Co: 1.9%—Si: 0.44%) | 260 | none | −22.1 | 27.2 | 18.4 | 39.6 |
| Example 15 | | | | | | | |

| | Contact | Chip Temperature | | Shield Inner Surface | | Shield Outer Surface (° C.) | | |
|---|---|---|---|---|---|---|---|---|
| | Resistance | (° C.) | | (° C.) | | | | Temperature |
| | (mΩ) | Minimum | Maximum | Minimum | Maximum | Minimum | Maximum | Difference |
| Comparative | 55.2 | 151.4 | 172.2 | 37.1 | 59.8 | 37.1 | 59.7 | 22.6 |
| Example 1 | | | | | | | | |
| Comparative | 4.2 | 139.3 | 159.8 | 37.9 | 63.5 | 38.1 | 63.4 | 25.3 |
| Example 2 | | | | | | | | |
| Comparative | 4.2 | 129.7 | 149.5 | 44.0 | 46.9 | 43.8 | 46.8 | 3.0 |
| Example 3 | | | | | | | | |
| Comparative | 4.2 | 139.0 | 159.4 | 38.2 | 62.5 | 38.4 | 62.5 | 24.1 |
| Example 4 | | | | | | | | |
| Comparative | 4.2 | 138.5 | 165.7 | 27.8 | 63.8 | 28.0 | 64.3 | 36.3 |
| Example 5 | | | | | | | | |
| Comparative | 4.2 | 131.7 | 152.6 | 41.8 | 56.4 | 42.0 | 56.4 | 14.4 |
| Example 6 | | | | | | | | |
| Comparative | 4.2 | 138.4 | 165.6 | 28.7 | 63.6 | 28.9 | 64.1 | 35.2 |
| Example 7 | | | | | | | | |
| Comparative | 4.2 | 137.7 | 159.0 | 27.6 | 61.5 | 27.8 | 61.9 | 34.1 |
| Example 8 | | | | | | | | |
| Comparative | 4.1 | 137.5 | 158.7 | 27.5 | 60.9 | 27.7 | 61.2 | 33.5 |
| Example 9 | | | | | | | | |
| Comparative | 4.2 | 136.6 | 157.7 | 36.3 | 58.4 | 36.5 | 58.6 | 22.1 |
| Example 10 | | | | | | | | |
| Comparative | 4.3 | 137.4 | 158.6 | 28.5 | 60.6 | 28.7 | 61.0 | 32.3 |
| Example 11 | | | | | | | | |
| Comparative | 4.2 | 136.4 | 157.5 | 37.4 | 58.0 | 37.6 | 58.2 | 20.6 |
| Example 12 | | | | | | | | |
| Comparative | 4.2 | 136.1 | 157.1 | 39.5 | 57.1 | 39.7 | 57.2 | 17.5 |
| Example 13 | | | | | | | | |
| Comparative | 4.2 | 138.4 | 165.6 | 28.8 | 63.6 | 29.0 | 64.1 | 35.1 |
| Example 14 | | | | | | | | |
| Comparative | 2.8 | 145.4 | 165.9 | 42.3 | 44.7 | 43.0 | 44.7 | 1.7 |
| Example 15 | | | | | | | | |

TABLE 4

| | Metal Material | | Heat | Surface Treatment | | | | | | | | | | | |
|---|---|---|---|---|---|---|---|---|---|---|---|---|---|---|---|
| | (% indicates mass %) | Thickness | Conductivity | Plating Condition | | | | | | Surface Form | | | | | |
| | (an element having | of a Metal | of a Metal | Ni | Zn | | | Current | Plating | | | | | Ni Deposition | Zn Deposition |
| | no % indication | Material | Material | Concentration | Concentration | | Temperature | Density | Time | | | | | Amount | Amount |
| | indicates the remainder) | (mm) | (W/m · K) | (g/L) | (g/L) | pH | (° C.) | Dk (A/dm²) | (sec) | ΔL | Δa | Δb | ΔE | μg/dm² | μg/dm² |
| Example | Corson alloy (Cu—Co: | 0.2 | 260 | 40 | 15 | 3.8 | 40 | 0.3 | 75 | −70.9 | 1.0 | 3.0 | 71.0 | 2812 | 4646 |
| 22 | 1.9%—Si: 0.44%) | | | | | | | | | | | | | | |
| Example | Corson alloy (Cu—Co: | 0.01 | 260 | 40 | 15 | 3.8 | 40 | 0.3 | 75 | −70.9 | 1.0 | 3.0 | 71.0 | 2812 | 4646 |
| 23 | 1.9%—Si: 0.44%) | | | | | | | | | | | | | | |
| Example | Corson alloy (Cu—Co: | 0.075 | 260 | 40 | 15 | 3.8 | 40 | 0.3 | 75 | −70.9 | 1.0 | 3.0 | 71.0 | 2812 | 4646 |
| 24 | 1.9%—Si: 0.44%) | | | | | | | | | | | | | | |
| Example | Corson alloy (Cu—Co: | 0.5 | 260 | 40 | 15 | 3.8 | 40 | 0.3 | 75 | −70.9 | 1.0 | 3.0 | 71.0 | 2812 | 4646 |
| 25 | 1.9%—Si: 0.44%) | | | | | | | | | | | | | | |
| Example | Corson alloy (Cu—Co: | 3.0 | 260 | 40 | 15 | 3.8 | 40 | 0.3 | 75 | −70.9 | 1.0 | 3.0 | 71.0 | 2812 | 4646 |
| 26 | 1.9%—Si: 0.44%) | | | | | | | | | | | | | | |
| Example | Corson alloy (Cu—Co: | 0.2 | 260 | 40 | 15 | 4 | 45 | 0.2 | 96 | −66.4 | 1.6 | 6.9 | 66.8 | 2225 | 4244 |
| 27 | 1.9%—Si: 0.44%) | | | | | | | | | | | | | | |
| Example | Corson alloy (Cu—Co: | 0.2 | 260 | 23.5 | 4.5 | 4.5 | 40 | 0.3 | 66 | −68.6 | 0.0 | 1.3 | 68.6 | 2537 | 3969 |
| 28 | 1.9%—Si: 0.44%) | | | | | | | | | | | | | | |
| Example | Corson alloy (Cu—Co: | 0.2 | 260 | 37 | 8 | 4.2 | 40 | 0.5 | 41 | −69.8 | 0.1 | 1.2 | 69.8 | 2791 | 3917 |
| 29 | 1.9%—Si: 0.44%) | | | | | | | | | | | | | | |
| Example | Corson alloy (Cu—Co: | 0.2 | 260 | 15 | 3 | 4 | 45 | 0.7 | 31 | −70.0 | −0.3 | 1.0 | 70.0 | 2840 | 4460 |
| 30 | 1.9%—Si: 0.44%) | | | | | | | | | | | | | | |
| Example | Corson alloy (Cu—Co: | 0.2 | 260 | 50 | 8 | 4.5 | 35 | 0.4 | 44 | −65.1 | 1.8 | 4.3 | 65.3 | 3610 | 2289 |
| 31 | 1.9%—Si: 0.44%) | | | | | | | | | | | | | | |
| Example | Corson alloy (Cu—Co: | 0.2 | 260 | 23.5 | 4.5 | 4.2 | 50 | 0.4 | 71 | −66.2 | 0.3 | 0.1 | 66.2 | 5131 | 4335 |
| 32 | 1.9%—Si: 0.44%) | | | | | | | | | | | | | | |
| Example | Corson alloy (Cu—Co: | 0.2 | 260 | 23.5 | 4.5 | 3.8 | 50 | 0.8 | 33 | −67.3 | 0.5 | 0.2 | 67.3 | 2800 | 6203 |
| 33 | 1.9%—Si: 0.44%) | | | | | | | | | | | | | | |
| Example | Corson alloy (Cu—Co: | 0.2 | 260 | 18.5 | 7 | 4 | 45 | 0.7 | 24 | −64.2 | 2.3 | 2.0 | 64.3 | 1533 | 3883 |
| 34 | 1.9%—Si: 0.44%) | | | | | | | | | | | | | | |
| Example | Corson alloy (Cu—Co: | 0.2 | 260 | 60 | 15 | 4 | 45 | 0.6 | 30 | −69.2 | 0.2 | −0.3 | 69.2 | 3563 | 2868 |
| 35 | 1.9%—Si: 0.44%) | | | | | | | | | | | | | | |
| Example | Corson alloy (Cu—Co: | 0.2 | 260 | 60 | 15 | 3.8 | 40 | 0.5 | 50 | −67.2 | 0.3 | 0.2 | 67.2 | 4321 | 3802 |
| 36 | 1.9%—Si: 0.44%) | | | | | | | | | | | | | | |
| Example | Corson alloy (Cu—Co: | 0.2 | 260 | 40 | 15 | 4 | 35 | 0.6 | 40 | −63.1 | 0.9 | 1.4 | 63.1 | 2319 | 5678 |
| 37 | 1.9%—Si: 0.44%) | | | | | | | | | | | | | | |
| Example | Corson alloy (Cu—Co: | 0.2 | 260 | 37 | 8 | 4.2 | 45 | 0.8 | 35 | −66.1 | −0.1 | −0.4 | 66.1 | 3695 | 5474 |
| 38 | 1.9%—Si: 0.44%) | | | | | | | | | | | | | | |
| Example | Corson alloy (Cu—Co: | 0.2 | 260 | 37 | 8 | 4.5 | 40 | 1 | 19 | −70.2 | 3.5 | 3.2 | 70.4 | 2413 | 3252 |
| 39 | 1.9%—Si: 0.44%) | | | | | | | | | | | | | | |

| | Surface Treatment | | | | | | | | | |
|---|---|---|---|---|---|---|---|---|---|---|
| | Surface Form | | | | | | | | | |
| | Ni + Zn Deposition | | Contact | Chip Temperature | | Shield Inner Surface | | Shield Outer Surface (° C.) | | |
| | Amount | | Resistance | (° C.) | | (° C.) | | | | Temperature |
| | μg/dm² | Ni Ratio % | (mΩ) | Minimum | Maximum | Minimum | Maximum | Minimum | Maximum | Difference |
| Example | 7458 | 37.7 | 4.7 | 113.3 | 132.3 | 42.6 | 44.9 | 42.7 | 44.9 | 2.2 |
| 22 | | | | | | | | | | |
| Example | 7458 | 37.7 | 4.7 | 113.4 | 132.4 | 42.7 | 45.0 | 42.8 | 45.0 | 2.2 |
| 23 | | | | | | | | | | |
| Example | 7458 | 37.7 | 4.7 | 113.3 | 132.3 | 42.6 | 44.9 | 42.7 | 44.9 | 2.2 |
| 24 | | | | | | | | | | |
| Example | 7458 | 37.7 | 4.7 | 113.3 | 132.3 | 42.6 | 44.9 | 42.7 | 44.9 | 2.2 |
| 25 | | | | | | | | | | |
| Example | 7458 | 37.7 | 4.7 | 113.2 | 132.2 | 42.5 | 44.8 | 42.6 | 44.7 | 2.1 |
| 26 | | | | | | | | | | |
| Example | 6469 | 34.4 | 4.6 | 114.9 | 133.9 | 42.4 | 44.7 | 42.5 | 44.7 | 2.2 |
| 27 | | | | | | | | | | |
| Example | 6506 | 39.0 | 4.7 | 114.1 | 133.2 | 42.5 | 44.8 | 42.6 | 44.7 | 2.1 |
| 28 | | | | | | | | | | |
| Example | 6708 | 41.6 | 4.7 | 113.6 | 132.7 | 42.5 | 44.8 | 42.6 | 44.8 | 2.2 |
| 29 | | | | | | | | | | |
| Example | 7300 | 38.9 | 4.7 | 113.6 | 132.7 | 42.6 | 44.8 | 42.7 | 44.8 | 2.2 |
| 30 | | | | | | | | | | |
| Example | 5899 | 61.2 | 5.0 | 115.3 | 134.4 | 42.4 | 44.7 | 42.5 | 44.7 | 2.2 |
| 31 | | | | | | | | | | |
| Example | 9466 | 54.2 | 4.9 | 114.9 | 134.0 | 42.4 | 44.7 | 42.5 | 44.7 | 2.2 |
| 32 | | | | | | | | | | |
| Example | 9003 | 31.1 | 4.6 | 114.5 | 133.6 | 42.5 | 44.7 | 42.6 | 44.8 | 2.3 |
| 33 | | | | | | | | | | |
| Example | 5416 | 28.3 | 4.6 | 115.7 | 134.7 | 42.3 | 44.6 | 42.4 | 44.6 | 2.2 |
| 34 | | | | | | | | | | |
| Example | 6431 | 55.4 | 4.9 | 113.9 | 132.9 | 42.5 | 44.8 | 42.6 | 44.8 | 2.2 |
| 35 | | | | | | | | | | |
| Example | 8123 | 53.2 | 4.9 | 114.6 | 133.7 | 42.5 | 44.7 | 42.6 | 44.7 | 2.2 |
| 36 | | | | | | | | | | |
| Example | 7997 | 29.0 | 4.6 | 116.0 | 135.1 | 42.3 | 44.6 | 42.4 | 44.4 | 2.0 |
| 37 | | | | | | | | | | |
| Example | 9169 | 40.3 | 4.7 | 115.0 | 134.1 | 42.4 | 44.7 | 42.5 | 44.7 | 2.2 |
| 38 | | | | | | | | | | |
| Example | 5665 | 42.6 | 4.8 | 113.5 | 132.6 | 42.6 | 44.8 | 42.7 | 44.8 | 2.2 |
| 39 | | | | | | | | | | |

TABLE 5

| | Metal Material | | | Surface Treatment | | | |
|---|---|---|---|---|---|---|---|
| | (% indicates mass %) | Thickness | Heat Conductivity | Plating Condition | | | |
| | (an element having no % | of a Metal | of a Metal | Ni | Zn | | |
| | indication indicates the | Material | Material | Concentration | Concentration | | Temperature |
| | remainder) | (mm) | (W/m · K) | (g/L) | (g/L) | pH | (° C.) |
| Example | Corson alloy (Cu—Co: 1.9%—Si: | 0.2 | 260 | 29 | 5.5 | 3.6 | 40 |
| 40 | 0.44%) | | | | | | |
| Example | Corson alloy (Cu—Co: 1.9%—Si: | 0.2 | 260 | 29 | 5.5 | 3.5 | 45 |
| 41 | 0.44%) | | | | | | |
| Example | Corson alloy (Cu—Co: 1.9%—Si: | 0.2 | 260 | 15 | 3 | 4 | 45 |
| 42 | 0.44%) | | | | | | |
| Example | Corson alloy (Cu—Co: 1.9%—Si: | 0.2 | 260 | 37 | 8 | 4 | 40 |
| 43 | 0.44%) | | | | | | |
| Example | Corson alloy (Cu—Co: 1.9%—Si: | 0.2 | 260 | 15 | 3 | 3.5 | 35 |
| 44 | 0.44%) | | | | | | |
| Example | Corson alloy (Cu—Co: 1.9%—Si: | 0.2 | 260 | 15 | 3 | 3.5 | 30 |
| 45 | 0.44%) | | | | | | |
| Example | Corson alloy (Cu—Co: 1.9%—Si: | 0.2 | 260 | 29 | 5.5 | 4.2 | 40 |
| 46 | 0.44%) | | | | | | |
| Example | Corson alloy (Cu—Co: 1.9%—Si: | 0.2 | 260 | 37 | 8 | 4.2 | 35 |
| 47 | 0.44%) | | | | | | |
| Example | Corson alloy (Cu—Co: 1.9%—Si: | 0.2 | 260 | 40 | 15 | 3.8 | 35 |
| 48 | 0.44%) | | | | | | |
| Example | Corson alloy (Cu—Co: 1.9%—Si: | 0.2 | 260 | 29 | 5.5 | 4.2 | 40 |
| 49 | 0.44%) | | | | | | |
| Example | Corson alloy (Cu—Co: 1.9%—Si: | 0.2 | 260 | 37 | 8 | 4.2 | 45 |
| 50 | 0.44%) | | | | | | |
| Example | Corson alloy (Cu—Co: 1.9%—Si: | 0.2 | 260 | 60 | 15 | 4.5 | 45 |
| 51 | 0.44%) | | | | | | |
| Example | Corson alloy (Cu—Co: 1.9%—Si: | 0.2 | 260 | 40 | 15 | 5 | 30 |
| 52 | 0.44%) | | | | | | |
| Example | Corson alloy (Cu—Co: 1.9%—Si: | 0.2 | 260 | 37 | 8 | 4.5 | 35 |
| 53 | 0.44%) | | | | | | |
| Example | Corson alloy (Cu—Co: 1.9%—Si: | 0.2 | 260 | 40 | 15 | 3.5 | 35 |
| 54 | 0.44%) | | | | | | |
| Example | Corson alloy (Cu—Co: 1.9%—Si: | 0.2 | 260 | 60 | 15 | 4.5 | 35 |
| 55 | 0.44%) | | | | | | |
| Example | Corson alloy (Cu—Co: 1.9%—Si: | 0.2 | 260 | 37 | 8 | 4.3 | 40 |
| 56 | 0.44%) | | | | | | |
| Example | Corson alloy (Cu—Co: 1.9%—Si: | 0.2 | 260 | 29 | 5.5 | 4.3 | 40 |
| 57 | 0.44%) | | | | | | |
| Example | Corson alloy (Cu—Co: 1.9%—Si: | 0.2 | 260 | 40 | 15 | 3.9 | 45 |
| 58 | 0.44%) | | | | | | |
| Example | Corson alloy (Cu—Co: 1.9%—Si: | 0.2 | 260 | 37 | 8 | 4 | 45 |
| 59 | 0.44%) | | | | | | |

| | Surface Treatment | | | | | | | | | |
|---|---|---|---|---|---|---|---|---|---|---|
| | | | Surface Form | | | | | | | |
| | Plating Condition | | | | | | | | Ni + | |
| | Current | Plating | | | | | Ni Deposition | Zn Deposition | Zn Deposition | |
| | Density | Time | | | | | Amount | Amount | Amount | |
| | Dk (A/dm²) | (sec) | ΔL | Δa | Δb | ΔE | μg/dm² | μg/dm² | μg/dm² | Ni Ratio % |
| Example | 3 | 10 | −65.0 | 1.1 | −7.0 | 65.4 | 4309 | 5805 | 10114 | 42.6 |
| 40 | | | | | | | | | | |
| Example | 2.9 | 13 | −57.7 | 0.4 | 0.8 | 57.7 | 3604 | 7730 | 11334 | 31.8 |
| 41 | | | | | | | | | | |
| Example | 1.5 | 20 | −58.6 | 0.5 | 0.8 | 58.6 | 3429 | 7154 | 10583 | 32.4 |
| 42 | | | | | | | | | | |
| Example | 0.8 | 40 | −59.1 | 0.7 | 0.8 | 59.1 | 3636 | 6933 | 10569 | 34.4 |
| 43 | | | | | | | | | | |
| Example | 1.1 | 40 | −60.9 | 0.8 | 1.0 | 60.9 | 5710 | 8459 | 14169 | 40.3 |
| 44 | | | | | | | | | | |
| Example | 0.5 | 75 | −61.3 | 0.9 | −4.9 | 61.5 | 4596 | 8424 | 13020 | 35.3 |
| 45 | | | | | | | | | | |
| Example | 0.7 | 50 | −62.6 | 0.5 | −6.0 | 62.9 | 3989 | 7407 | 11396 | 35.0 |
| 46 | | | | | | | | | | |
| Example | 0.8 | 40 | −60.9 | −0.3 | −5.3 | 61.1 | 3881 | 6900 | 10781 | 36.0 |
| 47 | | | | | | | | | | |
| Example | 1.1 | 35 | −61.0 | −0.5 | −4.8 | 61.2 | 4741 | 8806 | 13547 | 35.0 |
| 48 | | | | | | | | | | |
| Example | 1.1 | 33 | −61.5 | 1.2 | −5.2 | 61.7 | 5056 | 7396 | 12452 | 40.6 |
| 49 | | | | | | | | | | |
| Example | 1.2 | 34 | −60.6 | 1.3 | −5.4 | 60.9 | 5177 | 8741 | 13918 | 37.2 |
| 50 | | | | | | | | | | |
| Example | 1.8 | 25 | −61.2 | 0.7 | −2.9 | 61.3 | 9031 | 5725 | 14756 | 61.2 |
| 51 | | | | | | | | | | |
| Example | 0.9 | 49 | −60.3 | 0.7 | −2.0 | 60.3 | 4089 | 10463 | 14552 | 28.1 |
| 52 | | | | | | | | | | |
| Example | 1.6 | 19 | −63.8 | 0.4 | −1.1 | 63.8 | 5370 | 4743 | 10113 | 53.1 |
| 53 | | | | | | | | | | |
| Example | 0.8 | 34 | −61.0 | 0.9 | 0.8 | 61.0 | 2730 | 6621 | 9351 | 29.2 |
| 54 | | | | | | | | | | |
| Example | 2 | 20 | −60.9 | 0.6 | −2.4 | 61.0 | 8057 | 5305 | 13362 | 60.3 |
| 55 | | | | | | | | | | |
| Example | 2.5 | 15 | −61.1 | 0.8 | −1.3 | 61.1 | 6630 | 5359 | 11989 | 55.3 |
| 56 | | | | | | | | | | |
| Example | 2.5 | 19 | −63.3 | 0.6 | −5.4 | 63.5 | 7872 | 7810 | 15682 | 50.2 |
| 57 | | | | | | | | | | |
| Example | 2.4 | 30 | −62.7 | 0.8 | −5.6 | 63.0 | 9243 | 14579 | 23822 | 38.8 |
| 58 | | | | | | | | | | |
| Example | 1.3 | 40 | −59.7 | 0.5 | 1.1 | 59.7 | 7239 | 9794 | 17033 | 42.5 |
| 59 | | | | | | | | | | |

| | | | | | | Shield Outer Surface | | |
|---|---|---|---|---|---|---|---|---|
| | Contact | Chip Temperature | | Shield Inner Surface | | (° C.) | | |
| | Resistance | (° C.) | | (° C.) | | | | Temperature |
| | (mΩ) | Minimum | Maximum | Minimum | Maximum | Minimum | Maximum | Difference |
| Example | 4.8 | 115.4 | 134.4 | 42.4 | 44.7 | 42.5 | 44.7 | 2.2 |
| 40 | | | | | | | | |
| Example | 4.6 | 118.0 | 137.1 | 42.1 | 44.4 | 42.2 | 44.4 | 2.2 |
| 41 | | | | | | | | |
| Example | 4.6 | 117.7 | 136.7 | 42.1 | 44.4 | 42.2 | 44.4 | 2.2 |
| 42 | | | | | | | | |
| Example | 4.6 | 117.5 | 136.6 | 42.2 | 44.4 | 42.3 | 44.3 | 2.1 |
| 43 | | | | | | | | |
| Example | 4.7 | 116.8 | 135.9 | 42.2 | 44.5 | 42.3 | 44.5 | 2.2 |
| 44 | | | | | | | | |
| Example | 4.7 | 116.7 | 135.8 | 42.2 | 44.5 | 42.3 | 44.5 | 2.2 |
| 45 | | | | | | | | |
| Example | 4.7 | 116.2 | 135.3 | 42.3 | 44.6 | 42.4 | 44.6 | 2.2 |
| 46 | | | | | | | | |
| Example | 4.7 | 116.8 | 135.9 | 42.2 | 44.5 | 42.3 | 44.5 | 2.2 |
| 47 | | | | | | | | |
| Example | 4.7 | 116.8 | 135.9 | 42.2 | 44.5 | 42.3 | 44.6 | 2.3 |
| 48 | | | | | | | | |
| Example | 4.7 | 116.6 | 135.7 | 42.2 | 44.5 | 42.3 | 44.5 | 2.2 |
| 49 | | | | | | | | |
| Example | 4.7 | 116.9 | 136.0 | 42.2 | 44.5 | 42.3 | 44.5 | 2.2 |
| 50 | | | | | | | | |
| Example | 5.0 | 116.7 | 135.8 | 42.2 | 44.5 | 42.3 | 44.5 | 2.2 |
| 51 | | | | | | | | |
| Example | 4.6 | 117.1 | 136.1 | 42.2 | 44.5 | 42.3 | 44.5 | 2.2 |
| 52 | | | | | | | | |
| Example | 4.9 | 115.8 | 134.9 | 42.3 | 44.6 | 42.4 | 44.6 | 2.2 |
| 53 | | | | | | | | |
| Example | 4.6 | 116.8 | 135.9 | 42.2 | 44.5 | 42.3 | 44.5 | 2.2 |
| 54 | | | | | | | | |
| Example | 5.0 | 116.8 | 135.9 | 42.2 | 44.5 | 42.3 | 44.5 | 2.2 |
| 55 | | | | | | | | |
| Example | 4.9 | 116.8 | 135.8 | 42.2 | 44.5 | 42.3 | 44.5 | 2.2 |
| 56 | | | | | | | | |
| Example | 4.9 | 116.0 | 135.1 | 42.3 | 44.6 | 42.4 | 44.6 | 2.2 |
| 57 | | | | | | | | |
| Example | 4.7 | 116.2 | 135.3 | 42.3 | 44.6 | 42.4 | 44.6 | 2.2 |
| 58 | | | | | | | | |
| Example | 4.8 | 117.3 | 136.3 | 42.2 | 44.5 | 42.3 | 44.5 | 2.2 |
| 59 | | | | | | | | |

TABLE 6

| | Metal Material | | | Surface Treatment | | | |
|---|---|---|---|---|---|---|---|
| | (% indicates mass %) | Thickness of | Heat Conductivity | Plating Condition | | | |
| | (an element having no % | a Metal | of a Metal | Ni | Zn | | |
| | indication indicates the | Material | Material | Concentration | Concentration | | Temperature |
| | remainder) | (mm) | (W/m · K) | (g/L) | (g/L) | pH | (° C.) |
| Example | Corson alloy (Cu—Co: 1.9%—Si: | 0.2 | 260 | 23.5 | 4.5 | 4 | 40 |
| 60 | 0.44%) | | | | | | |
| Example | Corson alloy (Cu—Co: 1.9%—Si: | 0.2 | 260 | 60 | 15 | 4.3 | 45 |
| 61 | 0.44%) | | | | | | |
| Example | Corson alloy (Cu—Co: 1.9%—Si: | 0.2 | 260 | 37 | 8 | 4.1 | 40 |
| 62 | 0.44%) | | | | | | |
| Example | Corson alloy (Cu—Co: 1.9%—Si: | 0.2 | 260 | 37 | 8 | 4.2 | 35 |
| 63 | 0.44%) | | | | | | |
| Example | Corson alloy (Cu—Co: 1.9%—Si: | 0.2 | 260 | 23.5 | 4.5 | 4.1 | 35 |
| 64 | 0.44%) | | | | | | |
| Example | Corson alloy (Cu—Co: 1.9%—Si: | 0.2 | 260 | 40 | 15 | 3.5 | 35 |
| 65 | 0.44%) | | | | | | |
| Example | Corson alloy (Cu—Co: 1.9%—Si: | 0.2 | 260 | 37 | 8 | 3.9 | 40 |
| 66 | 0.44%) | | | | | | |
| Example | Corson alloy (Cu—Co: 1.9%—Si: | 0.2 | 260 | 15 | 3 | 3.8 | 40 |
| 67 | 0.44%) | | | | | | |
| Example | Corson alloy (Cu—Co: 1.9%—Si: | 0.2 | 260 | 15 | 3 | 4 | 45 |
| 68 | 0.44%) | | | | | | |
| Example | Corson alloy (Cu—Co: 1.9%—Si: | 0.2 | 260 | 15 | 3 | 4.1 | 45 |
| 69 | 0.44%) | | | | | | |
| Example | Corson alloy (Cu—Co: 1.9%—Si: | 0.2 | 260 | 40 | 15 | 3.6 | 45 |
| 70 | 0.44%) | | | | | | |
| Example | Corson alloy (Cu—Co: 1.9%—Si: | 0.2 | 260 | 40 | 15 | 3.6 | 45 |
| 71 | 0.44%) | | | | | | |
| Example | Corson alloy (Cu—Co: 1.9%—Si: | 0.2 | 260 | 37 | 8 | 3.5 | 40 |
| 72 | 0.44%) | | | | | | |
| Example | Corson alloy (Cu—Co: 1.9%—Si: | 0.2 | 260 | 29 | 5.5 | 3.8 | 50 |
| 73 | 0.44%) | | | | | | |
| Example | Corson alloy (Cu—Co: 1.9%—Si: | 0.2 | 260 | 37 | 8 | 4.2 | 25 |
| 74 | 0.44%) | | | | | | |
| Example | Corson alloy (Cu—Co: 1.9%—Si: | 0.2 | 260 | 29 | 5.5 | 4.5 | 30 |
| 75 | 0.44%) | | | | | | |
| Example | Corson alloy (Cu—Co: 1.9%—Si: | 0.2 | 260 | 37 | 8 | 3.6 | 25 |
| 76 | 0.44%) | | | | | | |
| Example | Corson alloy (Cu—Co: 1.9%—Si: | 0.2 | 260 | 50 | 8 | 4.8 | 40 |
| 77 | 0.44%) | | | | | | |
| Example | Corson alloy (Cu—Co: 1.9%—Si: | 0.2 | 260 | 40 | 15 | 3.5 | 25 |
| 78 | 0.44%) | | | | | | |
| Example | Corson alloy (Cu—Co: 1.9%—Si: | 0.2 | 260 | 23.5 | 4.5 | 4.6 | 30 |
| 79 | 0.44%) | | | | | | |
| Example | Corson alloy (Cu—Co: 1.9%—Si: | 0.2 | 260 | 21.5 | 9 | 3.6 | 45 |
| 80 | 0.44%) | | | | | | |

| | Surface Treatment | | | | | | | | | |
|---|---|---|---|---|---|---|---|---|---|---|
| | Plating Condition | | Surface Form | | | | | | | |
| | Current | Plating | | | | | Ni Deposition | Zn Deposition | Ni + Zn Deposition | |
| | Density | Time | | | | | Amount | Amount | Amount | |
| | Dk (A/dm²) | (sec) | ΔL | Δa | Δb | ΔE | μg/dm² | μg/dm² | μg/dm² | Ni Ratio % |
| Example | 1.1 | 51 | −60.0 | 0.6 | 1.1 | 60.0 | 9092 | 10211 | 19303 | 47.1 |
| 60 | | | | | | | | | | |
| Example | 2.8 | 25 | −60.1 | 0.6 | 0.9 | 60.1 | 12185 | 11567 | 23752 | 51.3 |
| 61 | | | | | | | | | | |
| Example | 2.9 | 18 | −60.8 | 0.9 | 0.9 | 60.8 | 7773 | 9813 | 17586 | 44.2 |
| 62 | | | | | | | | | | |
| Example | 1 | 59 | −60.6 | 0.7 | 1.0 | 60.6 | 9648 | 10164 | 19812 | 48.7 |
| 63 | | | | | | | | | | |
| Example | 2.6 | 26 | −60.5 | 0.7 | 1.2 | 60.5 | 11691 | 10663 | 22354 | 52.3 |
| 64 | | | | | | | | | | |
| Example | 0.7 | 68 | −54.6 | 0.3 | 2.0 | 54.6 | 5078 | 10891 | 15969 | 31.8 |
| 65 | | | | | | | | | | |
| Example | 0.8 | 64 | −56.4 | 0.5 | 2.1 | 56.4 | 6730 | 10266 | 16996 | 39.6 |
| 66 | | | | | | | | | | |
| Example | 1.1 | 45 | −53.9 | −0.5 | 2.0 | 53.9 | 5352 | 11178 | 16530 | 32.4 |
| 67 | | | | | | | | | | |
| Example | 1.1 | 55 | −60.3 | 1.2 | −5.3 | 60.5 | 7298 | 12791 | 20089 | 36.3 |
| 68 | | | | | | | | | | |
| Example | 1.5 | 30 | −62.1 | 1.0 | −5.9 | 62.4 | 6393 | 8991 | 15384 | 41.6 |
| 69 | | | | | | | | | | |
| Example | 1.2 | 55 | −61.6 | 1.2 | −5.7 | 61.9 | 7163 | 14772 | 21935 | 32.7 |
| 70 | | | | | | | | | | |
| Example | 1.2 | 48 | −61.7 | 1.2 | −5.3 | 61.9 | 6296 | 13182 | 19478 | 32.3 |
| 71 | | | | | | | | | | |
| Example | 2.7 | 20 | −61.5 | 1.4 | −5.5 | 61.7 | 6321 | 12419 | 18740 | 33.7 |
| 72 | | | | | | | | | | |
| Example | 3 | 19 | −61.3 | 1.4 | −5.6 | 61.5 | 6241 | 12038 | 18279 | 34.1 |
| 73 | | | | | | | | | | |
| Example | 2.4 | 21 | −63.6 | 0.5 | −5.9 | 63.9 | 8356 | 9930 | 18286 | 45.7 |
| 74 | | | | | | | | | | |
| Example | 0.9 | 59 | −64.7 | 1.1 | −5.2 | 64.9 | 8342 | 8922 | 17264 | 48.3 |
| 75 | | | | | | | | | | |
| Example | 1.2 | 43 | −61.4 | 1.5 | −5.5 | 61.7 | 6013 | 10340 | 16353 | 36.8 |
| 76 | | | | | | | | | | |
| Example | 0.4 | 181 | −62.1 | 1.3 | −3.5 | 62.2 | 19514 | 4818 | 24332 | 80.2 |
| 77 | | | | | | | | | | |
| Example | 3 | 23 | −63.4 | 0.8 | −2.4 | 63.5 | 5339 | 17872 | 23211 | 23.0 |
| 78 | | | | | | | | | | |
| Example | 1.1 | 55 | −60.6 | 0.6 | −3.1 | 60.7 | 13562 | 6294 | 19856 | 68.3 |
| 79 | | | | | | | | | | |
| Example | 3 | 18 | −59.4 | 0.2 | −4.2 | 59.5 | 4346 | 13322 | 17668 | 24.6 |
| 80 | | | | | | | | | | |

| | | | | | | Shield Outer Surface | | |
|---|---|---|---|---|---|---|---|---|
| | Contact | Chip Temperature | | Shield Inner Surface | | (° C.) | | |
| | Resistance | (° C.) | | (° C.) | | | | Temperature |
| | (mΩ) | Minimum | Maximum | Minimum | Maximum | Minimum | Maximum | Difference |
| Example | 4.8 | 117.2 | 136.2 | 42.2 | 44.5 | 42.3 | 44.5 | 2.2 |
| 60 | | | | | | | | |
| Example | 4.9 | 117.1 | 136.2 | 42.2 | 44.5 | 42.3 | 44.5 | 2.2 |
| 61 | | | | | | | | |
| Example | 4.8 | 116.9 | 136.0 | 42.2 | 44.5 | 42.3 | 44.5 | 2.2 |
| 62 | | | | | | | | |
| Example | 4.8 | 116.9 | 136.0 | 42.2 | 44.5 | 42.3 | 44.5 | 2.2 |
| 63 | | | | | | | | |
| Example | 4.9 | 119.0 | 138.1 | 42.0 | 44.3 | 42.1 | 44.3 | 2.2 |
| 64 | | | | | | | | |
| Example | 4.6 | 121.1 | 140.2 | 41.8 | 44.1 | 41.9 | 44.1 | 2.2 |
| 65 | | | | | | | | |
| Example | 4.7 | 120.4 | 139.5 | 41.9 | 44.1 | 42.0 | 44.1 | 2.2 |
| 66 | | | | | | | | |
| Example | 4.6 | 121.3 | 140.4 | 41.8 | 44.1 | 41.9 | 44.1 | 2.2 |
| 67 | | | | | | | | |
| Example | 4.7 | 117.1 | 136.1 | 42.2 | 44.5 | 42.3 | 44.5 | 2.2 |
| 68 | | | | | | | | |
| Example | 4.7 | 116.4 | 135.5 | 42.3 | 44.6 | 42.4 | 44.6 | 2.2 |
| 69 | | | | | | | | |
| Example | 4.6 | 116.6 | 135.7 | 42.3 | 44.5 | 42.4 | 44.5 | 2.2 |
| 70 | | | | | | | | |
| Example | 4.6 | 116.5 | 135.6 | 42.3 | 44.5 | 42.4 | 44.4 | 2.1 |
| 71 | | | | | | | | |
| Example | 4.6 | 116.6 | 135.7 | 42.2 | 44.5 | 42.3 | 44.5 | 2.2 |
| 72 | | | | | | | | |
| Example | 4.6 | 116.7 | 135.8 | 42.2 | 44.5 | 42.3 | 44.5 | 2.2 |
| 73 | | | | | | | | |
| Example | 4.8 | 115.9 | 134.9 | 42.3 | 44.6 | 42.4 | 44.6 | 2.2 |
| 74 | | | | | | | | |
| Example | 4.8 | 115.5 | 134.6 | 42.4 | 44.6 | 42.5 | 44.6 | 2.2 |
| 75 | | | | | | | | |
| Example | 4.7 | 116.7 | 135.7 | 42.2 | 44.5 | 42.3 | 44.5 | 2.2 |
| 76 | | | | | | | | |
| Example | 5.2 | 116.4 | 135.5 | 42.3 | 44.6 | 42.4 | 44.6 | 2.2 |
| 77 | | | | | | | | |
| Example | 4.5 | 115.9 | 135.0 | 42.3 | 44.6 | 42.4 | 44.5 | 2.1 |
| 78 | | | | | | | | |
| Example | 5.1 | 116.9 | 136.0 | 42.2 | 44.5 | 42.3 | 44.5 | 2.2 |
| 79 | | | | | | | | |
| Example | 4.5 | 117.4 | 136.5 | 42.2 | 44.5 | 42.3 | 44.5 | 2.2 |
| 80 | | | | | | | | |

TABLE 7

| | Metal Material | | | Surface Treatment | | | |
|---|---|---|---|---|---|---|---|
| | (% indicates mass %) | Thickness of | Heat Conductivity | Plating Condition | | | |
| | (an element having no % | a Metal | of a Metal | Ni | Zn | | |
| | indication indicates the | Material | Material | Concentration | Concentration | | Temperature |
| | remainder) | (mm) | (W/m · K) | (g/L) | (g/L) | pH | (° C.) |
| Example | Corson alloy (Cu—Co: 1.9%—Si: | 0.2 | 260 | 21.5 | 9 | 3.5 | 55 |
| 81 | 0.44%) | | | | | | |
| Example | Corson alloy (Cu—Co: 1.9%—Si: | 0.2 | 260 | 60 | 15 | 4.8 | 55 |
| 82 | 0.44%) | | | | | | |
| Example | Corson alloy (Cu—Co: 1.9%—Si: | 0.2 | 260 | 60 | 15 | 4.7 | 45 |
| 83 | 0.44%) | | | | | | |
| Example | Corson alloy (Cu—Co: 1.9%—Si: | 0.2 | 260 | 60 | 15 | 4.9 | 40 |
| 84 | 0.44%) | | | | | | |
| Example | Corson alloy (Cu—Co: 1.9%—Si: | 0.2 | 260 | 60 | 15 | 5 | 35 |
| 85 | 0.44%) | | | | | | |
| Example | Corson alloy (Cu—Co: 1.9%—Si: | 0.2 | 260 | 23.5 | 4.5 | 4.5 | 35 |
| 86 | 0.44%) | | | | | | |
| Example | Corson alloy (Cu—Co: 1.9%—Si: | 0.2 | 260 | 23.5 | 4.5 | 4.6 | 35 |
| 87 | 0.44%) | | | | | | |
| Example | Corson alloy (Cu—Co: 1.9%—Si: | 0.2 | 260 | 23.5 | 4.5 | 4.6 | 40 |
| 88 | 0.44%) | | | | | | |
| Example | Corson alloy (Cu—Co: 1.9%—Si: | 0.2 | 260 | 50 | 8 | 5.5 | 40 |
| 89 | 0.44%) | | | | | | |
| Example | Corson alloy (Cu—Co: 1.9%—Si: | 0.2 | 260 | 60 | 15 | 4.8 | 35 |
| 90 | 0.44%) | | | | | | |
| Example | Corson alloy (Cu—Co: 1.9%—Si: | 0.2 | 260 | 29 | 5.5 | 4.4 | 35 |
| 91 | 0.44%) | | | | | | |
| Example | Corson alloy (Cu—Co: 1.9%—Si: | 0.2 | 260 | 29 | 5.5 | 4.5 | 45 |
| 92 | 0.44%) | | | | | | |
| Example | Corson alloy (Cu—Co: 1.9%—Si: | 0.2 | 260 | 60 | 15 | 4.2 | 35 |
| 93 | 0.44%) | | | | | | |
| Example | Corson alloy (Cu—Co: 1.9%—Si: | 0.2 | 260 | 50 | 8 | 5 | 40 |
| 94 | 0.44%) | | | | | | |
| Example | Corson alloy (Cu—Co: 1.9%—Si: | 0.2 | 260 | 23.5 | 4.5 | 4 | 40 |
| 95 | 0.44%) | | | | | | |

| | Surface Treatment | | | | | | | | | |
|---|---|---|---|---|---|---|---|---|---|---|
| | Plating Condition | | Surface Form | | | | | | | |
| | Current | Plating | | | | | Ni Deposition | Zn Deposition | Ni + Zn Deposition | |
| | Density | Time | | | | | Amount | Amount | Amount | |
| | Dk (A/dm²) | (sec) | ΔL | Δa | Δb | ΔE | μg/dm² | μg/dm² | μg/dm² | Ni Ratio % |
| Example | 2.1 | 9 | −48.3 | −0.5 | 2.6 | 48.4 | 1420 | 4172 | 5592 | 25.4 |
| 81 | | | | | | | | | | |
| Example | 1.8 | 12 | −51.9 | 1.1 | 0.6 | 51.9 | 4257 | 2688 | 6945 | 61.3 |
| 82 | | | | | | | | | | |
| Example | 2.1 | 10 | −52.2 | 1.2 | 0.7 | 52.2 | 4468 | 2785 | 7253 | 61.6 |
| 83 | | | | | | | | | | |
| Example | 0.8 | 30 | −52.7 | 0.5 | 0.9 | 52.7 | 5390 | 3139 | 8529 | 63.2 |
| 84 | | | | | | | | | | |
| Example | 0.8 | 30 | −53.9 | 0.3 | 0.7 | 53.9 | 5577 | 2747 | 8324 | 67.0 |
| 85 | | | | | | | | | | |
| Example | 0.9 | 30 | −54.6 | 0.3 | 0.7 | 54.6 | 6458 | 2807 | 9265 | 69.7 |
| 86 | | | | | | | | | | |
| Example | 0.9 | 35 | −54.2 | 0.5 | 0.9 | 54.2 | 7875 | 2810 | 10685 | 73.7 |
| 87 | | | | | | | | | | |
| Example | 1 | 36 | −55.1 | 0.5 | 0.7 | 55.1 | 9277 | 2771 | 12048 | 77.0 |
| 88 | | | | | | | | | | |
| Example | 0.8 | 50 | −47.6 | 0.4 | 0.1 | 47.6 | 12502 | 1657 | 14159 | 88.3 |
| 89 | | | | | | | | | | |
| Example | 0.5 | 35 | −45.3 | 0.5 | 0.3 | 45.3 | 5059 | 1171 | 6230 | 81.2 |
| 90 | | | | | | | | | | |
| Example | 0.5 | 36 | −60.1 | 1.9 | 4.1 | 60.3 | 3728 | 2171 | 5899 | 63.2 |
| 91 | | | | | | | | | | |
| Example | 0.6 | 70 | −59.8 | 0.6 | −0.1 | 59.8 | 9380 | 4875 | 14255 | 65.8 |
| 92 | | | | | | | | | | |
| Example | 1.7 | 18 | −61.2 | 0.5 | 0.1 | 61.2 | 5765 | 4124 | 9889 | 58.3 |
| 93 | | | | | | | | | | |
| Example | 1.5 | 20 | −54.3 | 0.4 | 0.2 | 54.3 | 8009 | 1854 | 9863 | 81.2 |
| 94 | | | | | | | | | | |
| Example | 1.3 | 30 | −57.6 | 0.3 | −0.3 | 57.6 | 8176 | 4760 | 12936 | 63.2 |
| 95 | | | | | | | | | | |

| | | | | | | Shield Outer Surface | | |
|---|---|---|---|---|---|---|---|---|
| | Contact | Chip Temperature | | Shield Inner Surface | | (° C.) | | |
| | Resistance | (° C.) | | (° C.) | | | | Temperature |
| | (mΩ) | Minimum | Maximum | Minimum | Maximum | Minimum | Maximum | Difference |
| Example | 4.5 | 123.4 | 142.4 | 41.6 | 43.9 | 41.7 | 43.9 | 2.2 |
| 81 | | | | | | | | |
| Example | 5.0 | 120.1 | 139.1 | 41.9 | 44.2 | 42.0 | 44.2 | 2.2 |
| 82 | | | | | | | | |
| Example | 5.0 | 120.0 | 139.0 | 41.9 | 44.2 | 42.0 | 44.2 | 2.2 |
| 83 | | | | | | | | |
| Example | 5.0 | 119.8 | 138.9 | 41.9 | 44.2 | 42.0 | 44.2 | 2.2 |
| 84 | | | | | | | | |
| Example | 5.1 | 119.3 | 138.4 | 42.0 | 44.3 | 42.1 | 44.3 | 2.2 |
| 85 | | | | | | | | |
| Example | 5.1 | 119.1 | 138.2 | 42.0 | 44.3 | 42.2 | 44.3 | 2.1 |
| 86 | | | | | | | | |
| Example | 5.2 | 119.2 | 138.3 | 42.0 | 44.3 | 42.1 | 44.3 | 2.2 |
| 87 | | | | | | | | |
| Example | 5.2 | 118.9 | 138.0 | 42.0 | 44.3 | 42.1 | 44.3 | 2.2 |
| 88 | | | | | | | | |
| Example | 5.3 | 121.6 | 140.7 | 41.8 | 44.0 | 41.9 | 44.0 | 2.2 |
| 89 | | | | | | | | |
| Example | 5.3 | 122.4 | 141.5 | 41.7 | 43.9 | 41.8 | 43.6 | 1.9 |
| 90 | | | | | | | | |
| Example | 5.0 | 119.1 | 138.2 | 42.0 | 44.3 | 42.1 | 44.3 | 2.2 |
| 91 | | | | | | | | |
| Example | 5.1 | 117.2 | 136.3 | 42.2 | 44.5 | 42.3 | 44.5 | 2.2 |
| 92 | | | | | | | | |
| Example | 5.0 | 116.7 | 135.8 | 42.2 | 44.5 | 42.3 | 44.5 | 2.2 |
| 93 | | | | | | | | |
| Example | 5.3 | 119.2 | 138.3 | 42.0 | 44.3 | 42.1 | 44.3 | 2.2 |
| 94 | | | | | | | | |
| Example | 5.0 | 118.0 | 137.1 | 42.1 | 44.4 | 42.2 | 44.4 | 2.2 |
| 95 | | | | | | | | |

TABLE 8

| | Metal Material | | | Surface Treatment | | | |
|---|---|---|---|---|---|---|---|
| | (% indicates mass %) | Thickness of | | Plating Condition | | | |
| | (an element having no % | a Metal | Heat Conductivity | Ni | Zn | | |
| | indication indicates the | Material | of a Metal Material | Concentration | Concentration | | Temperature |
| | remainder) | (mm) | (W/m · K) | (g/L) | (g/L) | pH | (° C.) |
| Example | Corson alloy (Cu—Co: 1.9%—Si: | 0.2 | 260 | 40 | 15 | 3.6 | 40 |
| 96 | 0.44%) | | | | | | |
| Example | Corson alloy (Cu—Co: 1.9%—Si: | 0.2 | 260 | 21.5 | 9 | 3.5 | 35 |
| 97 | 0.44%) | | | | | | |
| Example | Corson alloy (Cu—Co: 1.9%—Si: | 0.2 | 260 | 21.5 | 9 | 3.6 | 40 |
| 98 | 0.44%) | | | | | | |
| Example | Corson alloy (Cu—Co: 1.9%—Si: | 0.2 | 260 | 40 | 15 | 3.8 | 45 |
| 99 | 0.44%) | | | | | | |
| Example | Corson alloy (Cu—Co: 1.9%—Si: | 0.2 | 260 | 18.5 | 7 | 3.5 | 50 |
| 100 | 0.44%) | | | | | | |
| Example | Corson alloy (Cu—Co: 1.9%—Si: | 0.2 | 260 | 21.5 | 9 | 3.7 | 45 |
| 101 | 0.44%) | | | | | | |
| Example | Corson alloy (Cu—Co: 1.9%—Si: | 0.2 | 260 | 21.5 | 9 | 3.8 | 45 |
| 102 | 0.44%) | | | | | | |
| Example | Corson alloy (Cu—Co: 1.9%—Si: | 0.2 | 260 | 21.5 | 9 | 3.7 | 50 |
| 103 | 0.44%) | | | | | | |
| Example | Corson alloy (Cu—Co: 1.9%—Si: | 0.2 | 260 | 18.5 | 7 | 3.6 | 45 |
| 104 | 0.44%) | | | | | | |
| Example | Corson alloy (Cu—Co: 1.9%—Si: | 0.2 | 260 | 40 | 15 | 3.6 | 45 |
| 105 | 0.44%) | | | | | | |
| Example | Corson alloy (Cu—Co: 1.9%—Si: | 0.2 | 260 | 21.5 | 9 | 3.5 | 50 |
| 106 | 0.44%) | | | | | | |
| Example | Corson alloy (Cu—Co: 1.9%—Si: | 0.2 | 260 | 18.5 | 7 | 3.6 | 50 |
| 107 | 0.44%) | | | | | | |
| Example | Corson alloy (Cu—Co: 1.9%—Si: | 0.2 | 260 | 50 | 8 | 4.3 | 50 |
| 108 | 0.44%) | | | | | | |
| Example | Corson alloy (Cu—Co: 1.9%—Si: | 0.2 | 260 | 50 | 8 | 4.5 | 45 |
| 109 | 0.44%) | | | | | | |
| Example | Corson alloy (Cu—Co: 1.9%—Si: | 0.2 | 260 | 18.5 | 7 | 2 | 30 |
| 110 | 0.44%) | | | | | | |
| Example | Corson alloy (Cu—Co: 1.9%—Si: | 0.2 | 260 | 29 | 5.5 | 4 | 35 |
| 111 | 0.44%) | | | | | | |
| Example | Corson alloy (Cu—Co: 1.9%—Si: | 0.2 | 260 | 15 | 3 | 4 | 40 |
| 112 | 0.44%) | | | | | | |

| | Surface Treatment | | | | | | | | | |
|---|---|---|---|---|---|---|---|---|---|---|
| | Plating Condition | | Surface Form | | | | | | | |
| | | Plating | | | | | Ni Deposition | Zn Deposition | Ni + Zn Deposition | |
| | Current Density | Time | | | | | Amount | Amount | Amount | |
| | Dk (A/dm²) | (sec) | ΔL | Δa | Δb | ΔE | μg/dm² | μg/dm² | μg/dm² | Ni Ratio % |
| Example | 1.4 | 30 | −60.1 | 0.1 | −0.4 | 60.1 | 3388 | 11278 | 14666 | 23.1 |
| 96 | | | | | | | | | | |
| Example | 3 | 14 | −43.1 | 0.2 | −0.3 | 43.1 | 1596 | 12527 | 14123 | 11.3 |
| 97 | | | | | | | | | | |
| Example | 2.9 | 5 | −50.1 | 3.1 | 2.9 | 50.3 | 957 | 4273 | 5230 | 18.3 |
| 98 | | | | | | | | | | |
| Example | 2.7 | 10 | −61.2 | 1.2 | 0.9 | 61.2 | 2407 | 6746 | 9153 | 26.3 |
| 99 | | | | | | | | | | |
| Example | 2.5 | 10 | −50.2 | 0.7 | 0.8 | 50.2 | 1493 | 7502 | 8995 | 16.6 |
| 100 | | | | | | | | | | |
| Example | 2.8 | 5 | −49.8 | 3.2 | 3.1 | 50.0 | 1172 | 3992 | 5164 | 22.7 |
| 101 | | | | | | | | | | |
| Example | 2.7 | 15 | −59.7 | 0.2 | −0.3 | 59.7 | 3092 | 9275 | 12366 | 25.0 |
| 102 | | | | | | | | | | |
| Example | 2.8 | 12 | −58.2 | 0.4 | −0.1 | 58.2 | 2375 | 9324 | 11699 | 20.3 |
| 103 | | | | | | | | | | |
| Example | 2.5 | 11 | −59.8 | 0.6 | 0.5 | 59.8 | 1894 | 7671 | 9565 | 19.8 |
| 104 | | | | | | | | | | |
| Example | 2.4 | 10 | −58.6 | 0.4 | 0.2 | 58.6 | 1741 | 6628 | 8369 | 20.8 |
| 105 | | | | | | | | | | |
| Example | 3 | 24 | −43.9 | 0.8 | −0.3 | 43.9 | 22083 | 1816 | 23899 | 7.6 |
| 106 | | | | | | | | | | |
| Example | 1.9 | 36 | −56.1 | 0.6 | 0.1 | 56.1 | 18422 | 4209 | 22631 | 18.6 |
| 107 | | | | | | | | | | |
| Example | 0.4 | 171 | −58.3 | 0.6 | 0.3 | 58.3 | 3652 | 18345 | 21997 | 83.4 |
| 108 | | | | | | | | | | |
| Example | 0.6 | 123 | −46.9 | 0.7 | −0.2 | 46.9 | 2572 | 21694 | 24266 | 89.4 |
| 109 | | | | | | | | | | |
| Example | 1.1 | 15 | −42.1 | 1.5 | 1.1 | 42.1 | 770 | 4331 | 5101 | 15.1 |
| 110 | | | | | | | | | | |
| Example | 0.6 | 20 | −70.2 | 13.5 | 19.1 | 74.0 | 1496 | 2291 | 3787 | 39.5 |
| 111 | | | | | | | | | | |
| Example | 0.7 | 14 | −73.5 | 18.5 | 21.6 | 78.8 | 1227 | 2106 | 3333 | 36.8 |
| 112 | | | | | | | | | | |

| | | Chip | | Shield Inner | | Shield Outer Surface | | |
|---|---|---|---|---|---|---|---|---|
| | Contact | Temperature | | Surface | | (° C.) | | |
| | Resistance | (° C.) | | (° C.) | | | | Temperature |
| | (mΩ) | Minimum | Maximum | Minimum | Maximum | Minimum | Maximum | Difference |
| Example | 4.5 | 117.1 | 136.2 | 42.2 | 44.5 | 42.3 | 44.5 | 2.2 |
| 96 | | | | | | | | |
| Example | 4.2 | 125.2 | 144.3 | 41.4 | 43.7 | 41.9 | 43.7 | 1.8 |
| 97 | | | | | | | | |
| Example | 4.4 | 126.7 | 145.8 | 41.2 | 43.5 | 41.3 | 43.5 | 2.2 |
| 98 | | | | | | | | |
| Example | 4.5 | 116.7 | 135.8 | 42.2 | 44.5 | 42.3 | 44.5 | 2.2 |
| 99 | | | | | | | | |
| Example | 4.4 | 122.7 | 141.8 | 41.6 | 43.9 | 41.7 | 43.9 | 2.2 |
| 100 | | | | | | | | |
| Example | 4.5 | 126.8 | 145.9 | 41.2 | 43.5 | 41.3 | 43.5 | 2.2 |
| 101 | | | | | | | | |
| Example | 4.5 | 117.3 | 136.3 | 42.2 | 44.5 | 42.3 | 44.5 | 2.2 |
| 102 | | | | | | | | |
| Example | 4.5 | 117.8 | 136.9 | 42.1 | 44.4 | 42.2 | 44.4 | 2.2 |
| 103 | | | | | | | | |
| Example | 4.5 | 117.2 | 136.3 | 42.2 | 44.5 | 42.3 | 44.5 | 2.2 |
| 104 | | | | | | | | |
| Example | 4.5 | 117.7 | 136.7 | 42.1 | 44.4 | 42.2 | 44.4 | 2.2 |
| 105 | | | | | | | | |
| Example | 5.4 | 122.9 | 142.0 | 41.6 | 43.9 | 41.7 | 43.9 | 2.2 |
| 106 | | | | | | | | |
| Example | 5.3 | 118.6 | 137.6 | 42.1 | 44.3 | 42.2 | 44.3 | 2.2 |
| 107 | | | | | | | | |
| Example | 4.4 | 117.8 | 136.8 | 42.1 | 44.4 | 42.2 | 44.4 | 2.2 |
| 108 | | | | | | | | |
| Example | 4.3 | 121.9 | 140.9 | 41.7 | 44.0 | 41.8 | 44.0 | 2.2 |
| 109 | | | | | | | | |
| Example | 4.4 | 129.6 | 148.7 | 41.0 | 43.2 | 41.1 | 43.2 | 2.2 |
| 110 | | | | | | | | |
| Example | 4.7 | 113.5 | 132.6 | 42.6 | 44.8 | 42.7 | 44.8 | 2.2 |
| 111 | | | | | | | | |
| Example | 4.7 | 112.3 | 131.4 | 42.7 | 45.0 | 42.8 | 45.0 | 2.2 |
| 112 | | | | | | | | |

TABLE 9

| | Metal Material | | | Surface Treatment | | | |
|---|---|---|---|---|---|---|---|
| | (% indicates mass %) | Thickness of | | Plating Condition | | | |
| | (an element having no % | a Metal | Heat Conductivity | Ni | Zn | | |
| | indication indicates the | Material | of a Metal Material | Concentration | Concentration | | Temperature |
| | remainder) | (mm) | (W/m · K) | (g/L) | (g/L) | pH | (° C.) |
| Example | Corson alloy (Cu—Co: 1.9%—Si: | 0.2 | 260 | 15 | 3 | 3.9 | 40 |
| 113 | 0.44%) | | | | | | |
| Example | Corson alloy (Cu—Co: 1.9%—Si: | 0.2 | 260 | 40 | 15 | 4.1 | 45 |
| 114 | 0.44%) | | | | | | |
| Example | Corson alloy (Cu—Co: 1.9%—Si: | 0.2 | 260 | 50 | 8 | 4.4 | 45 |
| 115 | 0.44%) | | | | | | |
| Example | Corson alloy (Cu—Co: 1.9%—Si: | 0.2 | 260 | 40 | 15 | 4.4 | 40 |
| 116 | 0.44%) | | | | | | |
| Example | Corson alloy (Cu—Co: 1.9%—Si: | 0.2 | 260 | 37 | 8 | 3.8 | 50 |
| 117 | 0.44%) | | | | | | |
| Example | Corson alloy (Cu—Co: 1.9%—Si: | 0.2 | 260 | 60 | 15 | 4.5 | 45 |
| 118 | 0.44%) | | | | | | |
| Example | Corson alloy (Cu—Co: 1.9%—Si: | 0.2 | 260 | 29 | 5.5 | 4.4 | 45 |
| 119 | 0.44%) | | | | | | |
| Example | Corson alloy (Cu—Co: 1.9%—Si: | 0.2 | 260 | 23.5 | 4.5 | 4 | 35 |
| 120 | 0.44%) | | | | | | |
| Example | Corson alloy (Cu—Co: 1.9%—Si: | 0.2 | 260 | 60 | 15 | 4.6 | 35 |
| 121 | 0.44%) | | | | | | |
| Example | Corson alloy (Cu—Co: 1.9%—Si: | 0.2 | 260 | 29 | 5.5 | 4.2 | 40 |
| 122 | 0.44%) | | | | | | |
| Example | Corson alloy (Cu—Co: 1.9%—Si: | 0.2 | 260 | 15 | 3 | 4.2 | 40 |
| 123 | 0.44%) | | | | | | |
| Example | Corson alloy (Cu—Co: 1.9%—Si: | 0.2 | 260 | 15 | 3 | 4.5 | 45 |
| 124 | 0.44%) | | | | | | |
| Example | Corson alloy (Cu—Co: 1.9%—Si: | 0.2 | 260 | 60 | 15 | 4.9 | 40 |
| 125 | 0.44%) | | | | | | |
| Example | Corson alloy (Cu—Co: 1.9%—Si: | 0.2 | 260 | 40 | 15 | 3.5 | 45 |
| 126 | 0.44%) | | | | | | |
| Example | Corson alloy (Cu—Co: 1.9%—Si: | 0.2 | 260 | 18.5 | 7 | 3.8 | 45 |
| 127 | 0.44%) | | | | | | |
| Example | Corson alloy (Cu—Co: 1.9%—Si: | 0.2 | 260 | 50 | 8 | 5.3 | 40 |
| 128 | 0.44%) | | | | | | |

| | Surface Treatment | | | | | | | | | |
|---|---|---|---|---|---|---|---|---|---|---|
| | Plating Condition | | Surface Form | | | | | | | |
| | Current | | | | | | Ni Deposition | Zn Deposition | Ni + Zn Deposition | |
| | Density | Plating Time | | | | | Amount | Amount | Amount | |
| | Dk (A/dm²) | (sec) | ΔL | Δa | Δb | ΔE | μg/dm² | μg/dm² | μg/dm² | Ni Ratio % |
| Example | 0.6 | 19 | −70.4 | 19.2 | 23.7 | 76.7 | 1253 | 2401 | 3654 | 34.3 |
| 113 | | | | | | | | | | |
| Example | 0.8 | 18 | −64.0 | 6.1 | 0.9 | 64.3 | 2149 | 2825 | 4974 | 43.2 |
| 114 | | | | | | | | | | |
| Example | 1.3 | 4 | −47.3 | 11.8 | 12.8 | 50.4 | 1199 | 657 | 1856 | 64.6 |
| 115 | | | | | | | | | | |
| Example | 0.5 | 28 | −66.1 | 7.4 | 2.1 | 66.5 | 2206 | 2342 | 4548 | 48.5 |
| 116 | | | | | | | | | | |
| Example | 0.3 | 47 | −51.5 | 14.6 | 14.9 | 55.6 | 1615 | 3265 | 4880 | 33.1 |
| 117 | | | | | | | | | | |
| Example | 0.2 | 50 | −52.8 | 10.6 | 9.5 | 54.7 | 1689 | 1566 | 3255 | 51.9 |
| 118 | | | | | | | | | | |
| Example | 0.8 | 17 | −55.3 | 7.1 | 6.0 | 56.1 | 2456 | 1861 | 4317 | 56.9 |
| 119 | | | | | | | | | | |
| Example | 0.7 | 21 | −53.0 | 6.9 | 5.7 | 53.8 | 3038 | 2218 | 5256 | 57.8 |
| 120 | | | | | | | | | | |
| Example | 0.4 | 41 | −54.2 | 7.0 | 5.6 | 54.9 | 3366 | 2198 | 5564 | 60.5 |
| 121 | | | | | | | | | | |
| Example | 0.9 | 16 | −51.5 | 8.1 | 6.7 | 52.6 | 1948 | 2668 | 4616 | 42.2 |
| 122 | | | | | | | | | | |
| Example | 1.1 | 10 | −56.1 | 9.4 | 7.5 | 57.4 | 1721 | 2376 | 4097 | 42 |
| 123 | | | | | | | | | | |
| Example | 0.9 | 15 | −48.0 | 9.4 | 9.2 | 49.8 | 2424 | 2123 | 4547 | 53.3 |
| 124 | | | | | | | | | | |
| Example | 2 | 9 | −56.9 | 9.4 | 5.3 | 57.9 | 4372 | 1059 | 5431 | 80.5 |
| 125 | | | | | | | | | | |
| Example | 1.5 | 10 | −46.8 | 6.5 | 4.2 | 47.4 | 1061 | 3741 | 4802 | 22.1 |
| 126 | | | | | | | | | | |
| Example | 2 | 6 | −43.2 | 10.1 | 6.7 | 44.9 | 745 | 3020 | 3765 | 19.8 |
| 127 | | | | | | | | | | |
| Example | 1.8 | 7 | −40.1 | 8.9 | 4.5 | 41.3 | 3519 | 810 | 4329 | 81.3 |
| 128 | | | | | | | | | | |

| | | Chip | | Shield Inner | | Shield Outer Surface | | |
|---|---|---|---|---|---|---|---|---|
| | Contact | Temperature | | Surface | | (° C.) | | |
| | Resistance | (° C.) | | (° C.) | | | | Temperature |
| | (mΩ) | Minimum | Maximum | Minimum | Maximum | Minimum | Maximum | Difference |
| Example | 4.6 | 113.4 | 132.5 | 42.6 | 44.8 | 42.7 | 44.8 | 2.2 |
| 113 | | | | | | | | |
| Example | 4.8 | 115.7 | 134.8 | 42.3 | 44.6 | 42.4 | 44.6 | 2.2 |
| 114 | | | | | | | | |
| Example | 5.0 | 127.7 | 146.8 | 41.1 | 43.4 | 41.2 | 43.4 | 2.2 |
| 115 | | | | | | | | |
| Example | 4.8 | 115.0 | 134.1 | 42.4 | 44.7 | 42.5 | 44.7 | 2.2 |
| 116 | | | | | | | | |
| Example | 4.6 | 126.2 | 145.3 | 41.3 | 43.6 | 41.4 | 43.6 | 2.2 |
| 117 | | | | | | | | |
| Example | 4.9 | 125.7 | 144.8 | 41.3 | 43.6 | 41.4 | 43.6 | 2.2 |
| 118 | | | | | | | | |
| Example | 4.9 | 125.0 | 144.7 | 41.4 | 43.7 | 41.5 | 43.7 | 2.2 |
| 119 | | | | | | | | |
| Example | 5.0 | 125.7 | 144.7 | 41.3 | 43.6 | 41.4 | 43.6 | 2.2 |
| 120 | | | | | | | | |
| Example | 5.0 | 125.4 | 144.8 | 41.5 | 43.8 | 41.6 | 43.8 | 2.2 |
| 121 | | | | | | | | |
| Example | 4.7 | 126.2 | 145.3 | 41.3 | 43.6 | 41.4 | 43.6 | 2.2 |
| 122 | | | | | | | | |
| Example | 4.7 | 124.9 | 144.7 | 41.5 | 43.7 | 41.6 | 43.7 | 2.2 |
| 123 | | | | | | | | |
| Example | 4.9 | 127.5 | 146.5 | 41.2 | 43.4 | 41.3 | 43.4 | 2.2 |
| 124 | | | | | | | | |
| Example | 5.2 | 124.5 | 144.6 | 41.5 | 43.8 | 41.6 | 43.8 | 2.2 |
| 125 | | | | | | | | |
| Example | 4.5 | 127.9 | 147.0 | 41.1 | 43.4 | 41.2 | 43.4 | 2.2 |
| 126 | | | | | | | | |
| Example | 4.5 | 129.2 | 148.3 | 41.0 | 43.3 | 41.1 | 43.3 | 2.2 |
| 127 | | | | | | | | |
| Example | 5.3 | 130.3 | 149.4 | 40.9 | 43.2 | 41.0 | 43.2 | 2.2 |
| 128 | | | | | | | | |

TABLE 10

| | Metal Material | Thickness | | Surface Treatment | | | |
|---|---|---|---|---|---|---|---|
| | (% indicates mass %) | of | | Plating Condition | | | |
| | (an element having no % | a Metal | Heat Conductivity | Ni | Zn | | |
| | indication indicates the | Material | of a Metal Material | Concentration | Concentration | | Temperature |
| | remainder) | (mm) | (W/m · K) | (g/L) | (g/L) | pH | (° C.) |
| Comparative | Corson alloy (Cu—Co: 1.9%—Si: | 0.2 | 260 | 20 | 0 | 2.5 | 30 |
| Example 16 | 0.44%) | | | | | | |
| Comparative | Corson alloy (Cu—Co: 1.9%—Si: | 0.2 | 260 | 15 | 0 | 2.5 | 20 |
| Example 17 | 0.44%) | | | | | | |
| Comparative | Corson alloy (Cu—Co: 1.9%—Si: | 0.2 | 260 | 0 | 5 | 2.5 | 20 |
| Example 18 | 0.44%) | | | | | | |
| Comparative | Corson alloy (Cu—Co: 1.9%—Si: | 0.2 | 260 | 0 | 5 | 2.5 | 60 |
| Example 19 | 0.44%) | | | | | | |
| Comparative | Corson alloy (Cu—Co: 1.9%—Si: | 0.2 | 260 | 22 | 6 | 2.8 | 35 |
| Example 20 | 0.44%) | | | | | | |
| Comparative | Corson alloy (Cu—Co: 1.9%—Si: | 0.2 | 260 | 23.5 | 4.5 | 3.5 | 40 |
| Example 21 | 0.44%) | | | | | | |
| Comparative | Corson alloy (Cu—Co: 1.9%—Si: | 0.2 | 260 | 28 | 2 | 3.8 | 35 |
| Example 22 | 0.44%) | | | | | | |
| Comparative | Corson alloy (Cu—Co: 1.9%—Si: | 0.2 | 260 | 29 | 5.5 | 3.5 | 45 |
| Example 23 | 0.44%) | | | | | | |
| Comparative | Corson alloy (Cu—Co: 1.9%—Si: | 0.2 | 260 | 25 | 0 | 2 | 55 |
| Example 24 | 0.44%) | | | | | | |
| Comparative | Corson alloy (Cu—Co: 1.9%—Si: | 0.2 | 260 | 25 | 0 | 2 | 40 |
| Example 25 | 0.44%) | | | | | | |
| Comparative | Corson alloy (Cu—Co: 1.9%—Si: | 0.2 | 260 | 30 | 0 | 3.5 | 25 |
| Example 26 | 0.44%) | | | | | | |
| Comparative | Corson alloy (Cu—Co: 1.9%—Si: | 0.2 | 260 | 15 | 0 | 4 | 30 |
| Example 27 | 0.44%) | | | | | | |
| Comparative | Corson alloy (Cu—Co: 1.9%—Si: | 0.2 | 260 | 0 | 20 | 2 | 30 |
| Example 28 | 0.44%) | | | | | | |
| Comparative | Corson alloy (Cu—Co: 1.9%—Si: | 0.2 | 260 | 0 | 15 | 2 | 30 |
| Example 29 | 0.44%) | | | | | | |
| Comparative | Corson alloy (Cu—Co: 1.9%—Si: | 0.2 | 260 | 0 | 20 | 3.5 | 40 |
| Example 30 | 0.44%) | | | | | | |

| | Surface Treatment | | | | | | | | | |
|---|---|---|---|---|---|---|---|---|---|---|
| | Plating Condition | | Surface Form | | | | | | | |
| | Current | Plating | | | | | Ni Deposition | Zn Deposition | Ni + Zn Deposition | |
| | Density | Time | | | | | Amount | Amount | Amount | |
| | Dk (A/dm²) | (sec) | ΔL | Δa | Δb | ΔE | μg/dm² | μg/dm² | μg/dm² | Ni Ratio % |
| Comparative | 0.3 | 6 | −23.4 | 20.3 | 16.2 | 35.0 | 581 | 0 | 581 | 100 |
| Example 16 | | | | | | | | | | |
| Comparative | 3 | 2 | −25.6 | 11.4 | 9.9 | 29.7 | 1718 | 0 | 1718 | 100 |
| Example 17 | | | | | | | | | | |
| Comparative | 0.8 | 7 | −25.8 | 11.6 | 10.3 | 30.1 | 0 | 1717 | 1717 | 0 |
| Example 18 | | | | | | | | | | |
| Comparative | 2 | 3 | −26.3 | 8.3 | 6.5 | 28.3 | 0 | 2216 | 2216 | 0 |
| Example 19 | | | | | | | | | | |
| Comparative | 0.5 | 2 | −22.1 | 27.2 | 18.4 | 39.6 | 65 | 268 | 333 | 19.5 |
| Example 20 | | | | | | | | | | |
| Comparative | 3 | 1 | −25.4 | 26.1 | 19.5 | 41.3 | 405 | 515 | 920 | 44 |
| Example 21 | | | | | | | | | | |
| Comparative | 0.2 | 20 | −30.6 | 20.3 | 16.6 | 40.3 | 1006 | 259 | 1265 | 79.5 |
| Example 22 | | | | | | | | | | |
| Comparative | 0.1 | 40 | −31.2 | 19.9 | 17.1 | 40.8 | 378 | 944 | 1322 | 28.6 |
| Example 23 | | | | | | | | | | |
| Comparative | 0.5 | 15 | −27.3 | 3.6 | 3.3 | 27.7 | 2673 | 0 | 2673 | 100 |
| Example 24 | | | | | | | | | | |
| Comparative | 0.8 | 15 | −28.2 | 0.8 | −0.9 | 28.2 | 4016 | 0 | 4016 | 100 |
| Example 25 | | | | | | | | | | |
| Comparative | 4 | 5 | −29.1 | 0.3 | −1.1 | 29.1 | 6845 | 0 | 6845 | 100 |
| Example 26 | | | | | | | | | | |
| Comparative | 4 | 18 | −31.2 | 0.1 | −1.3 | 31.2 | 23331 | 0 | 23331 | 100 |
| Example 27 | | | | | | | | | | |
| Comparative | 0.5 | 24 | −28.3 | 1.0 | −0.8 | 28.3 | 0 | 3923 | 3923 | 0 |
| Example 28 | | | | | | | | | | |
| Comparative | 0.8 | 20 | −29.2 | 0.6 | −0.5 | 29.2 | 0 | 5660 | 5660 | 0 |
| Example 29 | | | | | | | | | | |
| Comparative | 0.5 | 45 | −30.3 | 0.4 | −0.7 | 30.3 | 0 | 7535 | 7535 | 0 |
| Example 30 | | | | | | | | | | |

| | | | | Shield | | Shield Outer Surface | | |
|---|---|---|---|---|---|---|---|---|
| | Contact | Chip Temperature | | Inner Surface | | (° C.) | | |
| | Resistance | (° C.) | | (° C.) | | | | Temperature |
| | (mΩ) | Minimum | Maximum | Minimum | Maximum | Minimum | Maximum | Difference |
| Comparative | 5.5 | 144.5 | 164.9 | 42.4 | 44.8 | 42.5 | 44.8 | 2.3 |
| Example 16 | | | | | | | | |
| Comparative | 5.5 | 142.9 | 163.2 | 42.6 | 45.0 | 42.7 | 45.0 | 2.3 |
| Example 17 | | | | | | | | |
| Comparative | 4.2 | 142.7 | 163.0 | 42.6 | 45.0 | 42.7 | 45.0 | 2.3 |
| Example 18 | | | | | | | | |
| Comparative | 4.2 | 142.4 | 162.6 | 42.6 | 45.0 | 42.7 | 45.0 | 2.3 |
| Example 19 | | | | | | | | |
| Comparative | 4.5 | 145.4 | 165.9 | 42.3 | 44.7 | 42.4 | 44.7 | 2.3 |
| Example 20 | | | | | | | | |
| Comparative | 4.8 | 143.0 | 163.3 | 42.5 | 45.0 | 42.6 | 45.0 | 2.3 |
| Example 21 | | | | | | | | |
| Comparative | 5.2 | 139.3 | 159.3 | 42.9 | 45.4 | 43.0 | 45.4 | 2.3 |
| Example 22 | | | | | | | | |
| Comparative | 4.6 | 138.8 | 158.8 | 43.0 | 45.4 | 43.1 | 45.4 | 2.4 |
| Example 23 | | | | | | | | |
| Comparative | 5.5 | 141.6 | 161.9 | 42.7 | 45.1 | 42.8 | 45.1 | 2.3 |
| Example 24 | | | | | | | | |
| Comparative | 5.5 | 141.0 | 161.2 | 42.7 | 45.2 | 42.8 | 45.2 | 2.3 |
| Example 25 | | | | | | | | |
| Comparative | 5.5 | 140.3 | 160.5 | 42.8 | 45.2 | 42.9 | 45.2 | 2.3 |
| Example 26 | | | | | | | | |
| Comparative | 5.5 | 138.8 | 158.8 | 43.0 | 45.4 | 43.1 | 45.4 | 2.4 |
| Example 27 | | | | | | | | |
| Comparative | 4.2 | 140.9 | 161.1 | 42.7 | 45.2 | 42.8 | 45.2 | 2.3 |
| Example 28 | | | | | | | | |
| Comparative | 4.2 | 140.3 | 160.4 | 42.8 | 45.3 | 42.9 | 45.3 | 2.3 |
| Example 29 | | | | | | | | |
| Comparative | 4.2 | 139.5 | 159.5 | 42.9 | 45.3 | 43.0 | 45.3 | 2.3 |
| Example 30 | | | | | | | | |

TABLE 11

| | Metal Material | | | Surface Treatment | | | |
|---|---|---|---|---|---|---|---|
| | (% indicates mass %) | Thickness | | Plating Condition | | | |
| | (an element having no % | of a Metal | Heat Conductivity | Ni | Zn | | |
| | indication indicates the | Material | of a Metal Material | Concentration | Concentration | | Temperature |
| | remainder) | (mm) | (W/m · K) | (g/L) | (g/L) | pH | (° C.) |
| Comparative | Corson alloy (Cu—Co: 1.9%—Si: | 0.2 | 260 | 0 | 20 | 2 | 40 |
| Example 31 | 0.44%) | | | | | | |
| Comparative | Corson alloy (Cu—Co: 1.9%—Si: | 0.2 | 260 | 55 | 4 | 5.5 | 50 |
| Example 32 | 0.44%) | | | | | | |
| Comparative | Corson alloy (Cu—Co: 1.9%—Si: | 0.2 | 260 | 60 | 4 | 5 | 50 |
| Example 33 | 0.44%) | | | | | | |
| Comparative | Corson alloy (Cu—Co: 1.9%—Si: | 0.2 | 260 | 70 | 3 | 5.5 | 50 |
| Example 34 | 0.44%) | | | | | | |
| Comparative | Corson alloy (Cu—Co: 1.9%—Si: | 0.2 | 260 | 25 | 0 | 3 | 40 |
| Example 35 | 0.44%) | | | | | | |
| Comparative | Corson alloy (Cu—Co: 1.9%—Si: | 0.2 | 260 | 21.5 | 9 | 3.2 | 40 |
| Example 36 | 0.44%) | | | | | | |
| Comparative | Corson alloy (Cu—Co: 1.9%—Si: | 0.2 | 260 | 0 | 10 | 2.5 | 50 |
| Example 37 | 0.44%) | | | | | | |
| Comparative | Corson alloy (Cu—Co: 1.9%—Si: | 0.2 | 260 | 21.5 | 9 | 2 | 50 |
| Example 38 | 0.44%) | | | | | | |
| Comparative | Corson alloy (Cu—Co: 1.9%—Si: | 0.2 | 260 | 23.5 | 4.5 | 3.8 | 40 |
| Example 39 | 0.44%) | | | | | | |
| Comparative | Corson alloy (Cu—Co: 1.9%—Si: | 0.2 | 260 | 23.5 | 4.5 | 4 | 45 |
| Example 40 | 0.44%) | | | | | | |
| Comparative | Corson alloy (Cu—Co: 1.9%—Si: | 0.2 | 260 | 21.5 | 9 | 3.8 | 45 |
| Example 41 | 0.44%) | | | | | | |
| Comparative | Corson alloy (Cu—Co: 1.9%—Si: | 0.2 | 260 | 60 | 15 | 4.8 | 40 |
| Example 42 | 0.44%) | | | | | | |
| Comparative | Corson alloy (Cu—Co: 1.9%—Si: | 0.2 | 260 | 40 | 15 | 3.7 | 35 |
| Example 43 | 0.44%) | | | | | | |

| | Surface Treatment | | | | | | | | | |
|---|---|---|---|---|---|---|---|---|---|---|
| | Plating Condition | | Surface Form | | | | | | | |
| | Current | Plating | | | | | Ni Deposition | Zn Deposition | Ni + Zn Deposition | |
| | Density | Time | | | | | Amount | Amount | Amount | |
| | Dk (A/dm²) | (sec) | ΔL | Δa | Δb | ΔE | μg/dm² | μg/dm² | μg/dm² | Ni Ratio % |
| Comparative | 0.8 | 90 | −31.8 | 0.2 | −1.6 | 31.8 | 0 | 24632 | 24632 | 0 |
| Example 31 | | | | | | | | | | |
| Comparative | 0.3 | 20 | −34.3 | 10.2 | 5.3 | 36.2 | 1776 | 387 | 2163 | 82.1 |
| Example 32 | | | | | | | | | | |
| Comparative | 4 | 8 | −38.9 | 0.3 | −0.2 | 38.9 | 7855 | 1258 | 9113 | 86.2 |
| Example 33 | | | | | | | | | | |
| Comparative | 5 | 9 | −29.6 | 0.2 | −0.1 | 29.6 | 13311 | 941 | 14252 | 93.4 |
| Example 34 | | | | | | | | | | |
| Comparative | 4.5 | 10 | −27.1 | 0.2 | −0.9 | 27.1 | 14751 | 0 | 14751 | 100 |
| Example 35 | | | | | | | | | | |
| Comparative | 2 | 20 | −30.1 | 0.2 | 0.2 | 30.1 | 1331 | 12391 | 13722 | 9.7 |
| Example 36 | | | | | | | | | | |
| Comparative | 0.5 | 75 | −26.5 | 0.1 | −2.1 | 26.6 | 0 | 12588 | 12588 | 0 |
| Example 37 | | | | | | | | | | |
| Comparative | 2 | 5 | −32.1 | 8.3 | 7.1 | 33.9 | 461 | 2156 | 2617 | 17.6 |
| Example 38 | | | | | | | | | | |
| Comparative | 0.5 | 8 | −33.7 | 18.6 | 17.0 | 42.1 | 768 | 815 | 1583 | 48.5 |
| Example 39 | | | | | | | | | | |
| Comparative | 0.5 | 11 | −38.3 | 14.9 | 15.4 | 43.9 | 1104 | 812 | 1916 | 57.6 |
| Example 40 | | | | | | | | | | |
| Comparative | 0.6 | 12 | −37.4 | 16.2 | 16.4 | 43.9 | 520 | 1742 | 2262 | 23 |
| Example 41 | | | | | | | | | | |
| Comparative | 1.8 | 5 | −38.2 | 13.5 | 15.2 | 43.3 | 1880 | 578 | 2458 | 76.5 |
| Example 42 | | | | | | | | | | |
| Comparative | 2.3 | 2 | −36.1 | 16.8 | 16.6 | 43.1 | 635 | 1221 | 1856 | 34.2 |
| Example 43 | | | | | | | | | | |

| | | | | Shield | | Shield Outer Surface | | |
|---|---|---|---|---|---|---|---|---|
| | Contact | Chip Temperature | | Inner Surface | | (° C.) | | |
| | Resistance | (° C.) | | (° C.) | | | | Temperature |
| | (mΩ) | Minimum | Maximum | Minimum | Maximum | Minimum | Maximum | Difference |
| Comparative | 4.2 | 138.4 | 158.4 | 43.0 | 45.5 | 43.1 | 45.5 | 2.4 |
| Example 31 | | | | | | | | |
| Comparative | 5.3 | 136.6 | 156.4 | 43.2 | 45.6 | 43.3 | 45.6 | 2.4 |
| Example 32 | | | | | | | | |
| Comparative | 5.3 | 133.3 | 152.8 | 43.5 | 46.0 | 43.6 | 46.0 | 2.4 |
| Example 33 | | | | | | | | |
| Comparative | 5.4 | 140.0 | 160.1 | 42.8 | 45.3 | 42.9 | 45.3 | 2.3 |
| Example 34 | | | | | | | | |
| Comparative | 5.5 | 141.8 | 162.0 | 42.7 | 45.1 | 42.8 | 45.1 | 2.3 |
| Example 35 | | | | | | | | |
| Comparative | 4.3 | 139.6 | 159.7 | 42.9 | 45.3 | 43.0 | 45.3 | 2.3 |
| Example 36 | | | | | | | | |
| Comparative | 4.2 | 142.2 | 162.5 | 42.6 | 45.0 | 42.7 | 45.0 | 2.3 |
| Example 37 | | | | | | | | |
| Comparative | 4.4 | 138.2 | 158.1 | 43.0 | 45.5 | 43.1 | 45.5 | 2.4 |
| Example 38 | | | | | | | | |
| Comparative | 4.8 | 137.0 | 156.9 | 43.1 | 45.6 | 43.2 | 45.6 | 2.4 |
| Example 39 | | | | | | | | |
| Comparative | 4.9 | 133.7 | 153.3 | 43.5 | 46.0 | 43.6 | 46.0 | 2.4 |
| Example 40 | | | | | | | | |
| Comparative | 4.5 | 134.4 | 154.0 | 43.4 | 45.9 | 43.5 | 45.9 | 2.4 |
| Example 41 | | | | | | | | |
| Comparative | 5.2 | 133.8 | 153.4 | 43.5 | 46.0 | 43.6 | 46.0 | 2.4 |
| Example 42 | | | | | | | | |
| Comparative | 4.6 | 135.3 | 155.0 | 43.3 | 45.8 | 43.4 | 45.8 | 2.4 |
| Example 43 | | | | | | | | |

TABLE 12

| | | | Heat | | |
|---|---|---|---|---|---|
| | Metal Material | | Con- | | |
| | (% indicates mass %) | Thickness | ductivity | Surface Treatment | |
| | (an element having no % | of a Metal | of a Metal | Plating Condition | |
| | indication indicates the | Material | Material | | Secondary Particle |
| | remainder) | (mm) | (W/m · K) | Primary Particle Current Condition | Current Condition |
| Example 129 | Corson alloy (Cu—Co: 1.9%—Si: | 0.2 | 260 | — | (50 A/dm2.30 As/dm2) |
| | 0.44%) | | | | |
| Example 130 | Corson alloy (Cu—Co: 1.9%—Si: | 0.2 | 260 | (63 A/dm2.80 As/dm2) + (1 A/dm2.2 As/dm2) | (28 A/dm2.73 As/dm2) |
| | 0.44%) | | | | |
| Example 131 | Corson alloy (Cu—Co: 1.9%—Si: | 0.2 | 260 | (63 A/dm2.80 As/dm2) + (1 A/dm2.2 As/dm2) | (31 A/dm2.40 As/dm2) |
| | 0.44%) | | | | |
| Example 132 | Corson alloy (Cu—Co: 1.9%—Si: | 0.2 | 260 | (63 A/dm2.80 As/dm2) + (10 A/dm2.30 As/dm2) | (31 A/dm2.40 As/dm2) |
| | 0.44%) | | | | |
| Example 133 | Corson alloy (Cu—Co: 1.9%—Si: | 0.2 | 260 | (65 A/dm2.80 As/dm2) + (20 A/dm2.30 As/dm2) | (28 A/dm2.20 As/dm2) |
| | 0.44%) | | | | |
| Example 134 | Corson alloy (Cu—Co: 1.9%—Si: | 0.2 | 260 | (65 A/dm2.80 As/dm2) + (2 A/dm2.4 As/dm2) | (25 A/dm2.15 As/dm2) |
| | 0.44%) | | | | |
| Example 135 | Corson alloy (Cu—Co: 1.9%—Si: | 0.2 | 260 | (60 A/dm2.80 As/dm2) + (10 A/dm2.20 As/dm2) | (25 A/dm2.30 As/dm2) |
| | 0.44%) | | | | |
| Example 136 | Corson alloy (Cu—Co: 1.9%—Si: | 0.2 | 260 | (55 A/dm2.75 As/dm2) + (1 A/dm2.5 As/dm2) | (25 A/dm2.30 As/dm2) |
| | 0.44%) | | | | |
| Example 137 | Corson alloy (Cu—Co: 1.9%—Si: | 0.2 | 260 | (50 A/dm2.70 As/dm2) + (5 A/dm2.10 As/dm2) | (25 A/dm2.30 As/dm2) |
| | 0.44%) | | | | |
| Comparative | Corson alloy (Cu—Co: 1.9%—Si: | 0.2 | 260 | (63 A/dm2.80 As/dm2) + (10 A/dm2.30 As/dm2) | — |
| Example 44 | 0.44%) | | | | |
| Comparative | Corson alloy (Cu—Co: 1.9%—Si: | 0.2 | 260 | (40 A/dm2.40 As/dm2) + (1 A/dm2.2 As/dm2) | (20 A/dm2.20 As/dm2) |
| Example 45 | 0.44%) | | | | |
| Comparative | Corson alloy (Cu—Co: 1.9%—Si: | 0.2 | 260 | (50 A/dm2.70 As/dm2) + (2 A/dm2.3 As/dm2) | (15 A/dm2.30 As/dm2) |
| Example 46 | 0.44%) | | | | |
| Comparative | Corson alloy (Cu—Co: 1.9%—Si: | 0.2 | 260 | (60 A/dm2.80 As/dm2) + (15 A/dm2.20 As/dm2) | covering plating |
| Example 47 | 0.44%) | | | | (20 A/dm2.60 As/dm2) |
| | | | | | →particle formation |
| | | | | | (20 A/dm2.20 As/dm2) |

| | Surface Treatment | | | | | | | | | | | | |
|---|---|---|---|---|---|---|---|---|---|---|---|---|---|
| | Surface Form | | | | | | | | | | | | |
| | | | | | Glossiness | | | | Shield Inner | | Shield Outer Surface (° C.) | | |
| | | | | | After | Contact | Chip Temperature | | Surface | | | | Temper- |
| | | | | | Surface | Resistance | (° C.) | | (° C.) | | | | ature |
| | ΔL | Δa | Δb | ΔE | Treatment | (mΩ) | Minimum | Maximum | Minimum | Maximum | Minimum | Maximum | Difference |
| Example 129 | −61.7 | 2.9 | 1.2 | 61.7 | 0.5 | 12.1 | 125.5 | 144.5 | 41.6 | 43.8 | 41.7 | 43.8 | 2.2 |
| Example 130 | −56.1 | 4.9 | 2.3 | 56.3 | 1.6 | 11.0 | 126.6 | 145.6 | 41.3 | 43.5 | 41.4 | 43.5 | 2.2 |
| Example 131 | −60.8 | 4.9 | 2.2 | 61.0 | 1.5 | 11.9 | 125.6 | 144.6 | 41.6 | 43.8 | 41.7 | 43.8 | 2.2 |
| Example 132 | −54.1 | 4.0 | 1.8 | 54.2 | 1.7 | 10.6 | 127.3 | 146.4 | 41.2 | 43.5 | 41.3 | 43.5 | 2.2 |
| Example 133 | −49.2 | 1.4 | 1.1 | 49.2 | 1.9 | 9.7 | 129.0 | 148.1 | 41.0 | 43.3 | 41.1 | 43.3 | 2.2 |
| Example 134 | −48.1 | 3.6 | 2.0 | 48.2 | 1.9 | 9.4 | 129.4 | 148.5 | 41.0 | 43.2 | 41.1 | 43.2 | 2.2 |
| Example 135 | −40.6 | 2.7 | 2.0 | 40.8 | 2.3 | 8.0 | 132.1 | 148.9 | 40.7 | 43.2 | 40.8 | 43.2 | 2.4 |
| Example 136 | −49.0 | 2.2 | 1.5 | 49.1 | 1.9 | 9.6 | 129.1 | 148.2 | 41.0 | 43.3 | 41.1 | 43.3 | 2.2 |
| Example 137 | −47.3 | 3.7 | 2.4 | 47.5 | 1.9 | 9.3 | 129.7 | 148.8 | 40.9 | 43.2 | 41.0 | 43.2 | 2.2 |
| Comparative | −34.7 | 36.3 | 23.6 | 55.5 | 1.7 | 6.8 | 135.3 | 155.8 | 43.3 | 45.7 | 43.4 | 45.7 | 2.3 |
| Example 44 | | | | | | | | | | | | | |
| Comparative | −36.4 | 1.9 | 4.2 | 36.7 | 2.5 | 7.1 | 134.1 | 154.6 | 43.4 | 45.8 | 43.5 | 45.8 | 2.3 |
| Example 45 | | | | | | | | | | | | | |
| Comparative | −33.5 | 2.8 | 3.4 | 33.8 | 2.7 | 6.6 | 136.2 | 156.7 | 43.2 | 45.6 | 43.3 | 45.6 | 2.3 |
| Example 46 | | | | | | | | | | | | | |
| Comparative | −38.5 | 2.1 | 2.1 | 38.7 | 2.4 | 7.6 | 132.5 | 153.0 | 43.6 | 46.0 | 43.7 | 46.0 | 2.3 |
| Example 47 | | | | | | | | | | | | | |

TABLE 13

| | Metal Material | | | Surface Treatment | | | | | |
|---|---|---|---|---|---|---|---|---|---|
| | (% indicates mass %) | | Heat | | Surface Form | | | | |
| | (an element having | Thickness | Conductivity | | | | | | Glossiness |
| | no % indication | of a Metal | of a Metal | | | | | | After |
| | indicates the | Material | Material | Plating | | | | | Surface |
| | remainder) | (mm) | (W/m · K) | Condition | ΔL | Δa | Δb | ΔE | Treatment |
| Example | Corson alloy (Cu—Co: | 0.2 | 260 | Ni—W plating | −67.3 | 1.0 | 3.0 | 67.4 | 20.0 |
| 138 | 1.9%—Si: 0.44%) | | | | | | | | |
| Example | Corson alloy (Cu—Co: | 0.2 | 260 | Co—Zn plating | −71.9 | 1.0 | 3.0 | 72.0 | 20.0 |
| 139 | 1.9%—Si: 0.44%) | | | | | | | | |
| Example | Corson alloy (Cu—Co: | 0.2 | 260 | Ni—Zn—W | −72.0 | 1.0 | 3.0 | 72.1 | 20.0 |
| 140 | 1.9%—Si: 0.44%) | | | plating | | | | | |

| | | | | | | Shield Outer Surface | | |
|---|---|---|---|---|---|---|---|---|
| | Contact | Chip Temperature | | Shield Inner Surface | | (° C.) | | |
| | Resistance | (° C.) | | (° C.) | | | | Temperature |
| | (mΩ) | Minimum | Maximum | Minimum | Maximum | Minimum | Maximum | Difference |
| Example | 5.5 | 114.5 | 133.7 | 42.3 | 44.6 | 42.5 | 44.7 | 2.2 |
| 138 | | | | | | | | |
| Example | 5.5 | 113.0 | 132.0 | 42.7 | 45.0 | 42.8 | 45.0 | 2.2 |
| 139 | | | | | | | | |
| Example | 5.5 | 113.0 | 132.0 | 42.7 | 45.0 | 42.8 | 45.0 | 2.2 |
| 140 | | | | | | | | |

TABLE 14

| | Metal Material | | | | | Surface Treatment | | | |
|---|---|---|---|---|---|---|---|---|---|
| | (% indicates mass %) | | Heat | Underlayer Treatment | | Plating Condition | | | |
| | (an element having | Thickness | Conductivity | | Glossiness | Ni | | | |
| | no % indication | of a Metal | of a Metal | | After | Concen- | Zn | | |
| | indicates the | Material | Material | Underlayer | Underlayer | tration | Concentration | | Temperature |
| | remainder) | (mm) | (W/m · K) | Treatment | Treatment | (g/L) | (g/L) | pH | (° C.) |
| Example | Corson alloy (Cu—Co: | 0.2 | 260 | none | 553 | 6 | 30 | 4.2 | 50 |
| 141 | 1.9%—Si: 0.44%) | | | | | | | | |
| Example | Corson alloy (Cu—Co: | 0.2 | 260 | none | 263 | 6 | 30 | 4.2 | 50 |
| 142 | 1.9%—Si: 0.44%) | | | | | | | | |
| Example | Corson alloy (Cu—Co: | 0.2 | 260 | none | 81 | 6 | 30 | 4.2 | 50 |
| 143 | 1.9%—Si: 0.44%) | | | | | | | | |
| Example | Corson alloy (Cu—Co: | 0.2 | 260 | copper | 3 | 6 | 30 | 4.2 | 50 |
| 144 | 1.9%—Si: 0.44%) | | | roughening | | | | | |
| Example | Corson alloy (Cu—Co: | 0.2 | 260 | texturing | 170 | 6 | 30 | 4.2 | 50 |
| 145 | 1.9%—Si: 0.44%) | | | | | | | | |
| Example | Corson alloy (Cu—Co: | 0.2 | 260 | high- | 520 | 6 | 30 | 4.2 | 50 |
| 146 | 1.9%—Si: 0.44%) | | | glossiness | | | | | |
| | | | | plating | | | | | |
| Example | Corson alloy (Cu—Co: | 0.2 | 260 | soft etching | 65 | 6 | 30 | 4.2 | 50 |
| 147 | 1.9%—Si: 0.44%) | | | | | | | | |
| Example | Corson alloy (Cu—Co: | 0.2 | 260 | none | 750 | 6 | 30 | 4.2 | 50 |
| 148 | 1.9%—Si: 0.44%) | | | | | | | | |
| Example | Corson alloy (Cu—Co: | 0.2 | 260 | none | 850 | 6 | 30 | 4.2 | 50 |
| 149 | 1.9%—Si: 0.44%) | | | | | | | | |
| Example | copper foil with carrier | 0.0015 | 350 | none | 450 | 6 | 30 | 4.2 | 50 |
| 150 | | | | | | | | | |
| Example | copper foil with carrier | 0.002 | 350 | none | 470 | 6 | 30 | 4.2 | 50 |
| 151 | | | | | | | | | |
| Example | copper foil with carrier | 0.003 | 350 | none | 500 | 6 | 30 | 4.2 | 50 |
| 152 | | | | | | | | | |
| Example | copper foil with carrier | 0.005 | 350 | none | 520 | 6 | 30 | 4.2 | 50 |
| 153 | | | | | | | | | |
| Example | copper foil with carrier | 0.003 | 350 | none | 500 | 6 | 30 | 4.2 | 50 |
| 154 | | | | | | | | | |

| | Surface Treatment | | | | | | | | | | |
|---|---|---|---|---|---|---|---|---|---|---|---|
| | | | Surface Form | | | | | | | | |
| | Plating Condition | | | | | | | | Ni + Zn | | |
| | Current | Plating | | | | | Ni Deposition | Zn Deposition | Deposition | | Glossiness |
| | Density | Time | | | | | Amount | Amount | Amount | Ni | After Ni—Zn |
| | Dk (A/dm²) | (sec) | ΔL | Δa | Δb | ΔE | μg/dm² | μg/dm² | μg/dm² | Ratio % | Plating |
| Example | 0.5 | 47 | −67.3 | 0.6 | 1.1 | 67.3 | 3184 | 4796 | 7980 | 39.9 | 33 |
| 141 | | | | | | | | | | | |
| Example | 0.5 | 48 | −68.3 | 0.2 | 1.3 | 68.3 | 3257 | 4866 | 8123 | 40.1 | 20 |
| 142 | | | | | | | | | | | |
| Example | 0.5 | 49 | −70.1 | 1.2 | 0.2 | 70.1 | 3313 | 4909 | 8222 | 40.3 | 11 |
| 143 | | | | | | | | | | | |
| Example | 0.5 | 46 | −72.6 | 0.4 | 0.1 | 72.6 | 4710 | 3167 | 7877 | 40.2 | 1.5 |
| 144 | | | | | | | | | | | |
| Example | 0.5 | 48 | −68.4 | 1.1 | 0.8 | 68.4 | 4763 | 3338 | 8101 | 41.2 | 16 |
| 145 | | | | | | | | | | | |
| Example | 0.5 | 48 | −66.3 | 0.6 | 1.4 | 66.3 | 4948 | 3258 | 8206 | 39.7 | 31 |
| 146 | | | | | | | | | | | |
| Example | 0.5 | 47 | −69.8 | 0.8 | 1.2 | 69.8 | 4763 | 3242 | 8005 | 40.5 | 7 |
| 147 | | | | | | | | | | | |
| Example | 0.5 | 47 | −67.3 | 0.6 | 1.1 | 67.3 | 3184 | 4796 | 7980 | 39.9 | 80 |
| 148 | | | | | | | | | | | |
| Example | 0.5 | 47 | −67.3 | 0.6 | 1.1 | 67.3 | 3184 | 4796 | 7980 | 39.9 | 110 |
| 149 | | | | | | | | | | | |
| Example | 0.5 | 48 | −66.3 | 0.6 | 1.4 | 66.3 | 4948 | 3258 | 8206 | 39.7 | 25 |
| 150 | | | | | | | | | | | |
| Example | 0.5 | 48 | −66.3 | 0.6 | 1.4 | 66.3 | 4948 | 3258 | 8206 | 39.7 | 26 |
| 151 | | | | | | | | | | | |
| Example | 0.5 | 48 | −66.3 | 0.6 | 1.4 | 66.3 | 4948 | 3258 | 8206 | 39.7 | 28 |
| 152 | | | | | | | | | | | |
| Example | 0.5 | 48 | −66.3 | 0.6 | 1.4 | 66.3 | 4948 | 3258 | 8206 | 39.7 | 31 |
| 153 | | | | | | | | | | | |
| Example | 0.5 | 48 | −66.3 | 0.6 | 1.4 | 66.3 | 4948 | 3258 | 8206 | 39.7 | 28 |
| 154 | | | | | | | | | | | |

| | | | | | | | Shield Outer Surface | | |
|---|---|---|---|---|---|---|---|---|---|
| | Contact | | Chip Temperature | | Shield Inner Surface | | (° C.) | | |
| | Resistance | Gloss | (° C.) | | (° C.) | | | | Temperature |
| | (mΩ) | (designability) | Minimum | Maximum | Minimum | Maximum | Minimum | Maximum | Difference |
| Example | 4.7 | present | 114.7 | 133.8 | 42.4 | 44.7 | 42.5 | 44.6 | 2.1 |
| 141 | | | | | | | | | |
| Example | 4.7 | a little present | 114.1 | 133.2 | 42.5 | 44.8 | 42.6 | 44.7 | 2.1 |
| 142 | | | | | | | | | |
| Example | 4.7 | a little present | 113.0 | 132.1 | 42.6 | 44.9 | 42.7 | 44.8 | 2.1 |
| 143 | | | | | | | | | |
| Example | 5.0 | absent | 109.1 | 128.2 | 43.0 | 45.3 | 43.1 | 45.2 | 2.1 |
| 144 | | | | | | | | | |
| Example | 5.0 | a little present | 113.6 | 132.7 | 42.6 | 44.8 | 42.7 | 44.7 | 2.1 |
| 145 | | | | | | | | | |
| Example | 5.0 | present | 114.8 | 133.7 | 42.4 | 44.7 | 42.5 | 44.6 | 2.1 |
| 146 | | | | | | | | | |
| Example | 5.0 | absent | 110.0 | 130.5 | 42.9 | 45.0 | 43.0 | 44.9 | 1.9 |
| 147 | | | | | | | | | |
| Example | 4.7 | present | 116.2 | 135.4 | 42.3 | 44.6 | 42.4 | 44.5 | 2.1 |
| 148 | | | | | | | | | |
| Example | 4.7 | present | 118.4 | 137.6 | 42.1 | 44.3 | 42.2 | 44.2 | 2.1 |
| 149 | | | | | | | | | |
| Example | 5.0 | present | 114.1 | 133.0 | 42.5 | 44.8 | 42.6 | 44.7 | 2.1 |
| 150 | | | | | | | | | |
| Example | 5.0 | present | 114.1 | 133.0 | 42.5 | 44.8 | 42.6 | 44.7 | 2.1 |
| 151 | | | | | | | | | |
| Example | 5.0 | present | 114.2 | 133.1 | 42.5 | 44.8 | 42.6 | 44.7 | 2.1 |
| 152 | | | | | | | | | |
| Example | 5.0 | present | 114.3 | 133.2 | 42.5 | 44.8 | 42.6 | 44.7 | 2.1 |
| 153 | | | | | | | | | |
| Example | 5.0 | present | 114.2 | 133.1 | 42.5 | 44.8 | 42.6 | 44.7 | 2.1 |
| 154 | | | | | | | | | |

(Evaluation Results)

In any of Examples 1 to 154, the temperatures of the chip, the shield inner surface and the shield outer surface were low, and the temperature difference in the shield outer surface was small, revealing that the heat absorbency and the heat releasability were good.

In any of Comparative Examples 1 to 47, the temperatures of the chip, the shield inner surface and the shield outer surface were higher than those in Examples, and the temperature difference in the shield outer surface was larger than that in Examples, revealing that the heat absorbency and the heat releasability were poor.

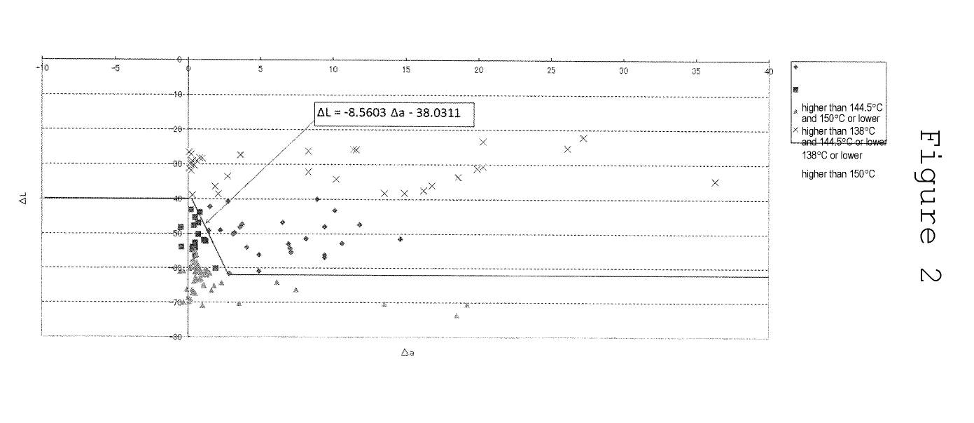

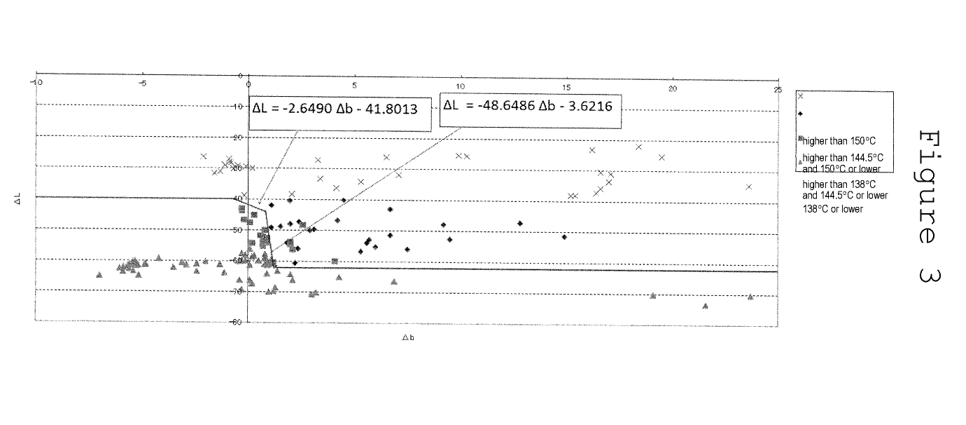

FIG. 2 shows a Δa-ΔL graph relevant to Examples 81 to 137 and Comparative Examples 16 to 47. FIG. 3 shows a Δb-ΔL graph relevant to Examples 81 to 137 and Comparative Examples 16 to 47.

1. A surface-treated metal material having:
a heat conductivity of 32 W/(m·K) or higher; and
a color difference ΔL based on JIS Z8730 of a surface thereof satisfying ΔL≦−40.

2. The surface-treated metal material according to claim 1, wherein with respect to color differences ΔL, Δa based on JIS Z8730 of a surface thereof,
when Δa≦0.23, ΔL satisfies ΔL≦−40;
when 0.23<Δa≦2.8, ΔL satisfies ΔL≦−8.5603×Δa−38.0311; and
when 2.8<Δa, ΔL satisfies ΔL≦−62.

3. The surface-treated metal material according to claim 1, wherein with respect to color differences ΔL, Δb based on JIS Z8730 of a surface thereof,
when Δb≦−0.68, ΔL satisfies ΔL≦−40;
when −0.68<Δb≦0.83, ΔL satisfies ΔL≦−2.6490×Δb−41.8013;
when 0.83<Δb≦1.2, ΔL satisfies ΔL≦−48.6486×Δb−3.6216; and
when 1.2<Δb, ΔL satisfies ΔL≦−62.

4. The surface-treated metal material according to claim 1, wherein with respect to color differences ΔL, Δa based on JIS Z8730 of a surface thereof,
when Δa≦0.23, ΔL satisfies ΔL≦−40;
when 0.23<Δa≦2.8, ΔL satisfies ΔL≦−8.5603×Δa−38.0311; and
when 2.8<Δa, ΔL satisfies ΔL≦−62, and
with respect to color differences ΔL, Δb based on JIS Z8730 of the surface thereof,
when Δb≦−0.68, ΔL satisfies ΔL≦−40;
when −0.68<Δb≦0.83, ΔL satisfies ΔL≦−2.6490×Δb−41.8013;
when 0.83<Δb≦1.2, ΔL satisfies ΔL≦−48.6486×Δb−3.6216; and
when 1.2<Δb, ΔL satisfies ΔL≦−62.

5. The surface-treated metal material according to claim 1, wherein the color difference ΔL satisfies ΔL≦−45.

6. The surface-treated metal material according to claim 5, wherein the color difference ΔL satisfies ΔL≦−55.

7. The surface-treated metal material according to claim 6, wherein the color difference ΔL satisfies ΔL≦−60.

8. The surface-treated metal material according to claim 7, wherein the color difference ΔL satisfies ΔL≦−65.

9. The surface-treated metal material according to claim 8, wherein the color difference ΔL satisfies ΔL≦−68.

10. The surface-treated metal material according to claim 9, wherein the color difference ΔL satisfies ΔL≦−70.

11. The surface-treated metal material according to claim 1, satisfying at least one of the following (A) to (C);
(A) the metal material is a metal material for heat release,
(B) the metal material has a treated surface layer comprising a metal,
(C) the metal material has a treated surface layer comprising a roughening-treated layer.

12. (canceled)

13. (canceled)

14. The surface-treated metal material according to claim 1, having a 60° glossiness of 10 to 80%.

15. The surface-treated metal material according to claim 1, having a 60° glossiness of lower than 10%.

16. The surface-treated metal material according to claim 1, having a treated surface layer comprising a chromium layer or a chromate layer and/or a silane-treated layer.

17. The surface-treated metal material according to claim 1, wherein the metal material is formed of copper, a copper alloy, aluminum, an aluminum alloy, iron, an iron alloy, nickel, a nickel alloy, gold, a gold alloy, silver, a silver alloy, a platinum-group metal, a platinum-group metal alloy, chromium, a chromium alloy, magnesium, a magnesium alloy, tungsten, a tungsten alloy, molybdenum, a molybdenum alloy, lead, a lead alloy, tantalum, a tantalum alloy, tin, a tin alloy, indium, an indium alloy, zinc, or a zinc alloy.

18. (canceled)

19. The surface-treated metal material according to claim 17, wherein the metal material is formed of a phosphor bronze, a Corson alloy, a red brass, a brass, a German silver, or another copper alloy.

20. (canceled)

21. The surface-treated metal material according to claim 1, wherein the treated surface layer has a resin layer or a resin layer comprising a dielectric on a surface thereof.

22. (canceled)

23. A metal foil with a carrier, having a middle layer and an ultrathin metal layer in this order on one surface or both surfaces of the carrier, wherein the ultrathin metal layer is the surface-treated metal material according to claim 1.

24. (canceled)

25. (canceled)

26. A connector or a terminal comprising the surface-treated metal material according to claim 1.

27. (canceled)

28. A laminate manufactured by laminating the surface-treated metal material according to claim 1 or a metal foil with a carrier, having a middle layer and an ultrathin metal layer in this order on one surface or both surfaces of the carrier, wherein the ultrathin metal layer is the surface-treated metal material according to claim 1 with a resin substrate.

29. A shielding tape or a shielding material or a printed wiring board comprising the laminate according to claim 28.

30. (canceled)

31. A processed metal member comprising the surface-treated metal material according to claim 1 or a metal foil with a carrier, having a middle layer and an ultrathin metal layer in this order on one surface or both surfaces of the carrier, wherein the ultrathin metal layer is the surface-treated metal material according to claim 1.

32. An electronic device comprising the surface-treated metal material according to claim 1 or a metal foil with a carrier, having a middle layer and an ultrathin metal layer in this order on one surface or both surfaces of the carrier, wherein the ultrathin metal layer is the surface-treated metal material according to claim 1.

33. A method for manufacturing a printed wiring board, comprising the steps of:
providing a metal foil with a carrier, having a middle layer and an ultrathin metal layer in this order on one surface or both surfaces of the carrier, wherein the ultrathin metal layer is the surface-treated metal material according to claim 1, and an insulating substrate;
laminating the metal foil with a carrier and the insulating substrate;
after the metal foil with a carrier and the insulating substrate are laminated, peeling off the carrier of the metal foil with a carrier to thereby form a metal clad laminated plate; and
thereafter forming a circuit by any one method of a semi-additive method, a subtractive method, a partly additive method and a modified semi-additive method.

34. A method for manufacturing a printed wiring board, comprising the steps of:
forming a circuit on a surface of the ultrathin metal layer side of a metal foil with a carrier, having a middle layer and an ultrathin metal layer in this order on one surface or both surfaces of the carrier, wherein the ultrathin metal layer is the surface-treated metal material according to claim 1 or a surface of the carrier side thereof;
forming a resin layer on the surface of the ultrathin metal layer side of the metal foil with a carrier or the surface of the carrier side thereof so as to embed the circuit;
forming a circuit on the resin layer;
after the circuit is formed on the resin layer, peeling off the carrier or the ultrathin metal layer; and
after the carrier or the ultrathin metal layer is peeled off, removing the ultrathin metal layer or the carrier to thereby expose the circuit formed on the surface of the ultrathin metal layer side or the surface of the carrier side and embedded in the resin layer.
